(19) United States
(12) Patent Application Publication
(10) Pub. No.: US 2015/0243895 A1
(43) Pub. Date: Aug. 27, 2015

(54) COMPOUND AND ORGANIC LIGHT-EMITTING DEVICE INCLUDING THE SAME

(71) Applicant: SAMSUNG DISPLAY CO., LTD., Yongin-City (KR)

(72) Inventors: Jin-O LIM, Yongin-City, Gyeonggi-Do (KR); Young-Kook KIM, Yongin-City, Gyeonggi-Do (KR); Jun-Ha PARK, Yongin-City, Gyeonggi-Do (KR); Eun-Young LEE, Yongin-City, Gyeonggi-Do (KR); Eun-Jae JEONG, Yongin-City, Gyeonggi-Do (KR); Seok-Hwan HWANG, Yongin-City, Gyeonggi-Do (KR)

(21) Appl. No.: 14/309,367

(22) Filed: Jun. 19, 2014

(30) Foreign Application Priority Data
Feb. 26, 2014 (KR) 10-2014-0022880

(51) Int. Cl. H01L 51/00; H01L 27/32; H01L 51/50

(52) U.S. Cl. CPC H01L 51/0054; H01L 51/0072; H01L 51/0067; H01L 51/0058; H01L 51/0073; H01L 51/0052; H01L 51/5092; H01L 51/5072; H01L 51/5056; H01L 51/504; H01L 51/5016; H01L 27/3248

(57) ABSTRACT

A compound is represented by Formula 1:

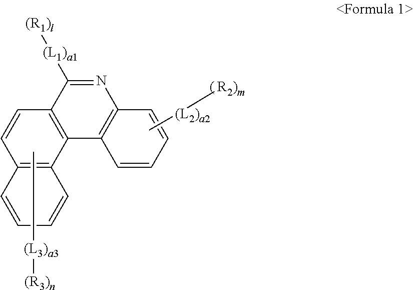

wherein L₁-L₃, R₁-R₃, a1-a3 and l-n are as described in the specification. An organic light-emitting device includes the compound.

### CROSS-REFERENCE TO RELATED APPLICATION

Korean Patent Application No. 10-2014-0022880, filed on Feb. 26, 2014, in the Korean Intellectual Property Office, and entitled: “Compound and Organic Light-Emitting Device Including the Same,” is incorporated by reference herein in its entirety.

### BACKGROUND

1. Field

One or more embodiments relate to a compound and an organic light-emitting device including the same.

2. Description of the Related Art

Organic light emitting devices are self-emission devices that have wide viewing angles, high contrast ratios, short response time, and excellent brightness, driving voltage, and response speed characteristics, and produce full-color images.

There is a need to develop a material that has excellent electric stability, high charge transport capability or luminescent capability, high glass transition temperature, and high crystallization prevention capability, compared to an organic monomolecular material according to the related art.

### SUMMARY

Embodiments are directed to a compound is represented by Formula 1 below:

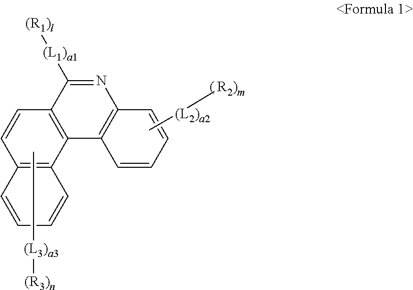

wherein in Formula 1,

R₁ to R₃ may be each independently a hydrogen; a deuterium; a halogen; a cyano group; a hydroxyl group; a nitro group; an amino group; an amidino group; a hydrazine group; a hydrazone group; carboxylic acid or a salt thereof; a sulfonic acid or a salt thereof; a phosphoric acid or a salt thereof; a substituted or unsubstituted C₁ to C₆₀ alkyl group; a substituted or unsubstituted C₂ to C₆₀ alkenyl group; a substituted or unsubstituted C₂ to C₆₀ alkynyl group; a substituted or unsubstituted C₃ to C₆₀ cycloalkyl group; a substituted or unsubstituted C₃ to C₆₀ cycloalkenyl group; a substituted or unsubstituted C₆ to C₆₀ aryl group; a substituted or unsubstituted C₁ to C₆₀ heteroaryl group; or a C₆ to C₆₀ substituted or unsubstituted condensed polycyclic group; —P(═O)R₄R₅; —P(═S)R₆R₇; —S(═O)R₈; or —S(═O)₂R₉,

L₁ to L₃ may be each independently a C₃ to C₁₀ substituted or unsubstituted cycloalkylene group; a C₃ to C₁₀ substituted or unsubstituted heterocycloalkylene group; a C₃ to C₁₀ substituted or unsubstituted cycloalkenylene group; a C₃ to C₁₀ substituted or unsubstituted heterocycloalkenylene group; a C₆ to C₆₀ substituted or unsubstituted arylene group; a C₁ to C₆₀ substituted or unsubstituted heteroarylene group; a C₆ to C₆₀ substituted or unsubstituted condensed polycyclic group; —P(═O)R₄—; —P(═S)R₅—; —S(═O)—; or —S(═O)₂—;

R₄ to R₉ may be each independently a hydrogen; a deuterium; a substituted or unsubstituted C₆ to C₆₀ aryl group; a substituted or unsubstituted C₂ to C₆₀ heteroaryl group; or a C₆ to C₆₀ substituted or unsubstituted condensed polycyclic group,

a1 to a3 may be each independently an integer of 0 to 3; and

l, m, and n may be each independently 1 or 2.

Embodiments are also directed to an organic light-emitting device that includes: a first electrode; a second electrode; and an organic layer disposed between the first electrode and the second electrode, wherein the organic layer includes the compound represented by Formula 1.

Embodiments are also directed to a flat panel display apparatus includes the organic light-emitting device, wherein the first electrode of the organic light-emitting device is electrically connected to a source electrode or a drain electrode of a thin film transistor.

### BRIEF DESCRIPTION OF THE DRAWINGS

Features will become apparent to those of skill in the art by describing in detail exemplary embodiments with reference to the attached drawings in which:

FIG. 1 is a schematic view of an organic light-emitting device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the term “and/or” includes any and all combinations of one or more of the associated listed items. Expressions such as “at least one of,” when preceding a list of elements, modify the entire list of elements and do not modify the individual elements of the list.

A compound according to an embodiment is represented by Formula 1:

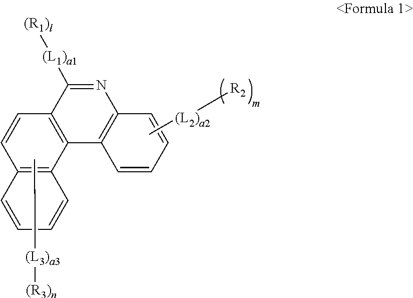

wherein in Formula 1,

R₁ to R₃ may be each independently a hydrogen; a deuterium; a halogen; a cyano group; a hydroxyl group, a nitro group, an amino group, an amidino group, a hydrazine group, a hydrazone group, carboxylic acid or a salt thereof, a sulfonic acid or a salt thereof, a phosphoric acid or a salt thereof; a substituted or unsubstituted C₁ to C₆₀ alkyl group; a substituted or unsubstituted C₂ to C₆₀ alkenyl group; a substituted or unsubstituted C₂ to C₆₀ alkynyl group; a substituted or unsubstituted C₃ to C₆₀ cycloalkyl group; a substituted or unsubstituted C₃ to C₆₀ cycloalkenyl group; a substituted or unsubstituted C₆ to C₆₀ aryl group; a substituted or unsubstituted C₁ to C₆₀ heteroaryl group; or a C₆ to C₆₀ substituted or unsubstituted condensed polycyclic group; —P(═O)R₄R₅; —P(═S)R₆R₇; —S(═O)R₈; or —S(═O)₂R₉,

L₁ to L₃ may be each independently a C₃ to C₁₀ substituted or unsubstituted cycloalkylene group; a C₃ to C₁₀ substituted or unsubstituted heterocycloalkylene group; a C₃ to C₁₀ substituted or unsubstituted cycloalkenylene group; a C₃ to C₁₀ substituted or unsubstituted heterocycloalkenylene group; a C₆ to C₆₀ substituted or unsubstituted arylene group; a C₁ to C₆₀ substituted or unsubstituted heteroarylene group; a C₆ to C₆₀ substituted or unsubstituted condensed polycyclic group; —P(═O)R₄—; —P(═S)R₅—; —S(═O)—; or —S(═O)₂—;

R₄ to R₉ may be each independently a hydrogen; a deuterium; a substituted or unsubstituted C₆ to C₆₀ aryl group; a substituted or unsubstituted C₂ to C₆₀ heteroaryl group; or a C₆ to C₆₀ substituted or unsubstituted condensed polycyclic group,

a1 to a3 may be each independently an integer of 0 to 3; and

l, m, and n may be each independently 1 or 2.

Compounds represented by Formula 1 according to an embodiment may act as an emission material for an organic light-emitting device. Also, compounds of Formula 1 may have high glass transition temperatures (Tg) or high melting points due to the introduction of a hetero-ring. Accordingly, during emission, a heat resistance against Joule's heat that may occur within an organic layer, between organic layers, or between an organic layer and a metal electrode, and durability at high temperature may increase. Accordingly, an organic light-emitting device manufactured by using such compounds according to the present disclosure has high durability during preservation or driving. Also, due to the introduction of a substituent having a hetero element, characteristics of an organic light-emitting device may be improved.

Substituents for the compound of Formula 1 will now be described in detail.

According to an embodiment, L₁ to L₃ may each independently be a C₆ to C₃₀ substituted or unsubstituted arylene group; a C₁ to C₃₀ substituted or unsubstituted heteroarylene group; a C₆ to C₃₀ substituted or unsubstituted condensed polycyclic group; —P(═O)R₄—; —P(═S)R₅—; —S(═O)—; or —S(═O)₂—. R₄ and R₅ are the same as defined above (also the same definition may be applied to R₄ and R₅ hereinafter). For example, each of R₄ and R₅ may be a phenyl group.

According to an embodiment, R₁ to R₃ in Formula 1 may each independently be a hydrogen; a deuterium; a cyano group; a substituted or unsubstituted C₆ to C₃₀ aryl group; a substituted or unsubstituted C₁ to C₃₀ heteroaryl group; a C₆ to C₃₀ substituted or unsubstituted condensed polycyclic group; —P(═O)R₄R₅; —P(═S)R₆R₇; —S(═O)R₈; or —S(═O)₂R₉. R₄ to R₉ may be the same as defined above (also the same definition is applied to R₄ to R₉ hereinafter). For example, each of R₄ to R₉ may be a phenyl group.

According to an embodiment, R₁ in Formula 1 may be a cyano group; a substituted or unsubstituted C₆ to C₃₀ aryl group; a substituted or unsubstituted C₁ to C₃₀ heteroaryl group; a C₃ to C₆₀ substituted or unsubstituted condensed polycyclic group; —P(═O)R₄R₅; —P(═S)R₆R₇; —S(═O)R₈; or —S(═O)₂R₉.

According to an embodiment, R₂ in Formula 1 may be a cyano group; a substituted or unsubstituted C₆ to C₃₀ aryl group; a substituted or unsubstituted C₁ to C₃₀ heteroaryl group; a C₃ to C₆₀ substituted or unsubstituted condensed polycyclic group; —P(═O)R₄R₅; —P(═S)R₆R₇; —S(═O)R₈; or —S(═O)₂R₉.

According to an embodiment, R₃ may be a cyano group; a substituted or unsubstituted C₆ to C₃₀ aryl group; a substituted or unsubstituted C₁ to C₃₀ heteroaryl group; a C₃ to C₆₀ substituted or unsubstituted condensed polycyclic group; —P(═O)R₄R₅; —P(═S)R₆R₇; —S(═O)R₈; or —S(═O)₂R₉.

According to an embodiment, R₂ and R₃ in Formula 1 may be each a hydrogen or a deuterium, and a2 and a3 may each be 0.

According to an embodiment, R₂ may be a hydrogen or a deuterium, and a2 may be 0.

According to an embodiment, R₃ may be a hydrogen or a deuterium, and a3 may be 0.

When a2 is 0, L₂ does not exist. When a3 is 0, L₃ does not exist.

According to an embodiment, L₁ to L₃ in Formula 1 may be each independently —P(═O)R₄—; —P(═S)R₅—; —S(═O)—; —S(═O)₂—; or one of Formulae 2a to 2h illustrated below:

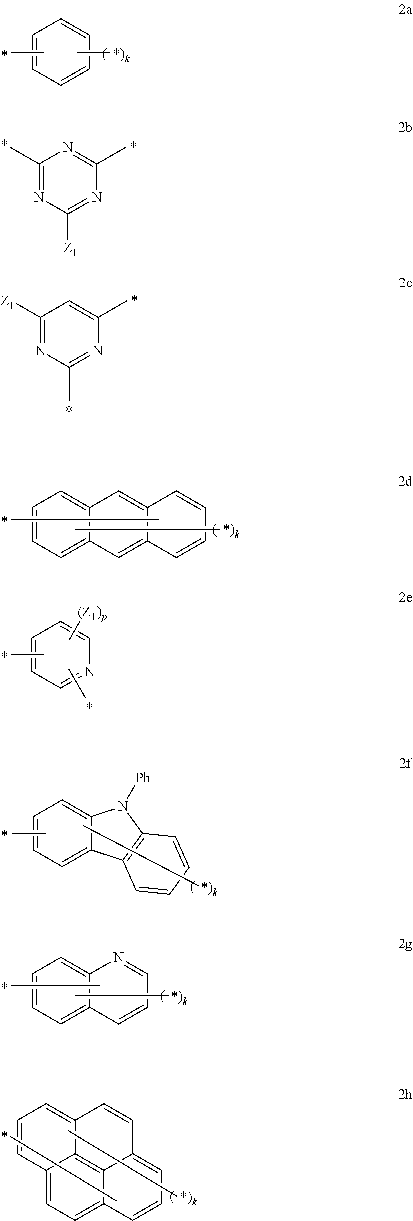

In Formulae 2a to 2h above, Z₁ may be a hydrogen, a deuterium, a substituted or unsubstituted C₁ to C₂₀ alkyl group, a substituted or unsubstituted C₆ to C₂₀ aryl group, a substituted or unsubstituted C₁ to C₂₀ heteroaryl group, a substituted or unsubstituted C₆ to C₂₀ condensed polycyclic group, a halogen group, a cyano group, a nitro group, a hydroxyl group, or a carboxy group;

p and k may be each independently an integer of 1 to 3; and * indicates a binding site.

According to another embodiment, R₁ to R₃ in Formula 1 may be each independently a hydrogen; a deuterium; a cyano group; —P(═O)R₄R₅; —P(═S)R₆R₇; —S(═O)R₈; —S(═O)₂R₉; or any one of Formulae 3a to 3h illustrated below:

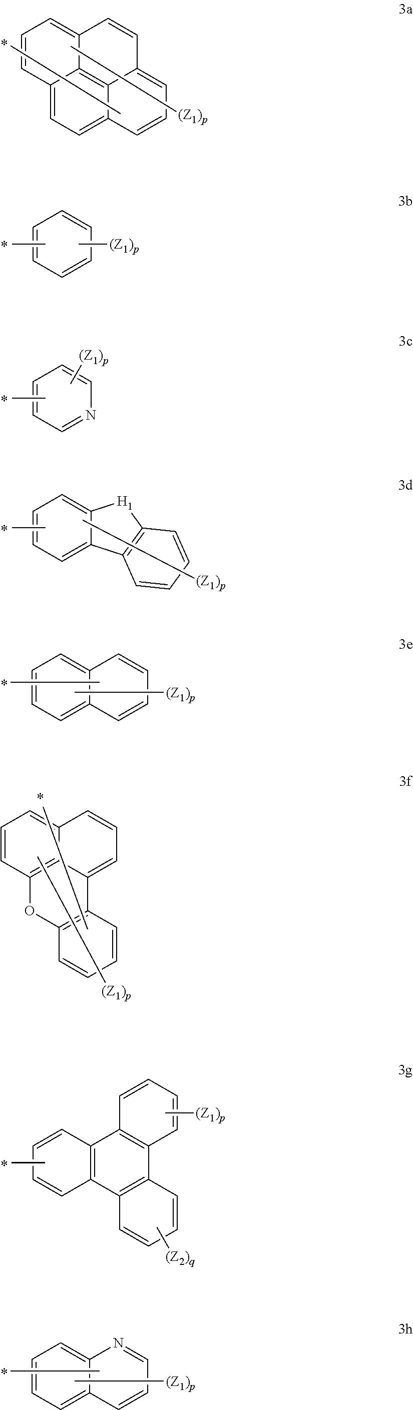

In these Formulae 3a to 3h above, Z₁ and Z₂ may be each independently a hydrogen, a deuterium, a substituted or unsubstituted C₁ to C₂₀ alkyl group, a substituted or unsubstituted C₆ to C₂₀ aryl group, a substituted or unsubstituted C₁ to C₂₀ heteroaryl group, a substituted or unsubstituted C₆ to C₂₀ condensed polycyclic group, a halogen group, a cyano group, a nitro group, a hydroxyl group, or a carboxy group;

p and q may be each independently an integer of 1 to 9; and * indicates a binding site.

Hereinafter, definitions of substituents used herein will be presented. (The number of carbon numbers restricting a substituent is not limited, and does not limit properties of the substituent, and unless defined otherwise, the definition of the substituent is consistent with a general definition thereof.)

The unsubstituted C₁ to C₆₀ alkyl group may be a linear or branched alkyl group. Examples thereof include a methyl group, an ethyl group, a propyl group, an isobutyl group, a sec-butyl group, a pentyl group, an iso-amyl group, a hexyl group, a heptyl group, an octyl group, a nonanyl group, and a dodecyl group. In the substituted C₁ to C₆₀ alkyl group, at least one hydrogen atom of the alkyl group may be substituted with a deuterium, a halogen atom, a hydroxyl group, a nitro group, a cyano group, an amino group, an amidino group, a hydrazine, a hydrazone, a carboxyl group or salt thereof, a sulfonic acid or salt thereof, a phosphoric acid or salt thereof, a C₁ to C₁₀ alkyl group, a C₁ to C₁₀ alkoxy group, a C₂ to C₁₀ alkenyl group, a C₂ to C₁₀ alkynyl group, a C₆ to C₁₆ aryl group, a C₄ to C₁₆ heteroaryl group, or an organosilyl group.

The unsubstituted C₂ to C₆₀ alkenyl group is an unsubstituted alkyl group having one or more carbon double bonds at a center or end thereof. Examples of the unsubstituted C₂-C₆₀ alkenyl group include an ethenyl group, a propenyl group, and a butenyl group. In the substituted C₂ to C₆₀ alkenyl group, at least one hydrogen atom of the alkenyl group may be substituted with the same substituents as described in connection with the substituted alkyl group.

The unsubstituted C₂ to C₆₀ alkynyl group is an unsubstituted alkyl group having one or more carbon triple bonds at a center or end thereof. Examples thereof include acetylene, propylene, phenylacetylene, naphthylacetylene, isopropylacetylene, t-butylacetylene, and diphenylacetylene. In the substituted C₂ to C₆₀ alkynyl group, at least one hydrogen atom of these alkynyl groups may be substituted with the same substituents as described in connection with the substituted alkyl group.

The unsubstituted C₃ to C₆₀ cycloalkyl group is a C₃ to C₆₀ cyclic alkyl group. in the substituted C₃ to C₆₀ cycloalkyl group, at least one hydrogen atom of the cycloalkyl group may be substituted with the same substituents as described in connection with the C₁ to C₆₀ alkyl group.

The unsubstituted C₁ to C₆₀ alkoxy group is a group having —OA (wherein A is the unsubstituted C₁ to C₆₀ alkyl group). Examples thereof include ethoxy, ethoxy, isopropyloxy, butoxy, and pentoxy. In the substituted C₁ to C₆₀ alkoxy group, at least one hydrogen atom of the unsubstituted alkoxy group may be substituted with the same substituents as described in connection with the alkyl group.

The unsubstituted C₆ to C₆₀ aryl group is a carbocyclic aromatic system having at least one aromatic ring. When the number of rings is two or more, the rings may be fused to each other or may be linked to each other via, for example, a single bond. The term ‘aryl’ includes an aromatic system, such as phenyl, naphthyl, or anthracenyl. In the substituted C₆ to C₆₀ aryl group, at least one hydrogen atom of the aryl group may be substituted with the same substituents described in connection with the C₁ to C₆₀ alkyl group.

Examples of a substituted or unsubstituted C₆ to C₆₀ aryl group include a phenyl group, a C₁ to C₁₀ alkylphenyl group (for example, an ethylphenyl group), a halophenyl group (for example, o-, m- and p-fluorophenyl groups, and a dichlorophenyl group), a cyanophenyl group, a dicyanophenyl group, a trifluoromethoxyphenyl group, a biphenyl group, a halobiphenyl group, a cyanobiphenyl group, a C₁ to C₁₀ alkylbiphenyl group, a C₁ to C₁₀ alkoxybiphenyl group, an o-, m-, or p-tolyl group, an o-, m- or p-cumenyl groups, a mesityl group, a phenoxyphenyl group, a (α,α-dimethylbenzene)phenyl group, a (N,N′-dimethyl)aminophenyl group, a (N,N′-diphenyl)aminophenyl group, a pentalenyl group, an indenyl group, a naphthyl group, a halonaphthyl group (for example, a fluoronaphthyl group), a C₁ to C₁₀ an alkylnaphthyl group (for example, a methylnaphthyl group), a C₁ to C₁₀ alkoxy naphthyl group (for example, a methoxynaphthyl group), a cyanonaphthyl group, an anthracenyl group, an azulenyl group, a heptalenyl group, an acenaphthylenyl group, a phenalenyl group, a fluorenyl group, an anthraquinolyl group, a methylanthryl group, a phenanthryl group, a triphenylene group, a pyrenyl group, a chrycenyl group, an ethyl-chrycenyl group, a picenyl group, a perylenyl group, a chlorophenylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl group, a pyranthrenyl group, and an ovalenyl group.

The unsubstituted C₁-C₆₀ heteroaryl group may include at least one hetero atom selected from nitrogen (N), oxygen (O), phosphorous (P), and sulfur (S). When the group has two or more rings, the rings may be fused to each other or may be linked to each other via, for example, a single bond. Examples of the unsubstituted C₁-C₆₀ heteroaryl group include a pyrazolyl group, an imidazolyl group, a oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, and a dibenzothiophene group. In the substituted C₁-C₆₀ heteroaryl group, at least one hydrogen atom of the heteroaryl may be substituted with the same substituents described in connection with the C₁ to C₆₀ alkyl group.

The unsubstituted C₆ to C₆₀ aryloxy group is a group represented by —OA₁, wherein A₁ is the C₆ to C₆₀ aryl group. An example of the aryloxy group is a phenoxy group. In the substituted C₆ to C₆₀ aryloxy group, at least one hydrogen atom of the aryloxy group may be substituted with the same substituents described in connection with the C₁ to C₆₀ alkyl group.

The unsubstituted C₆ to C₆₀ arylthio group is a group represented by —SA₁, wherein A₁ is the C₆ to C₆₀ aryl group. Examples of the arylthio group include a benzenethio group and a naphthylthio group. In the substituted C₆ to C₆₀ arylthio group, at least one hydrogen atom of the arylthio group may be substituted with the same substituents described in connection with the C₁ to C₆₀ alkyl group.

The unsubstituted C₆ to C₆₀ condensed polycyclic group may be either a substituent having two or more rings in which at least one aromatic ring, which may include 1, 2, 3, or 4 hetero atoms selected from N, O, P, and S, is fused with at least one non-aromatic ring, which may include 1, 2, 3, or 4 hetero atoms selected from N, O, P, and S, or a substituent that includes a unsaturated group in its ring or does not include a conjugated structure. The unsubstituted C₆ to C₆₀ condensed polycyclic group overall does not have aromatic properties, which is a distinguishing factor from an aryl group or a heteroaryl group.

Examples of the compound represented by Formula 1 include compounds illustrated below.

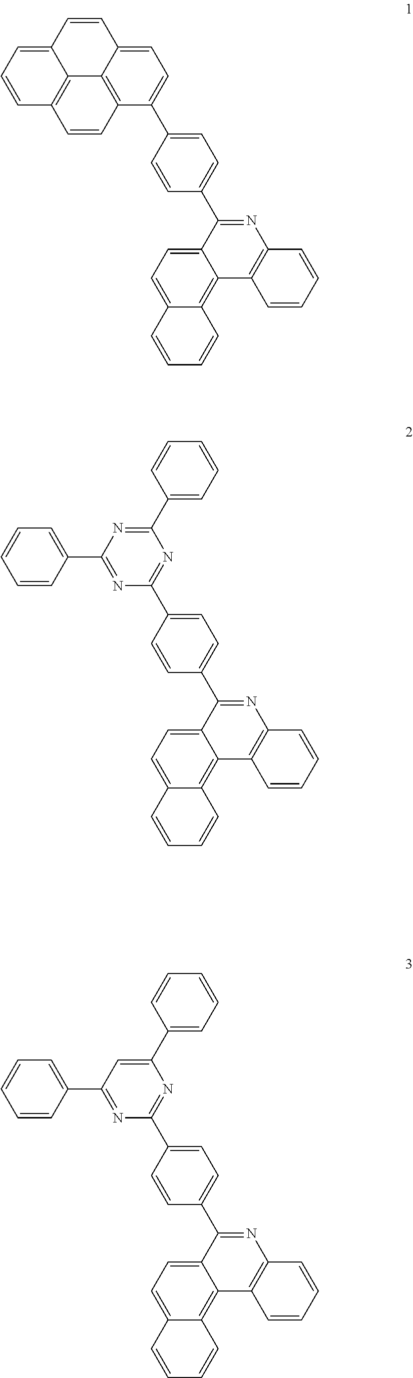 [SMILES: c1ccc2c(c1)ccc1c(-c3ccc(-c4ccc5ccc6cccc7ccc4c5c67)cc3)nc3ccccc3c12 ; c1ccc(-c2nc(-c3ccccc3)nc(-c3ccc(-c4nc5ccccc5c5c4ccc4ccccc45)cc3)n2)cc1 ; c1ccc(-c2cc(-c3ccccc3)nc(-c3ccc(-c4nc5ccccc5c5c4ccc4ccccc45)cc3)n2)cc1]

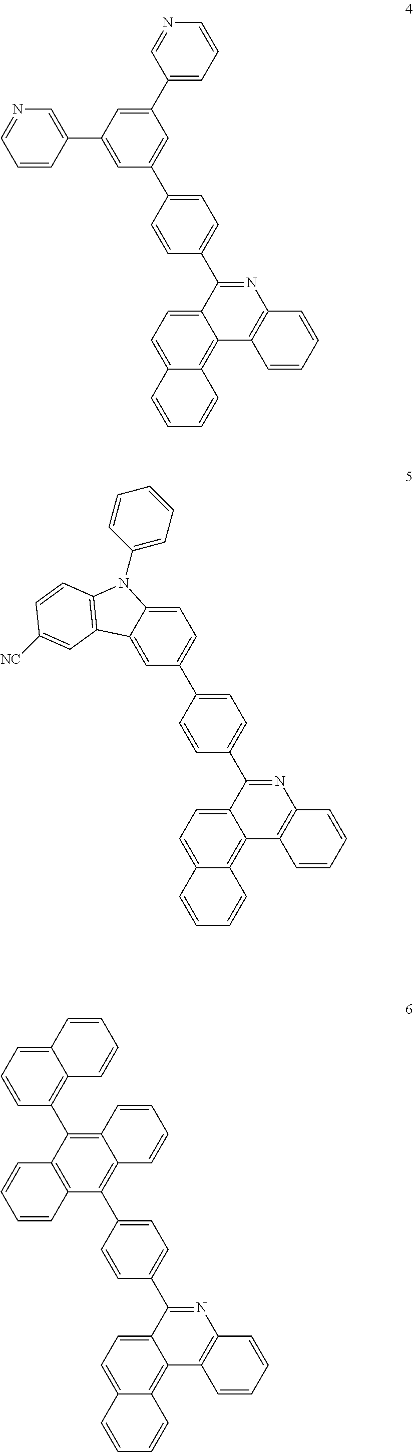 [SMILES: c1cncc(-c2cc(-c3ccc(-c4nc5ccccc5c5c4ccc4ccccc45)cc3)cc(-c3cccnc3)c2)c1 ; N#Cc1ccc2c(c1)c1cc(-c3ccc(-c4nc5ccccc5c5c4ccc4ccccc45)cc3)ccc1n2-c1ccccc1 ; c1ccc2c(-c3c4ccccc4c(-c4ccc(-c5nc6ccccc6c6c5ccc5ccccc56)cc4)c4ccccc34)cccc2c1]

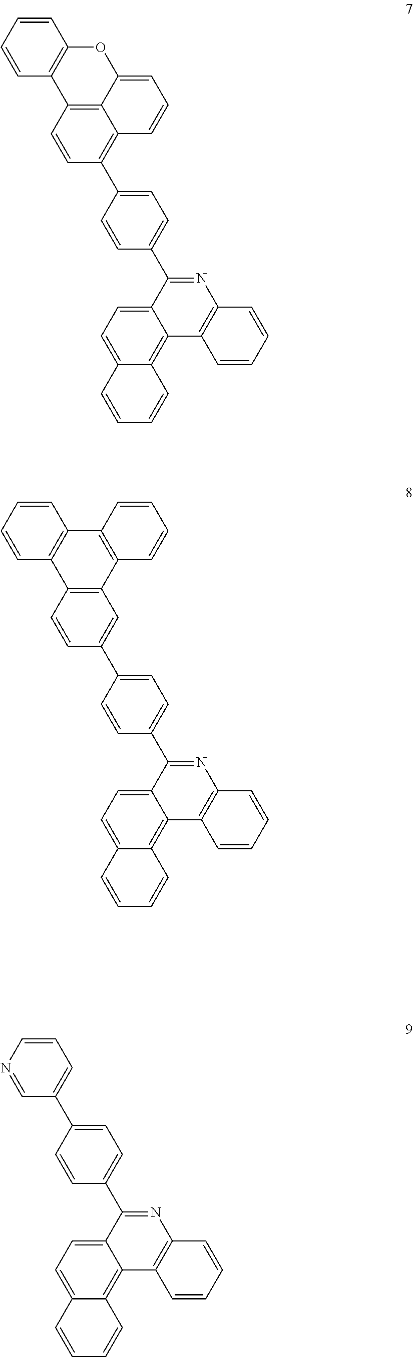 [SMILES: c1ccc2c(c1)Oc1cccc3c(-c4ccc(-c5nc6ccccc6c6c5ccc5ccccc56)cc4)ccc-2c13 ; c1ccc2c(c1)ccc1c(-c3ccc(-c4ccc5c6ccccc6c6ccccc6c5c4)cc3)nc3ccccc3c12 ; c1cncc(-c2ccc(-c3nc4ccccc4c4c3ccc3ccccc34)cc2)c1]

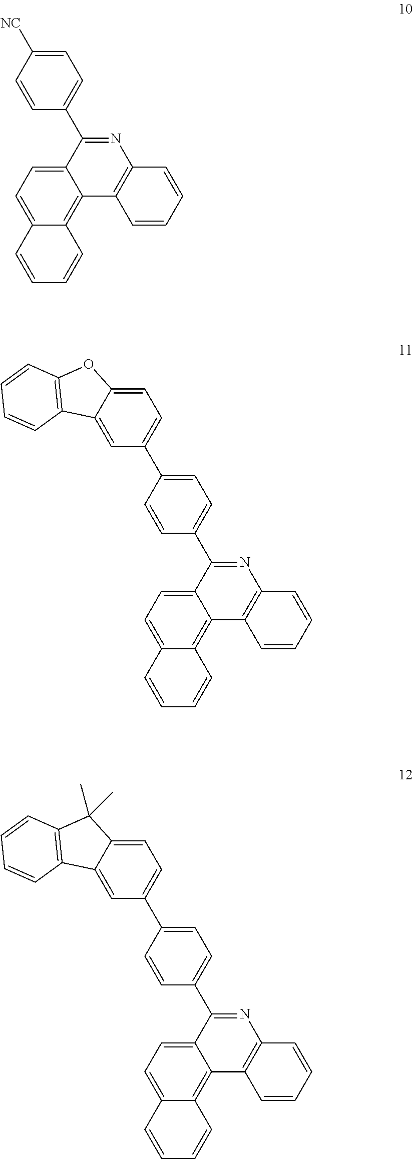 [SMILES: N#Cc1ccc(-c2nc3ccccc3c3c2ccc2ccccc23)cc1 ; c1ccc2c(c1)ccc1c(-c3ccc(-c4ccc5oc6ccccc6c5c4)cc3)nc3ccccc3c12 ; CC1(C)c2ccccc2-c2cc(-c3ccc(-c4nc5ccccc5c5c4ccc4ccccc45)cc3)ccc21]

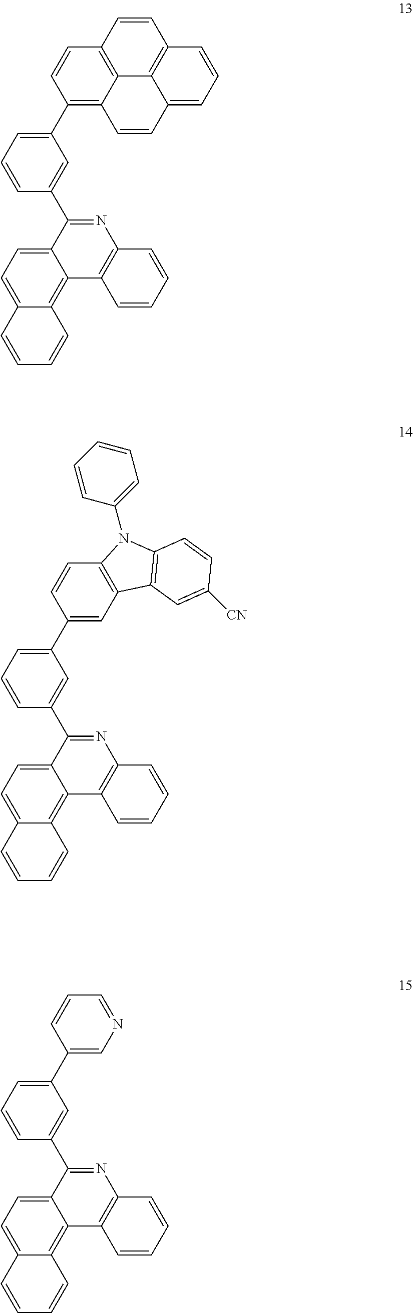 [SMILES: c1cc(-c2nc3ccccc3c3c2ccc2ccccc23)cc(-c2ccc3ccc4cccc5ccc2c3c45)c1 ; N#Cc1ccc2c(c1)c1cc(-c3cccc(-c4nc5ccccc5c5c4ccc4ccccc45)c3)ccc1n2-c1ccccc1 ; c1cncc(-c2cccc(-c3nc4ccccc4c4c3ccc3ccccc34)c2)c1]

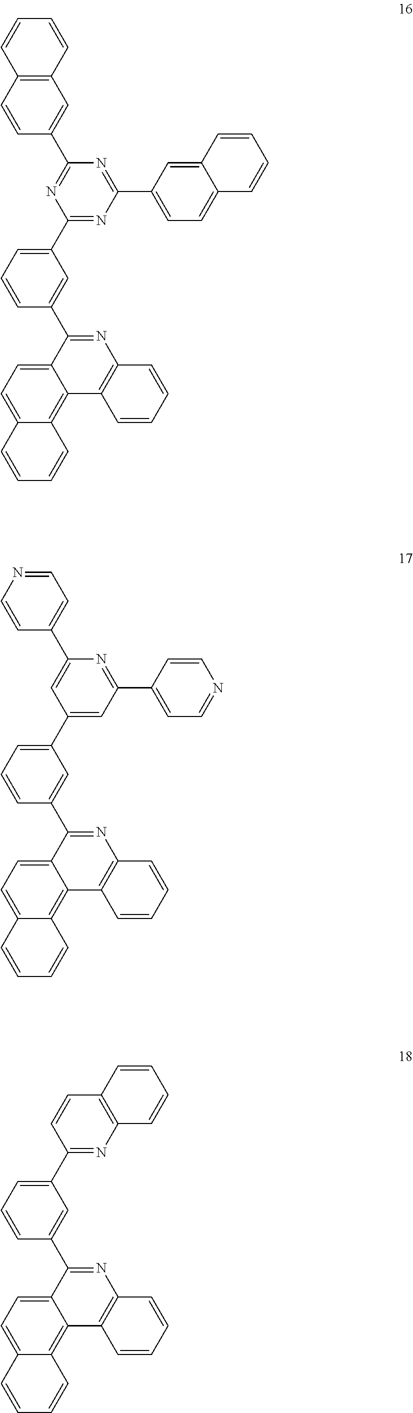 [SMILES: c1cc(-c2nc(-c3ccc4ccccc4c3)nc(-c3ccc4ccccc4c3)n2)cc(-c2nc3ccccc3c3c2ccc2ccccc23)c1 ; c1cc(-c2cc(-c3ccncc3)nc(-c3ccncc3)c2)cc(-c2nc3ccccc3c3c2ccc2ccccc23)c1 ; c1cc(-c2ccc3ccccc3n2)cc(-c2nc3ccccc3c3c2ccc2ccccc23)c1]

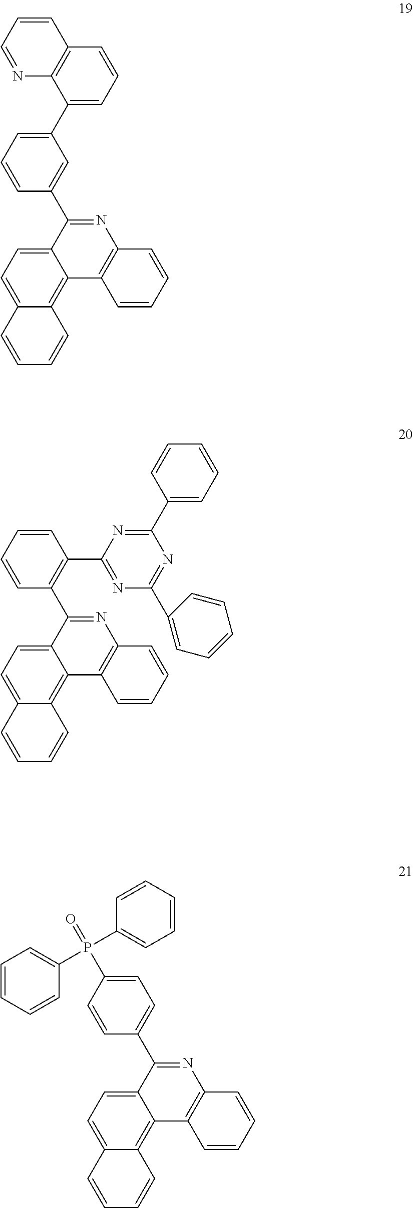 [SMILES: c1cc(-c2nc3ccccc3c3c2ccc2ccccc23)cc(-c2cccc3cccnc23)c1 ; c1ccc(-c2nc(-c3ccccc3)nc(-c3ccccc3-c3nc4ccccc4c4c3ccc3ccccc34)n2)cc1 ; O=P(c1ccccc1)(c1ccccc1)c1ccc(-c2nc3ccccc3c3c2ccc2ccccc23)cc1]

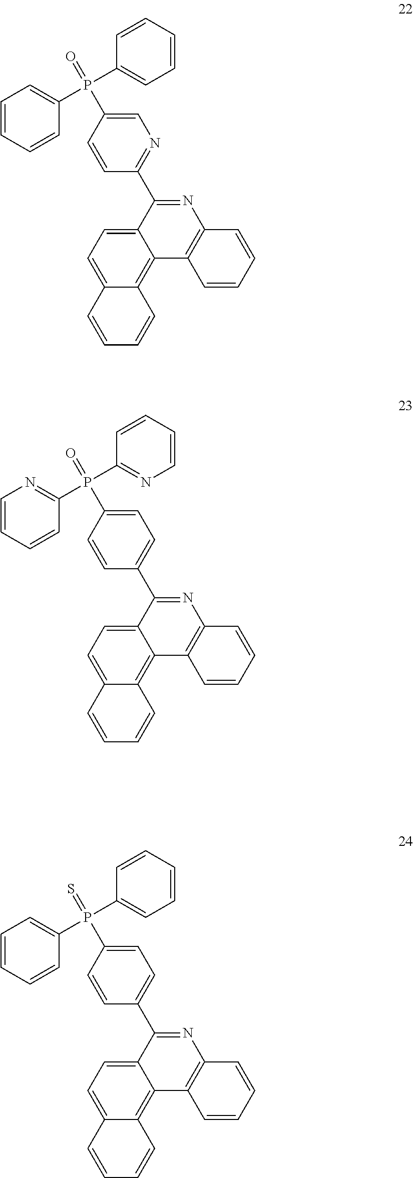 [SMILES: O=P(c1ccccc1)(c1ccccc1)c1ccc(-c2nc3ccccc3c3c2ccc2ccccc23)nc1 ; O=P(c1ccc(-c2nc3ccccc3c3c2ccc2ccccc23)cc1)(c1ccccn1)c1ccccn1 ; S=P(c1ccccc1)(c1ccccc1)c1ccc(-c2nc3ccccc3c3c2ccc2ccccc23)cc1]

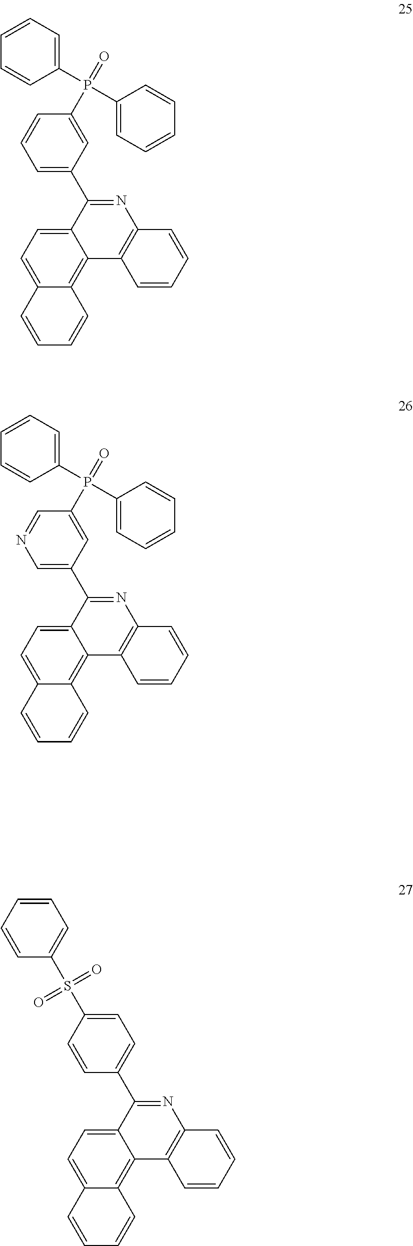 [SMILES: O=P(c1ccccc1)(c1ccccc1)c1cccc(-c2nc3ccccc3c3c2ccc2ccccc23)c1 ; O=P(c1ccccc1)(c1ccccc1)c1cncc(-c2nc3ccccc3c3c2ccc2ccccc23)c1 ; O=S(=O)(c1ccccc1)c1ccc(-c2nc3ccccc3c3c2ccc2ccccc23)cc1]

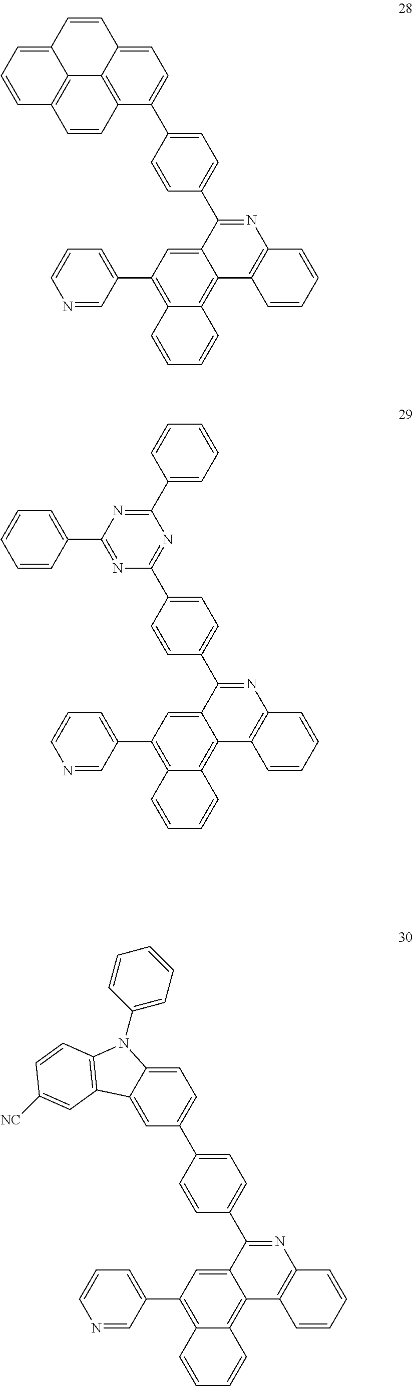 [SMILES: c1cncc(-c2cc3c(-c4ccc(-c5ccc6ccc7cccc8ccc5c6c78)cc4)nc4ccccc4c3c3ccccc23)c1 ; c1ccc(-c2nc(-c3ccccc3)nc(-c3ccc(-c4nc5ccccc5c5c4cc(-c4cccnc4)c4ccccc45)cc3)n2)cc1 ; N#Cc1ccc2c(c1)c1cc(-c3ccc(-c4nc5ccccc5c5c4cc(-c4cccnc4)c4ccccc45)cc3)ccc1n2-c1ccccc1]

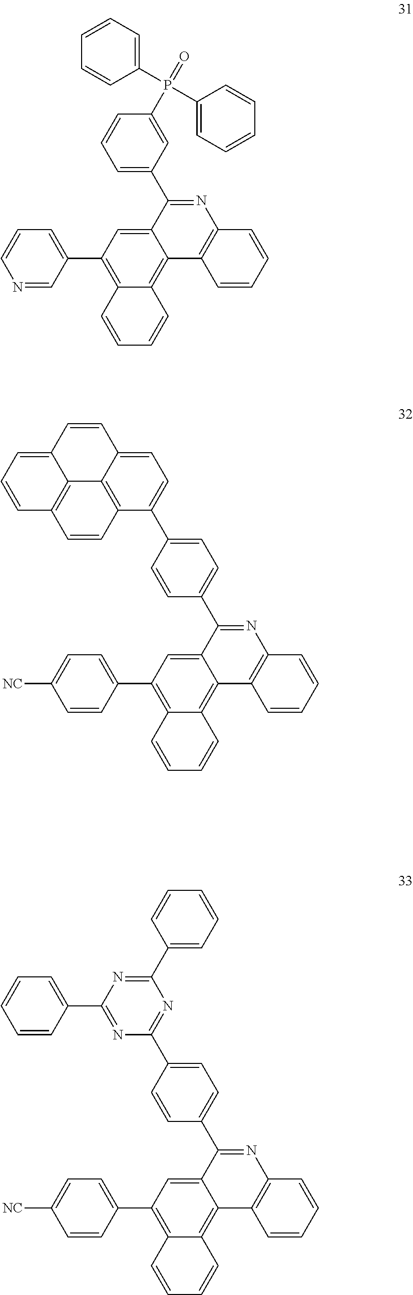 [SMILES: O=P(c1ccccc1)(c1ccccc1)c1cccc(-c2nc3ccccc3c3c2cc(-c2cccnc2)c2ccccc23)c1 ; N#Cc1ccc(-c2cc3c(-c4ccc(-c5ccc6ccc7cccc8ccc5c6c78)cc4)nc4ccccc4c3c3ccccc23)cc1 ; N#Cc1ccc(-c2cc3c(-c4ccc(-c5nc(-c6ccccc6)nc(-c6ccccc6)n5)cc4)nc4ccccc4c3c3ccccc23)cc1]

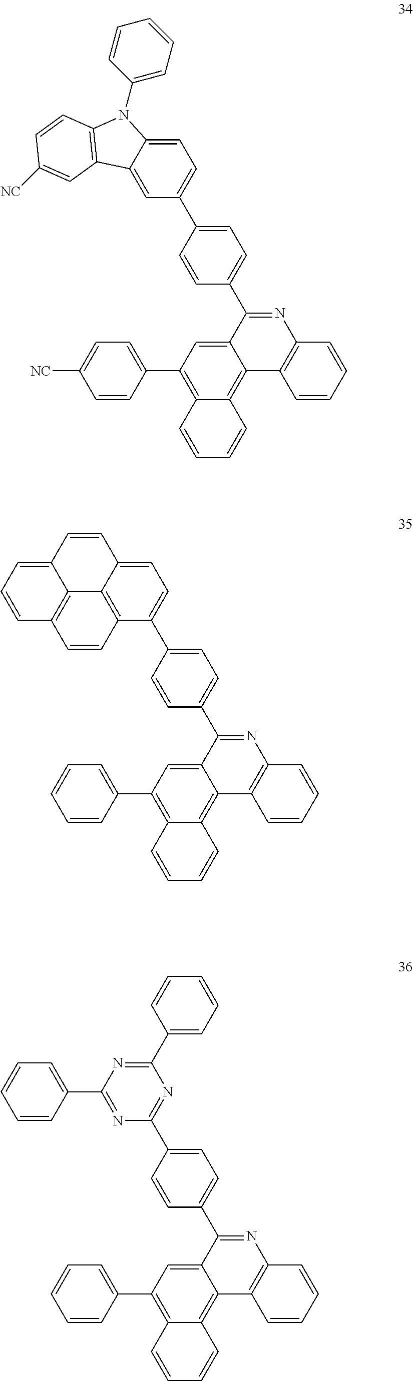 [SMILES: N#Cc1ccc(-c2cc3c(-c4ccc(-c5ccc6c(c5)c5cc(C#N)ccc5n6-c5ccccc5)cc4)nc4ccccc4c3c3ccccc23)cc1 ; c1ccc(-c2cc3c(-c4ccc(-c5ccc6ccc7cccc8ccc5c6c78)cc4)nc4ccccc4c3c3ccccc23)cc1 ; c1ccc(-c2nc(-c3ccccc3)nc(-c3ccc(-c4nc5ccccc5c5c4cc(-c4ccccc4)c4ccccc45)cc3)n2)cc1]

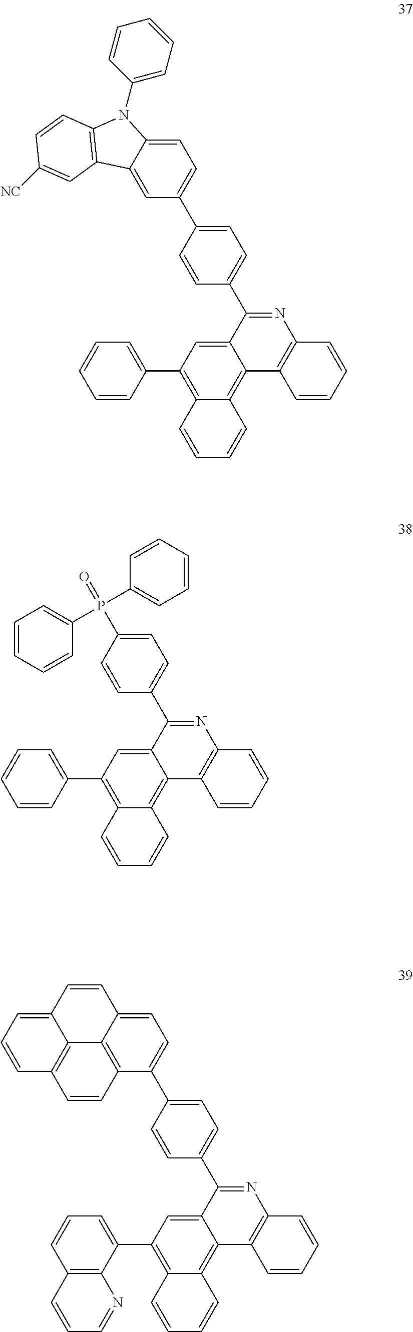 [SMILES: N#Cc1ccc2c(c1)c1cc(-c3ccc(-c4nc5ccccc5c5c4cc(-c4ccccc4)c4ccccc45)cc3)ccc1n2-c1ccccc1 ; O=P(c1ccccc1)(c1ccccc1)c1ccc(-c2nc3ccccc3c3c2cc(-c2ccccc2)c2ccccc23)cc1 ; c1cnc2c(-c3cc4c(-c5ccc(-c6ccc7ccc8cccc9ccc6c7c89)cc5)nc5ccccc5c4c4ccccc34)cccc2c1]

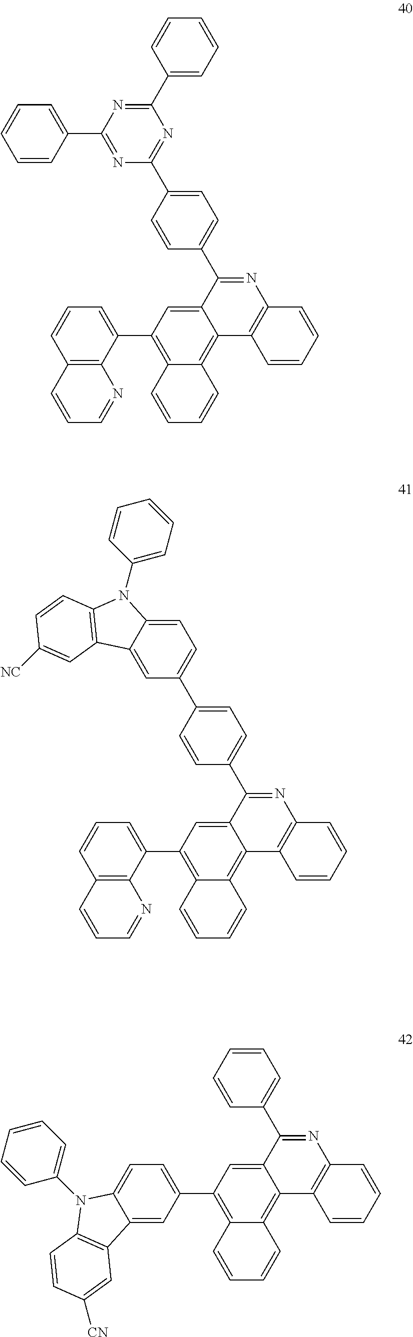 [SMILES: c1ccc(-c2nc(-c3ccccc3)nc(-c3ccc(-c4nc5ccccc5c5c4cc(-c4cccc6cccnc46)c4ccccc45)cc3)n2)cc1 ; N#Cc1ccc2c(c1)c1cc(-c3ccc(-c4nc5ccccc5c5c4cc(-c4cccc6cccnc46)c4ccccc45)cc3)ccc1n2-c1ccccc1 ; N#Cc1ccc2c(c1)c1cc(-c3cc4c(-c5ccccc5)nc5ccccc5c4c4ccccc34)ccc1n2-c1ccccc1]

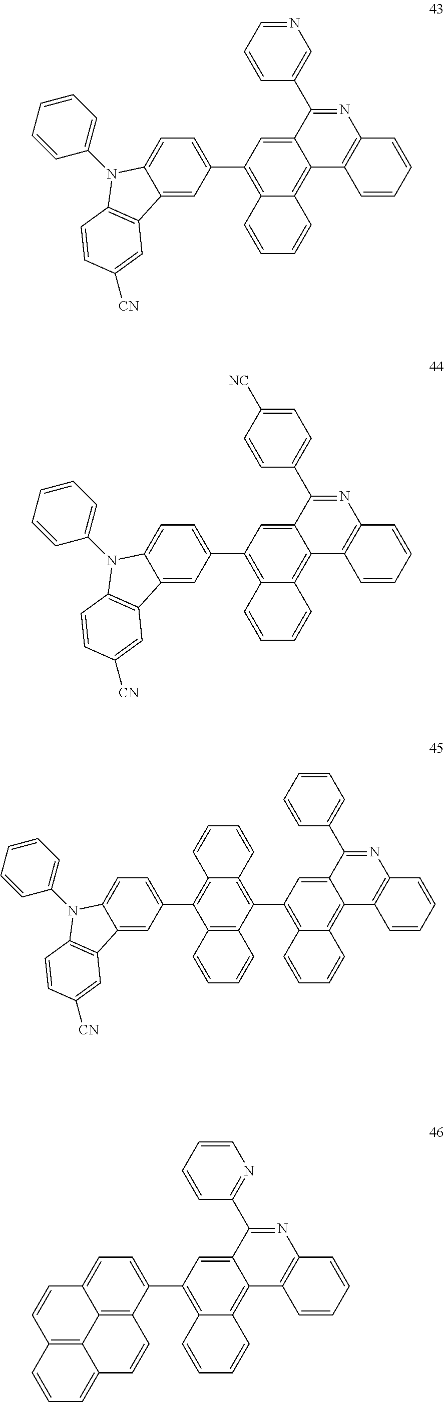 [SMILES: N#Cc1ccc2c(c1)c1cc(-c3cc4c(-c5cccnc5)nc5ccccc5c4c4ccccc34)ccc1n2-c1ccccc1 ; N#Cc1ccc(-c2nc3ccccc3c3c2cc(-c2ccc4c(c2)c2cc(C#N)ccc2n4-c2ccccc2)c2ccccc23)cc1 ; N#Cc1ccc2c(c1)c1cc(-c3c4ccccc4c(-c4cc5c(-c6ccccc6)nc6ccccc6c5c5ccccc45)c4ccccc34)ccc1n2-c1ccccc1 ; c1ccc(-c2nc3ccccc3c3c2cc(-c2ccc4ccc5cccc6ccc2c4c56)c2ccccc23)nc1]

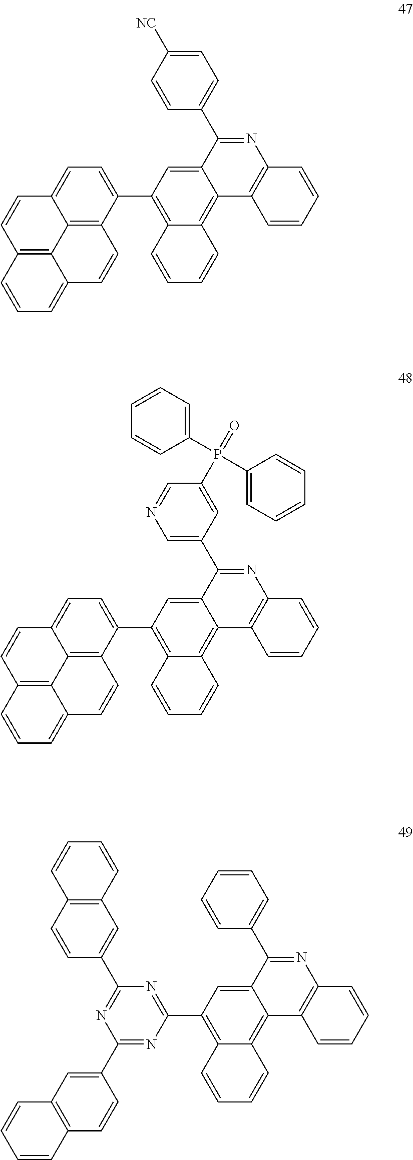 [SMILES: N#Cc1ccc(-c2nc3ccccc3c3c2cc(-c2ccc4ccc5cccc6ccc2c4c56)c2ccccc23)cc1 ; O=P(c1ccccc1)(c1ccccc1)c1cncc(-c2nc3ccccc3c3c2cc(-c2ccc4ccc5cccc6ccc2c4c56)c2ccccc23)c1 ; c1ccc(-c2nc3ccccc3c3c2cc(-c2nc(-c4ccc5ccccc5c4)nc(-c4ccc5ccccc5c4)n2)c2ccccc23)cc1]

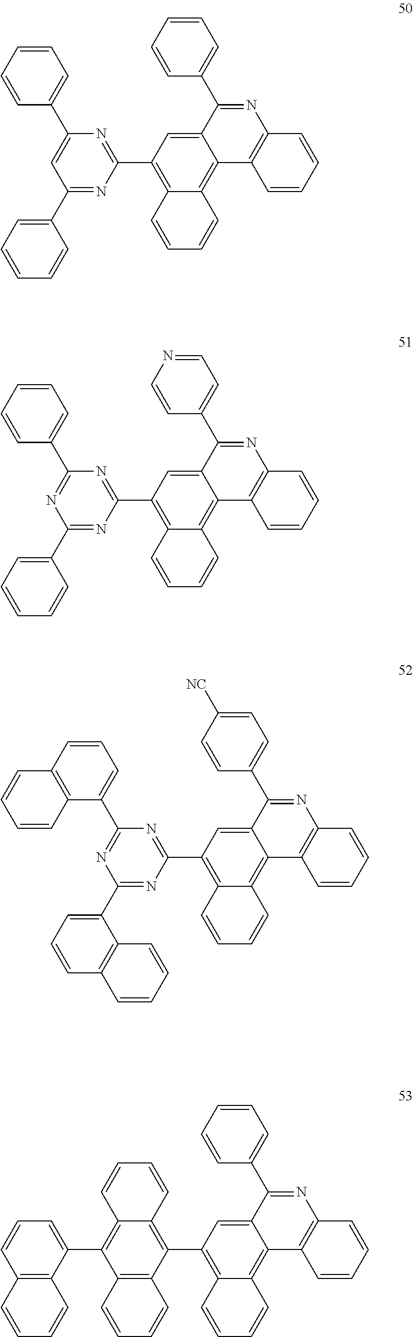 [SMILES: c1ccc(-c2cc(-c3ccccc3)nc(-c3cc4c(-c5ccccc5)nc5ccccc5c4c4ccccc34)n2)cc1 ; c1ccc(-c2nc(-c3ccccc3)nc(-c3cc4c(-c5ccncc5)nc5ccccc5c4c4ccccc34)n2)cc1 ; N#Cc1ccc(-c2nc3ccccc3c3c2cc(-c2nc(-c4cccc5ccccc45)nc(-c4cccc5ccccc45)n2)c2ccccc23)cc1 ; c1ccc(-c2nc3ccccc3c3c2cc(-c2c4ccccc4c(-c4cccc5ccccc45)c4ccccc24)c2ccccc23)cc1]

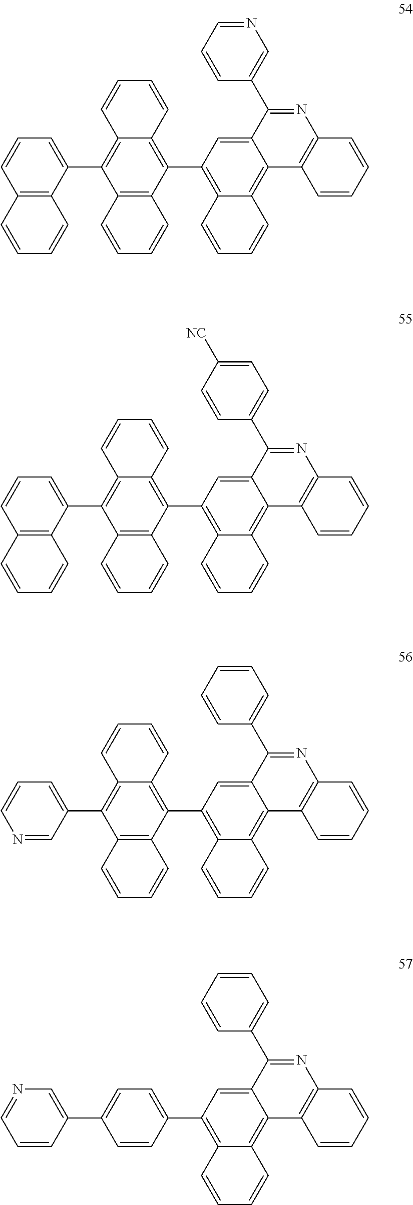 [SMILES: c1cncc(-c2nc3ccccc3c3c2cc(-c2c4ccccc4c(-c4cccc5ccccc45)c4ccccc24)c2ccccc23)c1 ; N#Cc1ccc(-c2nc3ccccc3c3c2cc(-c2c4ccccc4c(-c4cccc5ccccc45)c4ccccc24)c2ccccc23)cc1 ; c1ccc(-c2nc3ccccc3c3c2cc(-c2c4ccccc4c(-c4cccnc4)c4ccccc24)c2ccccc23)cc1 ; c1ccc(-c2nc3ccccc3c3c2cc(-c2ccc(-c4cccnc4)cc2)c2ccccc23)cc1]

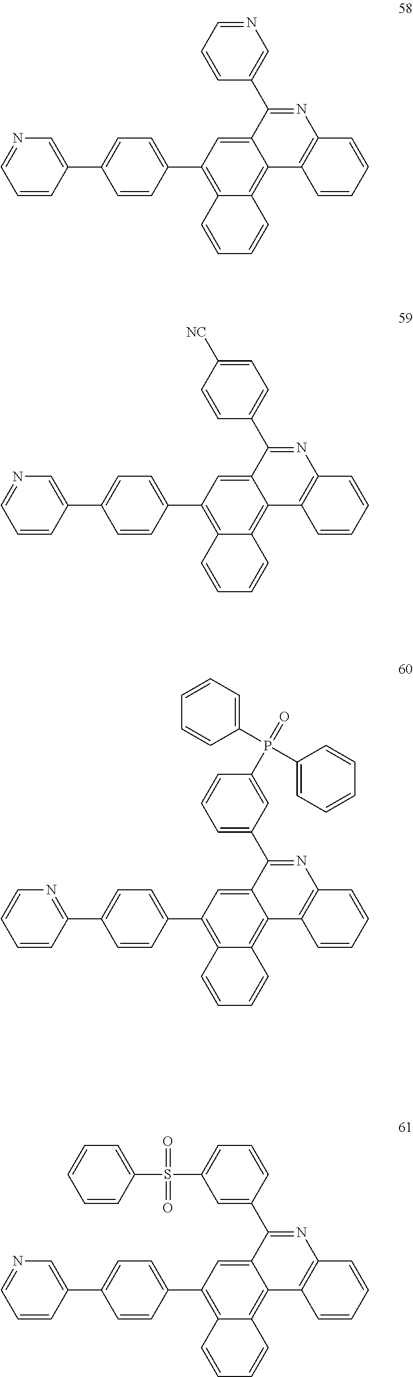 [SMILES: c1cncc(-c2ccc(-c3cc4c(-c5cccnc5)nc5ccccc5c4c4ccccc34)cc2)c1 ; N#Cc1ccc(-c2nc3ccccc3c3c2cc(-c2ccc(-c4cccnc4)cc2)c2ccccc23)cc1 ; O=P(c1ccccc1)(c1ccccc1)c1cccc(-c2nc3ccccc3c3c2cc(-c2ccc(-c4ccccn4)cc2)c2ccccc23)c1 ; O=S(=O)(c1ccccc1)c1cccc(-c2nc3ccccc3c3c2cc(-c2ccc(-c4cccnc4)cc2)c2ccccc23)c1]

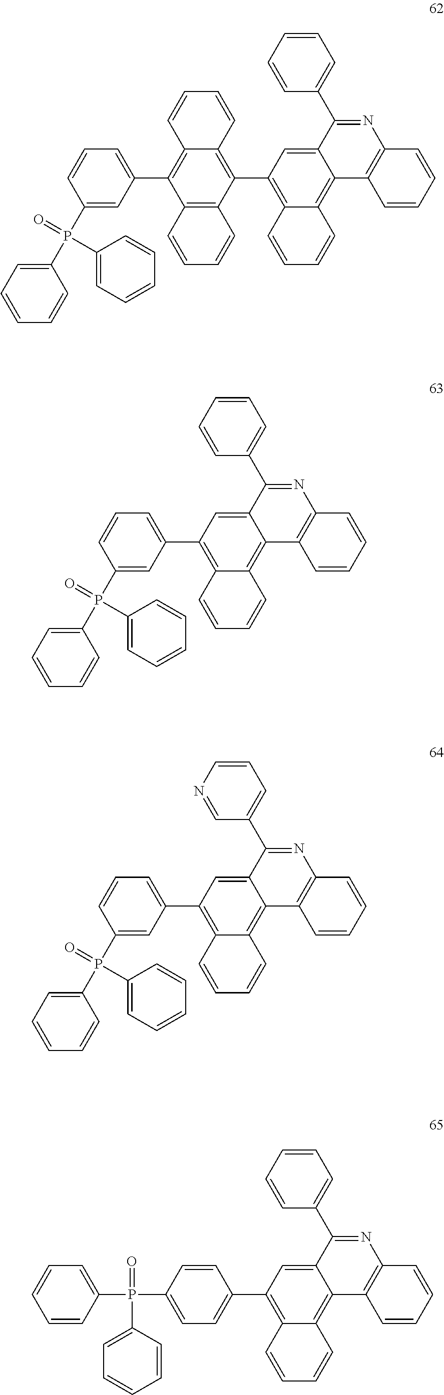 [SMILES: O=P(c1ccccc1)(c1ccccc1)c1cccc(-c2c3ccccc3c(-c3cc4c(-c5ccccc5)nc5ccccc5c4c4ccccc34)c3ccccc23)c1 ; O=P(c1ccccc1)(c1ccccc1)c1cccc(-c2cc3c(-c4ccccc4)nc4ccccc4c3c3ccccc23)c1 ; O=P(c1ccccc1)(c1ccccc1)c1cccc(-c2cc3c(-c4cccnc4)nc4ccccc4c3c3ccccc23)c1 ; O=P(c1ccccc1)(c1ccccc1)c1ccc(-c2cc3c(-c4ccccc4)nc4ccccc4c3c3ccccc23)cc1]

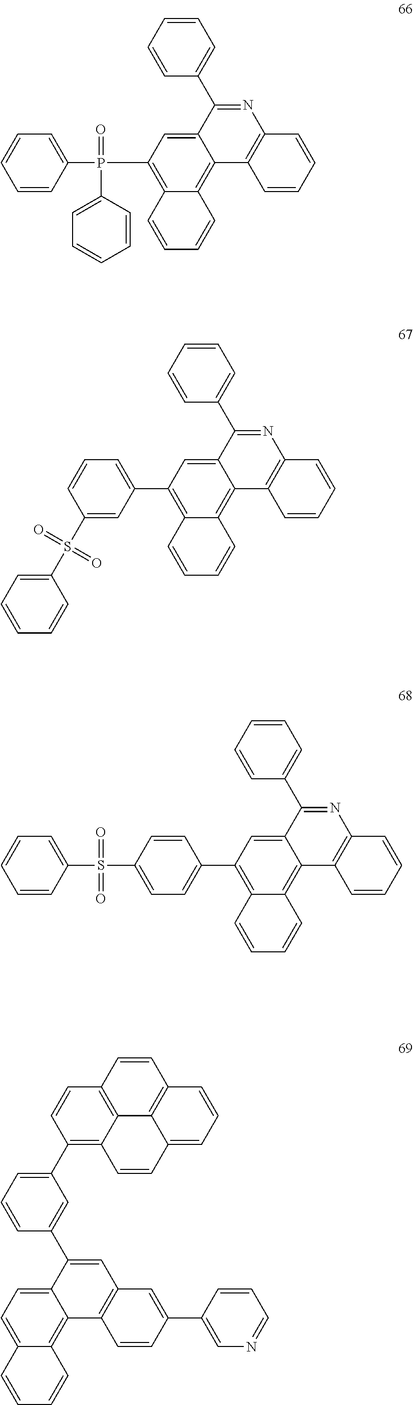 [SMILES: O=P(c1ccccc1)(c1ccccc1)c1cc2c(-c3ccccc3)nc3ccccc3c2c2ccccc12 ; O=S(=O)(c1ccccc1)c1cccc(-c2cc3c(-c4ccccc4)nc4ccccc4c3c3ccccc23)c1 ; O=S(=O)(c1ccccc1)c1ccc(-c2cc3c(-c4ccccc4)nc4ccccc4c3c3ccccc23)cc1 ; c1cncc(-c2ccc3c(c2)cc(-c2cccc(-c4ccc5ccc6cccc7ccc4c5c67)c2)c2ccc4ccccc4c23)c1]

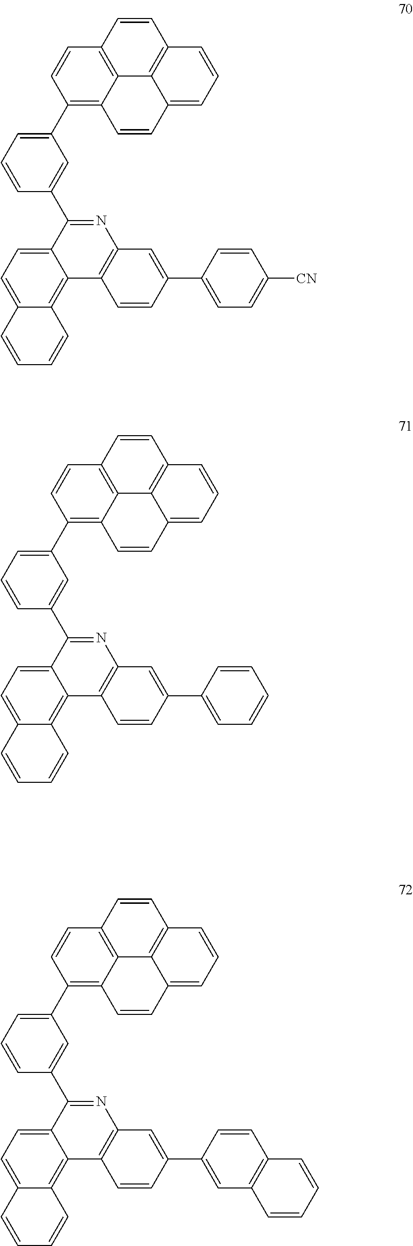 [SMILES: N#Cc1ccc(-c2ccc3c(c2)nc(-c2cccc(-c4ccc5ccc6cccc7ccc4c5c67)c2)c2ccc4ccccc4c23)cc1 ; c1ccc(-c2ccc3c(c2)nc(-c2cccc(-c4ccc5ccc6cccc7ccc4c5c67)c2)c2ccc4ccccc4c23)cc1 ; c1cc(-c2nc3cc(-c4ccc5ccccc5c4)ccc3c3c2ccc2ccccc23)cc(-c2ccc3ccc4cccc5ccc2c3c45)c1]

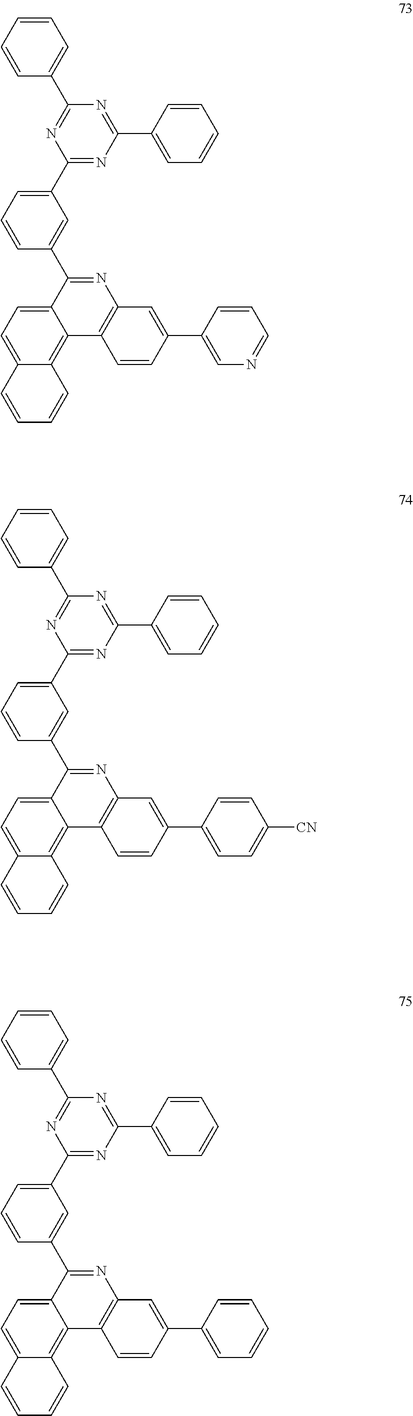 [SMILES: c1ccc(-c2nc(-c3ccccc3)nc(-c3cccc(-c4nc5cc(-c6cccnc6)ccc5c5c4ccc4ccccc45)c3)n2)cc1 ; N#Cc1ccc(-c2ccc3c(c2)nc(-c2cccc(-c4nc(-c5ccccc5)nc(-c5ccccc5)n4)c2)c2ccc4ccccc4c23)cc1 ; c1ccc(-c2ccc3c(c2)nc(-c2cccc(-c4nc(-c5ccccc5)nc(-c5ccccc5)n4)c2)c2ccc4ccccc4c23)cc1]

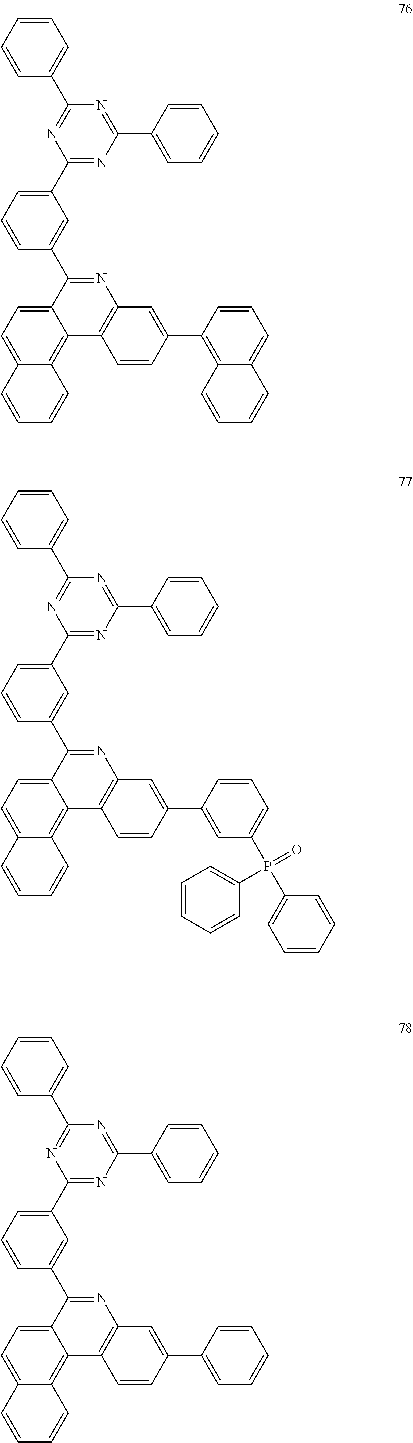 [SMILES: c1ccc(-c2nc(-c3ccccc3)nc(-c3cccc(-c4nc5cc(-c6cccc7ccccc67)ccc5c5c4ccc4ccccc45)c3)n2)cc1 ; O=P(c1ccccc1)(c1ccccc1)c1cccc(-c2ccc3c(c2)nc(-c2cccc(-c4nc(-c5ccccc5)nc(-c5ccccc5)n4)c2)c2ccc4ccccc4c23)c1 ; c1ccc(-c2ccc3c(c2)nc(-c2cccc(-c4nc(-c5ccccc5)nc(-c5ccccc5)n4)c2)c2ccc4ccccc4c23)cc1]

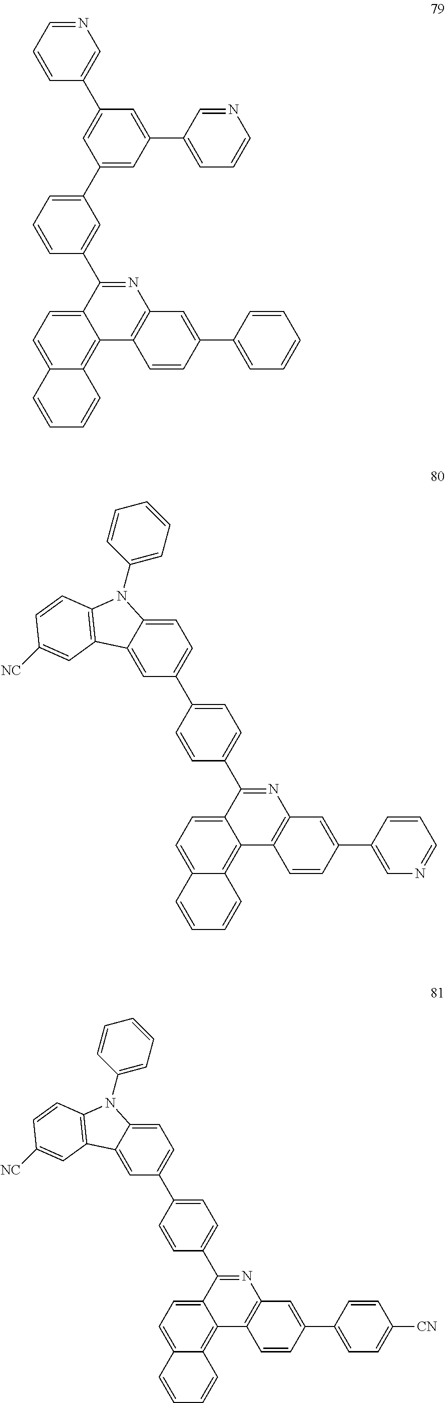 [SMILES: c1ccc(-c2ccc3c(c2)nc(-c2cccc(-c4cc(-c5cccnc5)cc(-c5cccnc5)c4)c2)c2ccc4ccccc4c23)cc1 ; N#Cc1ccc2c(c1)c1cc(-c3ccc(-c4nc5cc(-c6cccnc6)ccc5c5c4ccc4ccccc45)cc3)ccc1n2-c1ccccc1 ; N#Cc1ccc(-c2ccc3c(c2)nc(-c2ccc(-c4ccc5c(c4)c4cc(C#N)ccc4n5-c4ccccc4)cc2)c2ccc4ccccc4c23)cc1]

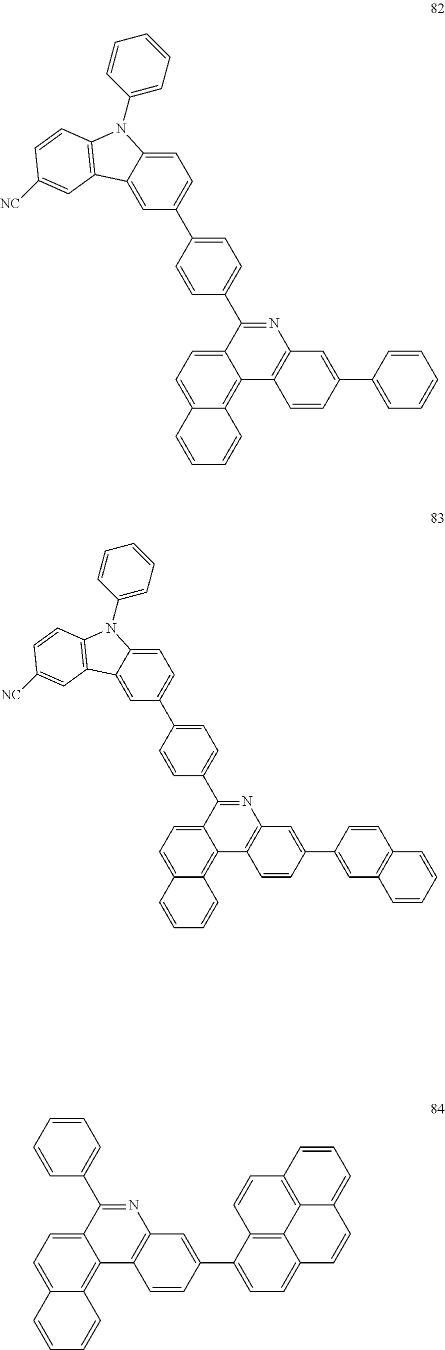 [SMILES: N#Cc1ccc2c(c1)c1cc(-c3ccc(-c4nc5cc(-c6ccccc6)ccc5c5c4ccc4ccccc45)cc3)ccc1n2-c1ccccc1 ; N#Cc1ccc2c(c1)c1cc(-c3ccc(-c4nc5cc(-c6ccc7ccccc7c6)ccc5c5c4ccc4ccccc45)cc3)ccc1n2-c1ccccc1 ; c1ccc(-c2nc3cc(-c4ccc5ccc6cccc7ccc4c5c67)ccc3c3c2ccc2ccccc23)cc1]

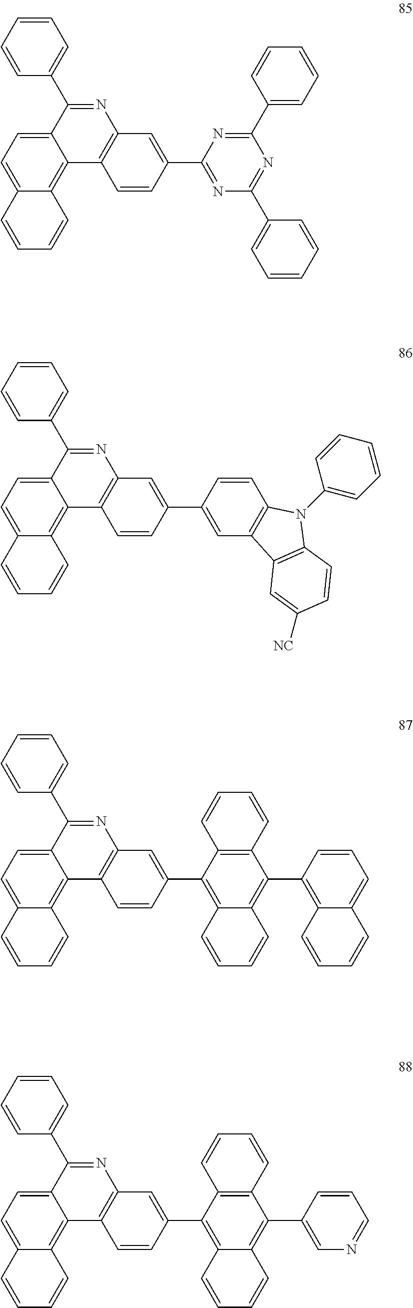 [SMILES: c1ccc(-c2nc(-c3ccccc3)nc(-c3ccc4c(c3)nc(-c3ccccc3)c3ccc5ccccc5c34)n2)cc1 ; N#Cc1ccc2c(c1)c1cc(-c3ccc4c(c3)nc(-c3ccccc3)c3ccc5ccccc5c34)ccc1n2-c1ccccc1 ; c1ccc(-c2nc3cc(-c4c5ccccc5c(-c5cccc6ccccc56)c5ccccc45)ccc3c3c2ccc2ccccc23)cc1 ; c1ccc(-c2nc3cc(-c4c5ccccc5c(-c5cccnc5)c5ccccc45)ccc3c3c2ccc2ccccc23)cc1]

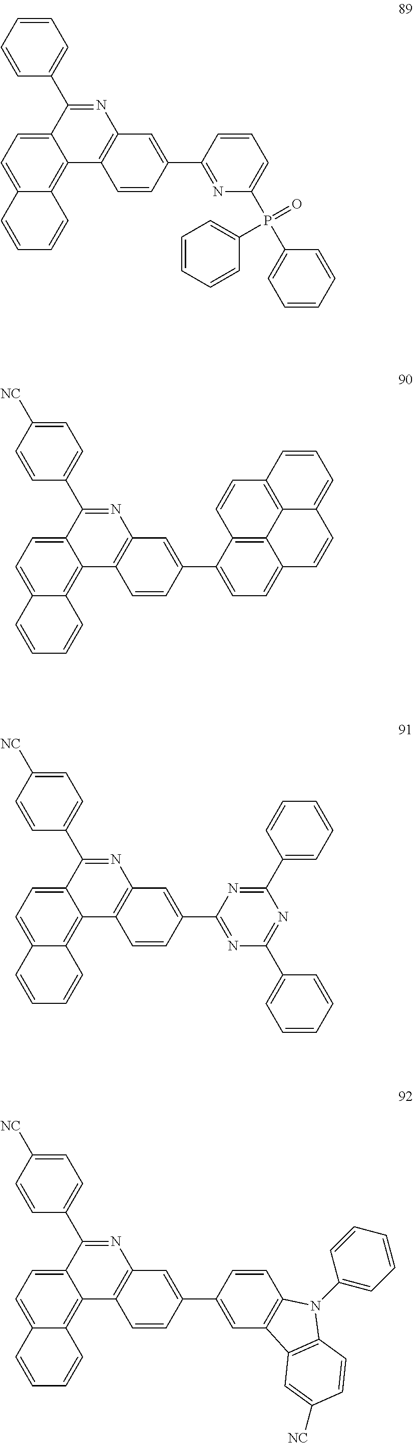 [SMILES: O=P(c1ccccc1)(c1ccccc1)c1cccc(-c2ccc3c(c2)nc(-c2ccccc2)c2ccc4ccccc4c23)n1 ; N#Cc1ccc(-c2nc3cc(-c4ccc5ccc6cccc7ccc4c5c67)ccc3c3c2ccc2ccccc23)cc1 ; N#Cc1ccc(-c2nc3cc(-c4nc(-c5ccccc5)nc(-c5ccccc5)n4)ccc3c3c2ccc2ccccc23)cc1 ; N#Cc1ccc(-c2nc3cc(-c4ccc5c(c4)c4cc(C#N)ccc4n5-c4ccccc4)ccc3c3c2ccc2ccccc23)cc1]

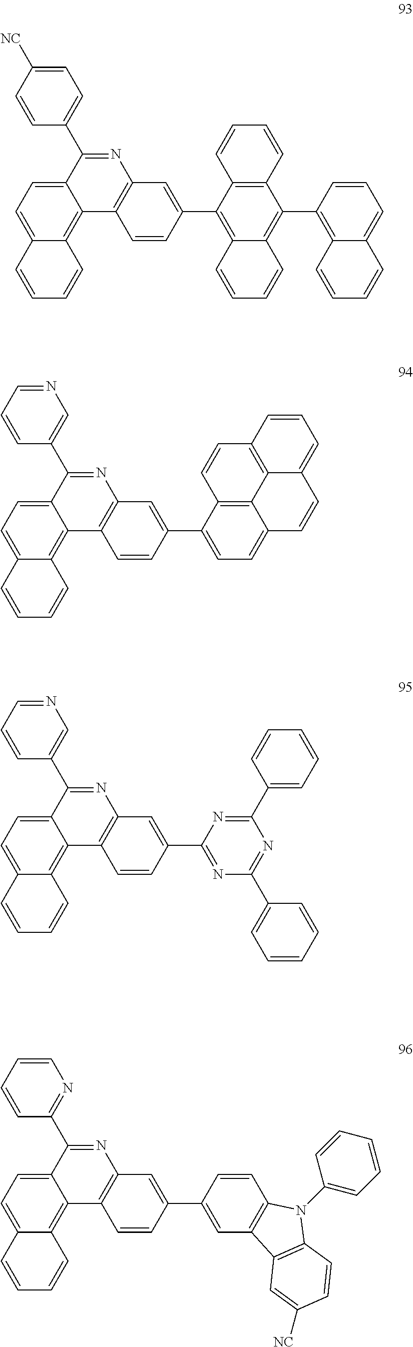 [SMILES: N#Cc1ccc(-c2nc3cc(-c4c5ccccc5c(-c5cccc6ccccc56)c5ccccc45)ccc3c3c2ccc2ccccc23)cc1 ; c1cncc(-c2nc3cc(-c4ccc5ccc6cccc7ccc4c5c67)ccc3c3c2ccc2ccccc23)c1 ; c1ccc(-c2nc(-c3ccccc3)nc(-c3ccc4c(c3)nc(-c3cccnc3)c3ccc5ccccc5c34)n2)cc1 ; N#Cc1ccc2c(c1)c1cc(-c3ccc4c(c3)nc(-c3ccccn3)c3ccc5ccccc5c34)ccc1n2-c1ccccc1]

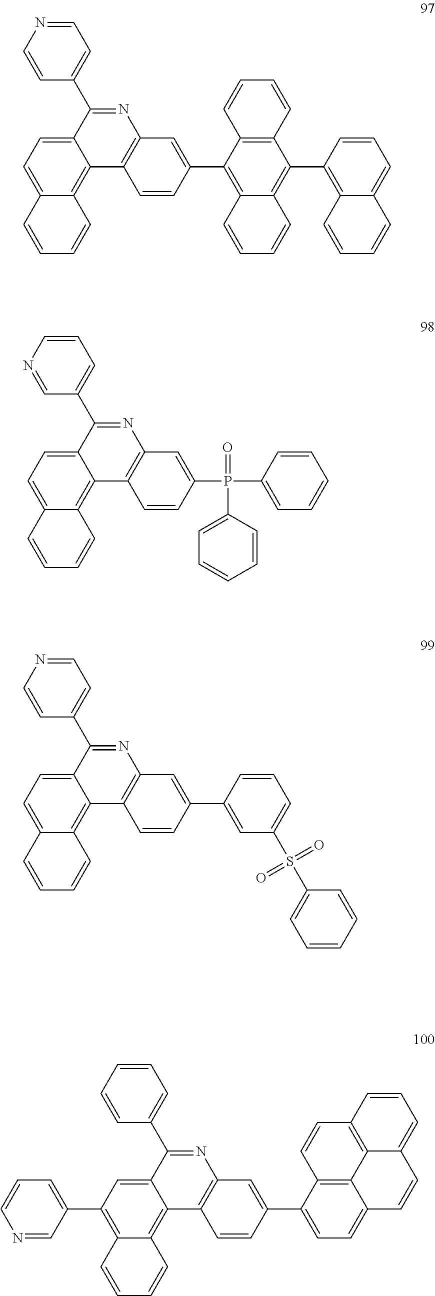 [SMILES: c1ccc2c(-c3c4ccccc4c(-c4ccc5c(c4)nc(-c4ccncc4)c4ccc6ccccc6c45)c4ccccc34)cccc2c1 ; O=P(c1ccccc1)(c1ccccc1)c1ccc2c(c1)nc(-c1cccnc1)c1ccc3ccccc3c12 ; O=S(=O)(c1ccccc1)c1cccc(-c2ccc3c(c2)nc(-c2ccncc2)c2ccc4ccccc4c23)c1 ; c1ccc(-c2nc3cc(-c4ccc5ccc6cccc7ccc4c5c67)ccc3c3c2cc(-c2cccnc2)c2ccccc23)cc1]

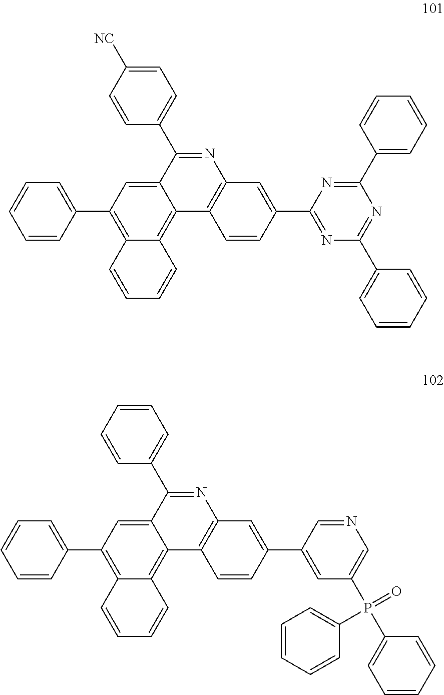 [SMILES: N#Cc1ccc(-c2nc3cc(-c4nc(-c5ccccc5)nc(-c5ccccc5)n4)ccc3c3c2cc(-c2ccccc2)c2ccccc23)cc1 ; O=P(c1ccccc1)(c1ccccc1)c1cncc(-c2ccc3c(c2)nc(-c2ccccc2)c2cc(-c4ccccc4)c4ccccc4c23)c1]

An organic light-emitting device according to an embodiment may include a first electrode, a second electrode, and an organic layer disposed between the first electrode and the second electrode. The organic layer includes the compound represented by Formula 1 above.

The organic layer may include at least one layer selected from a hole injection layer, a hole transport layer, a functional layer having a hole injection function and a hole transport function (hereinafter referred to as “H-functional layer”), a buffer layer, an electron blocking layer, an emission layer, a hole blocking layer, an electron transport layer, an electron injection layer, and a functional layer having an electron transport function and an electron injection function (hereinafter referred to as “E-functional layer”).

For example, the organic layer may include an electron transport layer, an electron injection layer, or a functional layer having an electron transport function and an electron injection function. For example, the organic layer may include an electron transport layer.

According to an embodiment, the organic light-emitting device may include an electron injection layer, an electron transport layer, an emission layer, a hole injection layer, a hole transport layer, or a H-functional layer, and the emission layer may include an anthracene-based compound, an arylamine-based compound, or a styryl-based compound.

According to another embodiment, the organic light-emitting device may include an electron injection layer, an electron transport layer, an emission layer, a hole injection layer, a hole transport layer, or a H-functional layer. The emission layer may include a red layer, a green layer, a blue layer, and a white layer. Any one of these layers may include a phosphorescent compound. The hole injection layer, the hole transport layer, or the H-functional layer may include a charge-generating material. The charge-generating material may be a p-dopant. The p-dopant may be a quinone derivative, a metal oxide, or a cyano group-containing compound.

The organic layer may include an electron transport layer that includes, in addition to a compound represented by Formula 1 according to an embodiment, a metal complex. The metal complex may be a Li complex.

The term “organic layer” used herein refers to a single layer and/or a plurality of layers disposed between the first electrode and the second electrode of an organic light-emitting device.

The organic layer includes an emission layer that may include the compound represented by Formula 1. In some embodiments, the organic layer may include at least one layer selected from a hole injection layer, a hole transport layer, and an H-functional layer, wherein at least one layer selected from the hole injection layer, the hole transport layer, and the H-functional layer includes the compound represented by Formula 1.

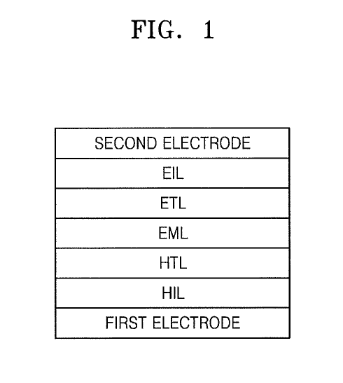

FIG. 1 is a schematic cross-sectional view of an organic light-emitting device according to an embodiment. Hereinafter, the structure of an organic light-emitting device according to an embodiment and a method of manufacturing an organic light-emitting device according to an embodiment will be described in connection with FIG. 1.

A substrate (not shown) may be any one of various substrates that are suitable for an organic light-emitting device. The substrate may be a glass substrate or a transparent plastic substrate, with excellent mechanical strength, thermal stability, transparency, surface smoothness, ease of handling, and water repellency.

The first electrode may be formed by, for example, depositing or sputtering a material for a first electrode on the substrate. When the first electrode is an anode, the material for the first electrode may be selected from materials with a high work function such that holes may be easily injected. The first electrode may be a reflective electrode or a transmission electrode. The material for the first electrode may be a transparent and highly conductive material. Examples of such a material include indium tin oxide (ITO), indium zinc oxide (IZO), tin oxide (SnO₂), and zinc oxide (ZnO). According to an embodiment, to form the first electrode as a reflective electrode, magnesium (Mg), aluminum (Al), aluminum-lithium (Al—Li), calcium (Ca), magnesium-indium (Mg—In), or magnesium-silver (Mg—Ag) may be used.

The first electrode may have a single- or multi-layered structure. For example, the first electrode may have a three-layered structure of ITO/Ag/ITO.

An organic layer is disposed on the first electrode.

The organic layer may include a hole injection layer, a hole transport layer, a buffer layer (not shown), an emission layer, an electron transport layer, or an electron injection layer.

A hole injection layer (HIL) may be formed on the first electrode by using a suitable method, such as vacuum deposition, spin coating, casting, Langmuir-Blodgett (LB) deposition, or the like.

When the hole injection layer is formed using vacuum deposition, vacuum deposition conditions may vary according to the compound that is used to form the hole injection layer, and the desired structure and thermal properties of the hole injection layer to be formed. For example, vacuum deposition may be performed at a temperature of about 100° C. to about 500° C., a pressure of about 10⁻⁸ torr to about 10⁻³ torr, and a deposition rate of about 0.01 to about 100 Å/sec.

When the hole injection layer is formed using spin coating, the coating conditions may vary according to the compound that is used to form the hole injection layer, and the desired structure and thermal properties of the hole injection layer to be formed. For example, the coating rate may be in the range of about 2,000 rpm to about 5,000 rpm, and a temperature at which heat treatment is performed to remove a solvent after coating may be in the range of about 80° C. to about 200° C.

A suitable hole injection material may be used. Examples of a suitable hole injection material include N,N′-diphenyl-N,N′-bis-[4-(phenyl-m-tolyl-amino)-phenyl]-biphenyl-4,4′-diamine (DNTPD), a phthalocyanine compound such as copper phthalocyanine, 4,4′,4″-tris(3-methylphenylphenylamino) triphenylamine (m-MTDATA), N,N′-di(1-naphthyl)-N,N′-diphenylbenzidine (NPB), TDATA, 2-TNATA, a polyaniline/dodecylbenzenesulfonic acid (pani/DBSA), poly(3,4-ethylenedioxythiophene)/poly(4-styrenesulfonate) (PEDOT/PSS), polyaniline/camphor sulfonic acid (pani/CSA), and (polyaniline)/poly(4-styrenesulfonate) (PANI/PSS).

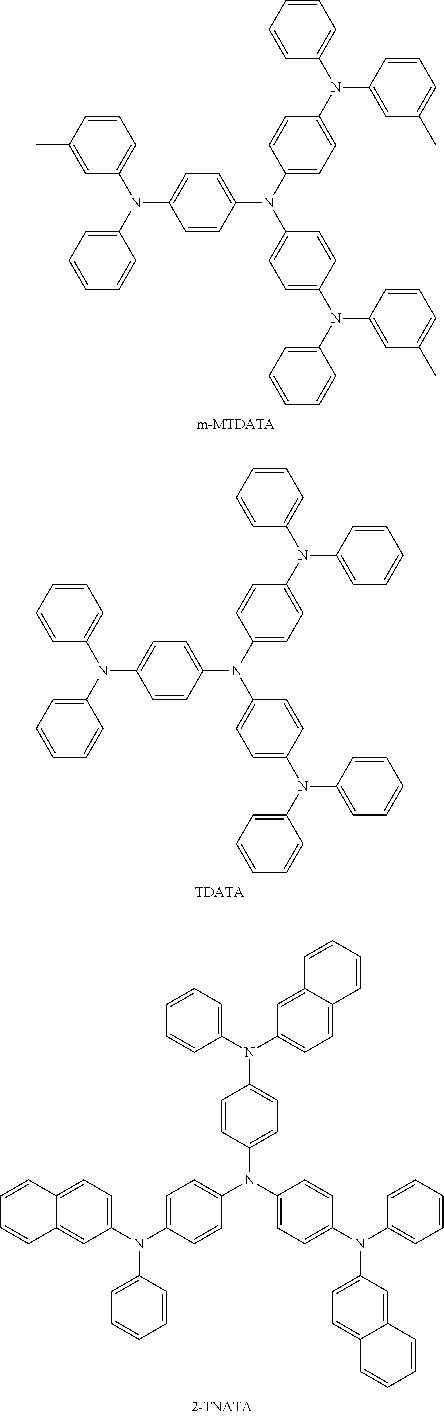

A thickness of the hole injection layer may be in a range of about 100 Å to about 10,000 Å, for example, about 100 Å to about 1,000 Å. If the thickness of the hole injection layer is within the ranges described above, excellent electron injection characteristics may be obtained without a substantial increase in driving voltage.

A hole transport layer (HTL) may be formed on the hole injection layer by using vacuum deposition, spin coating, casting, or LB. When the hole transport layer is formed by vacuum deposition or spin coating, the deposition or coating conditions may be similar to those applied to form the hole injection layer although the deposition or coating conditions may vary according to the material that is used to form the hole transport layer.

For use as a hole transport material, a suitable hole transport material may be used. Examples of a suitable hole transport material include a carbazole derivative, such as N-phenylcarbazole or polyvinylcarbazol, N,N′-bis(3-methylphenyl)-N,N′-diphenyl-[1,1-biphenyl]-4,4′-diamine (TPD), 4,4′,4″-tris(N-carbazolyl)triphenylamine (TCTA), and N,N′-di(1-naphthyl)-N,N′-diphenylbenzidine (NPB).

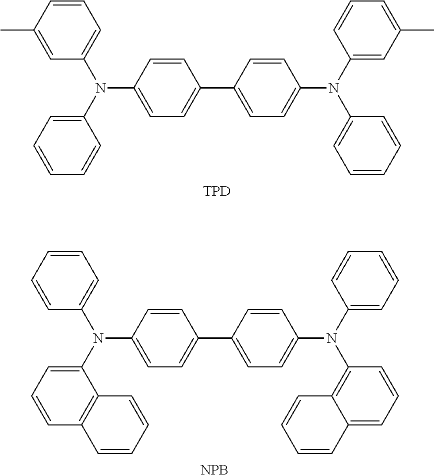

A thickness of the hole transport layer may be in a range of about 50 Å to about 2,000 Å, for example, about 100 Å to about 1,500 Å. When the thickness of the hole transport layer is within these ranges, the hole transport layer may have satisfactory hole transporting ability without a substantial increase in driving voltage.

The H-functional layer may include at least one material selected from the materials used to form a hole injection layer and the materials used to form a hole transport layer. A thickness of the H-functional layer may be in a range of about 100 Å to about 10,000 Å, for example, about 100 Å to about 1,000 Å. When the thickness of the H-functional layer is within these ranges, satisfactory hole injection and transport characteristics may be obtained without a substantial increase in driving voltage.

In addition, at least one layer of the hole injection layer, the hole transport layer, and the H-functional layer may include at least one of a compound represented by Formula 300 below and a compound represented by Formula 350 below:

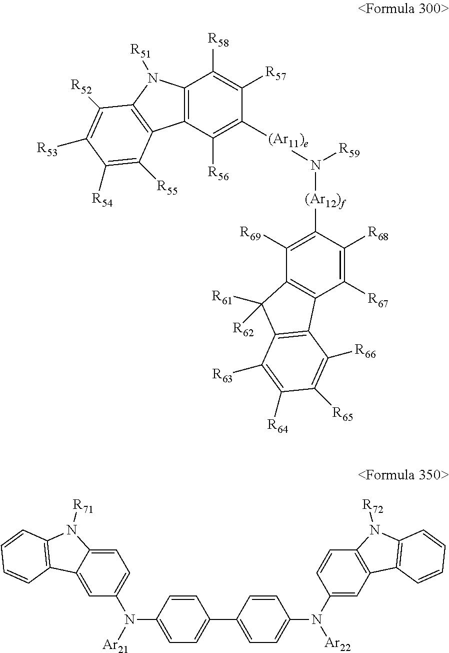

wherein in Formulae 300 and 350, Ar₁₁ and Ar₁₂ are each independently, a substituted or unsubstituted C₅-C₆₀ arylene group. Ar₁₁ and Ar₁₂, may be understood by referring to the explanation presented in connection with L₁.

e and f in Formula 300 may be each independently an integer of 0 to 5, or 0, 1 or 2. For example, e may be 1 and f may be 0.

R₅₁ to R₅₈, R₆₁ to R₆₉, and R₇₁ and R₇₂ in Formulae 300 and 350 may be each independently a hydrogen, a deuterium, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ aryl group, a substituted or unsubstituted C₅-C₆₀ aryloxy group, or a substituted or unsubstituted C₅-C₆₀ arylthio group. For example, R₅₁ to R₅₈, R₆₁ to R₆₉, and R₇₁ and R₇₂ may be each independently a hydrogen; a deuterium; a halogen atom; a hydroxyl group; a cyano group; a nitro group; an amino group; an amidino group; a hydrazine group; a hydrazone group; a carboxylic acid group or a salt thereof; a sulfonic acid group or a salt thereof; a phosphoric acid group or a salt thereof; a C₁-C₁₀ alkyl group (for example, a methyl group, an ethyl group, a propyl group, a butyl group, a pentyl group, or a hexyl group); a C₁-C₁₀ alkoxy group (for example, a methoxy group, an ethoxy group, a propoxy group, a butoxy group, or a pentoxy group); a C₁-C₁₀ alkyl group and a C₁-C₁₀ alkoxy group, each substituted with at least one selected from a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof; a phenyl group; a naphthyl group; anthryl group; a fluorenyl group; a pyrenyl group; and a phenyl group, a naphthyl group, anthryl group, a fluorenyl group and a pyrenyl group, each substituted with at least one selected from a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, and a C₁-C₁₀ alkoxy group.

R₅₉ in Formula 300 and Ar₂₁ and Ar₂₂ in Formula 350 may be one selected from a phenyl group; a naphthyl group; anthryl group; a biphenyl group; a pyridyl group; and a phenyl group, a naphthyl group, anthryl group, a biphenyl group and a pyridyl group, each substituted with at least one selected from a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

According to an embodiment, the compound represented by Formula 300 may be represented by Formula 300A below:

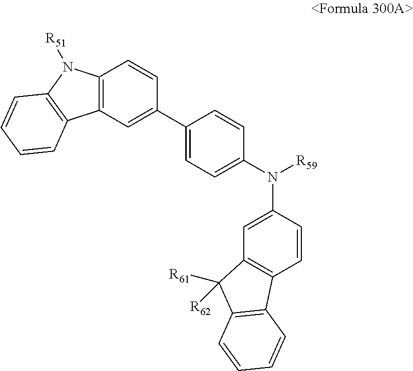

R₅₁, R₆₀, R₆₁, and R₅₉ in Formula 300A may be understood by referring to the description provided herein.

For example, at least one layer of the hole injection layer, the hole transport layer, and the H-functional layer may include at least one of Compounds 301 to 320 below.

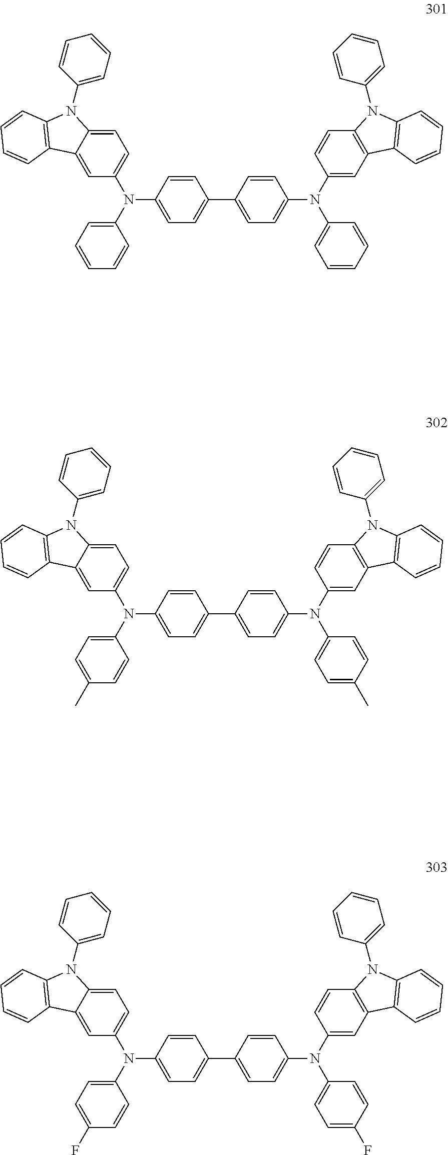 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

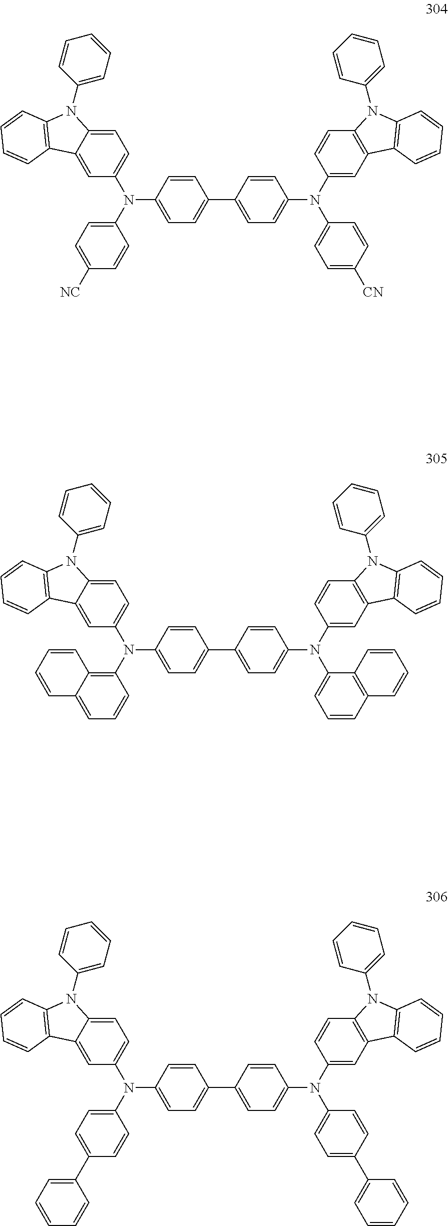 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1]

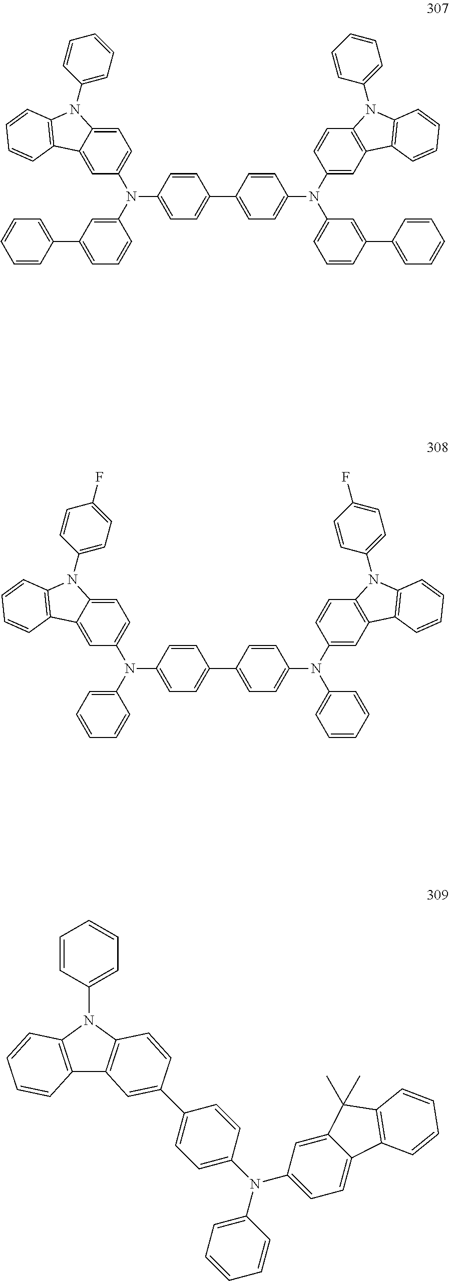 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; CC1(C)c2ccccc2-c2ccc(N(c3ccccc3)c3ccc(-c4ccc5c(c4)c4ccccc4n5-c4ccccc4)cc3)cc21]

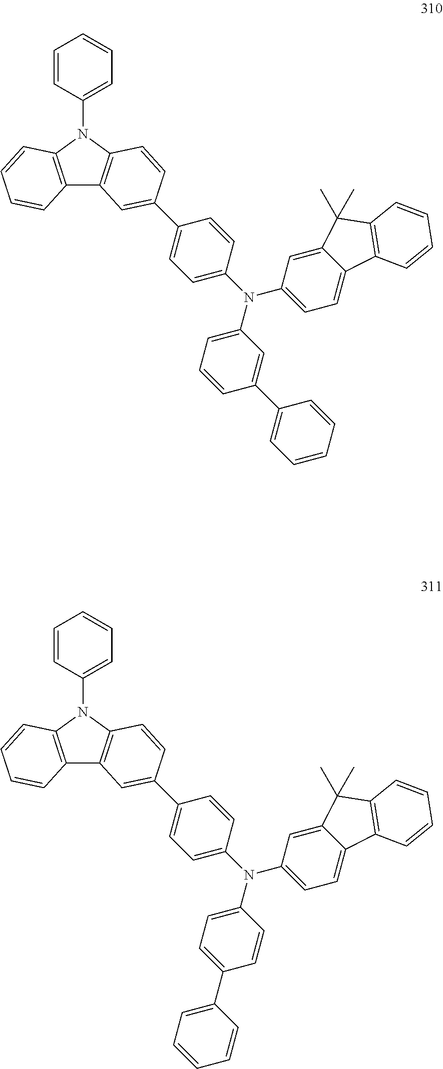 [SMILES: CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

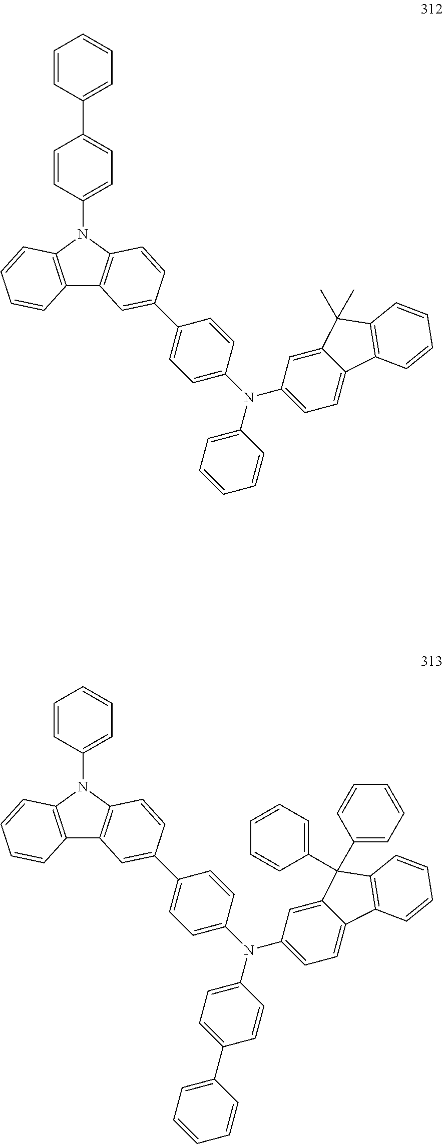 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

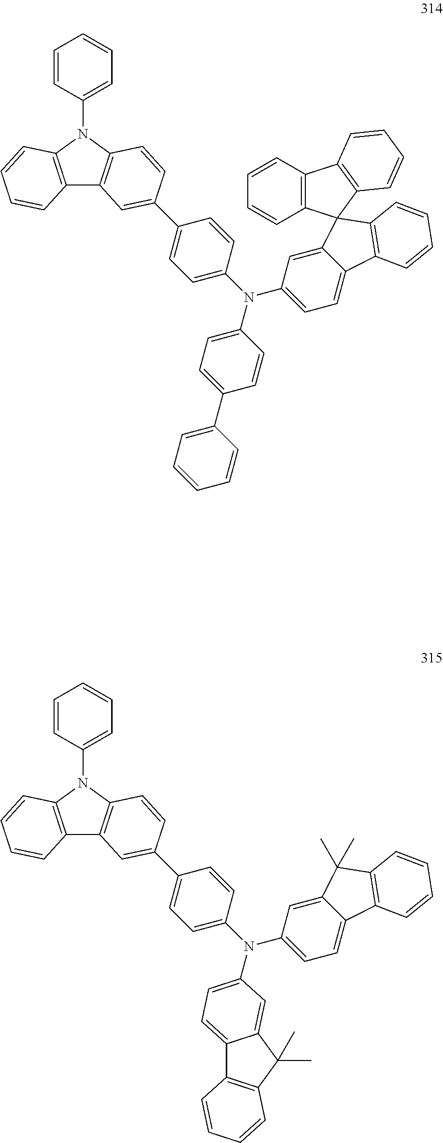 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

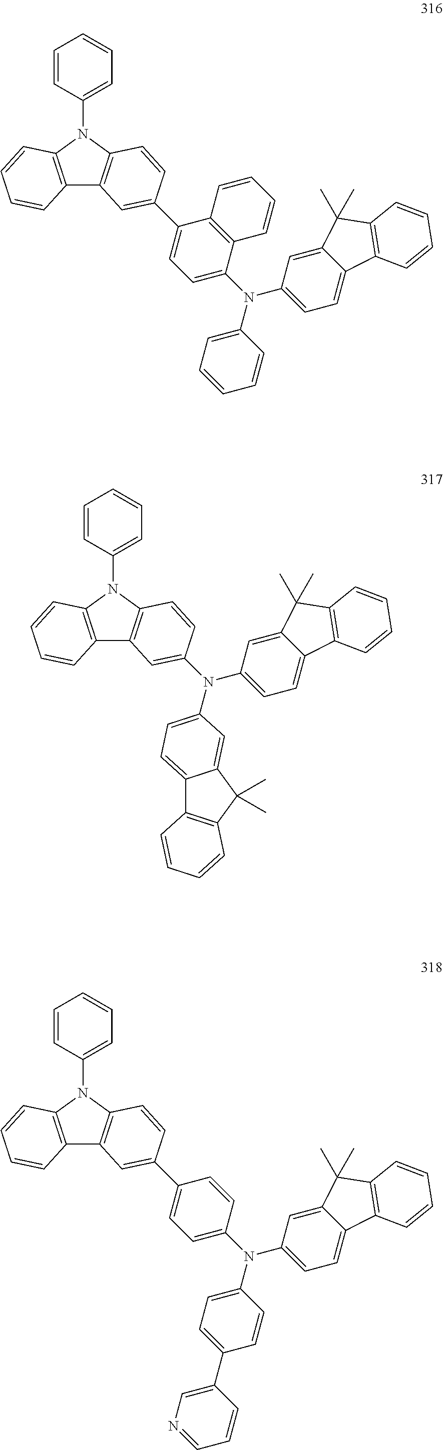 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

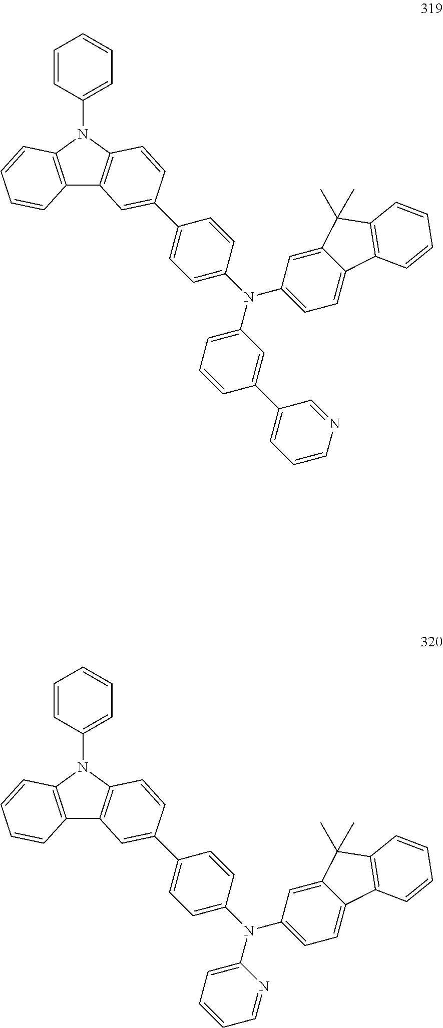 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

At least one of the hole injection layer, the hole transport layer, and the H-functional layer may further include a charge-generating material to increase conductivity of a layer, in addition to suitable hole injection materials, suitable hole transport materials, and/or suitable materials having both hole injection and hole transport capabilities.

The charge-generating material may be, for example, a p-dopant. The p-dopant may be one of a quinone derivative, a metal oxide, and a cyano group-containing compound, as examples. Examples of the p-dopant include a quinone derivative, such as tetracyanoquinonedimethane (TCNQ) or 2,3,5,6-tetrafluoro-tetracyano-1,4-benzoquinonedimethane (F4-TCNQ); a metal oxide, such as tungsten oxide or molybdenum oxide; and a cyano group-containing compound, such as Compound 200 below.

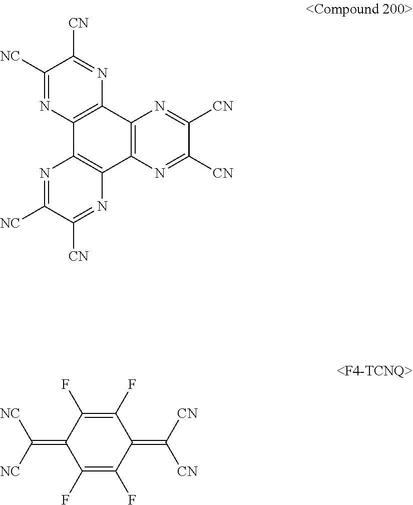 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

When the hole injection layer, the hole transport layer or the H-functional layer further includes a charge-generating material, the charge-generating material may be homogeneously dispersed or non-homogeneously distributed in the hole injection layer, the hole transport layer, and the H-functional layer.

A buffer layer may be disposed between at least one of the hole injection layer, the hole transport layer, and the H-functional layer, and an emission layer. The buffer layer may compensate for an optical resonance distance according to a wavelength of light emitted from the emission layer. Thus, efficiency of a formed organic light-emitting device may be improved. The buffer layer may include a suitable hole injection material and a suitable hole transport material. The buffer layer may include a material that is identical to one of materials included in the hole injection layer, the hole transport layer, and the H-functional layer formed under the buffer layer.

An emission layer (EML) may be formed on the hole transport layer, the H-functional layer, or the buffer layer by spin coating, casting, or a LB method. When the emission layer is formed by vacuum deposition or spin coating, the deposition and coating conditions may be similar to those for the formation of the hole injection layer, though the conditions for deposition and coating may vary according to the material that is used to form the emission layer.

The emission layer may be formed by using suitable luminescent materials. For example, the emission layer may be formed by using any suitable host and any suitable dopant. An example of the dopant may be any suitable fluorescent or phosphorescent dopant.

Examples of a suitable host include Alg₃, 4,4′-N,N′-dicarbazole-biphenyl (CBP), poly(n-vinylcarbazole)(PVK), 9,10-di(naphthalene-2-yl)anthracene (ADN), TCTA, 1,3,5-tris(N-phenylbenzimidazole-2-yl)benzene (TPBI), 3-tert-butyl-9,10-di(naphth-2-yl) anthracene (TBADN), E3, distyrylarylene (DSA), dmCBP (see the following chemical structure), and Compounds 501 to 509 illustrated below.

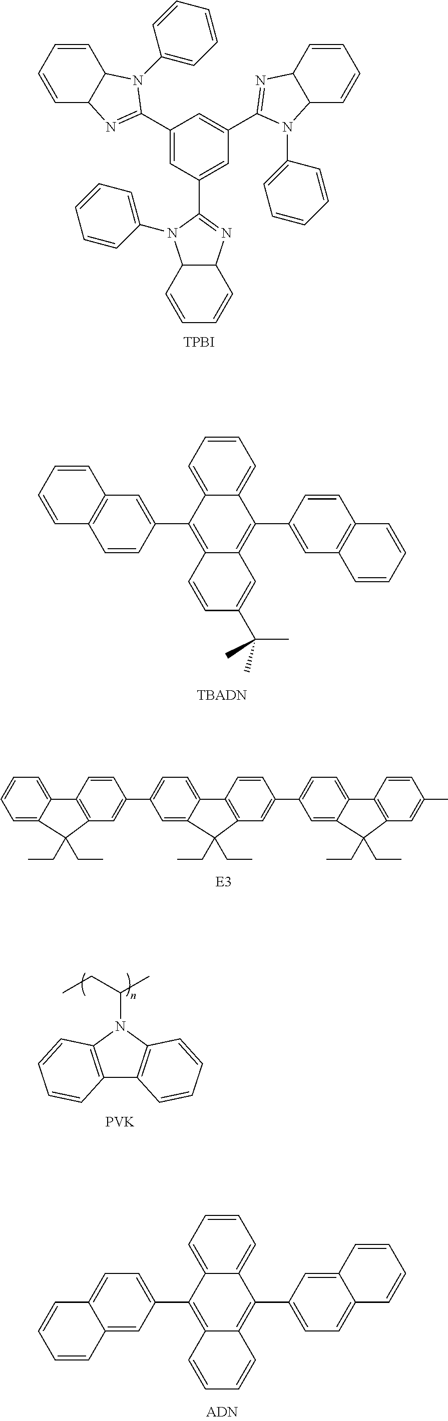

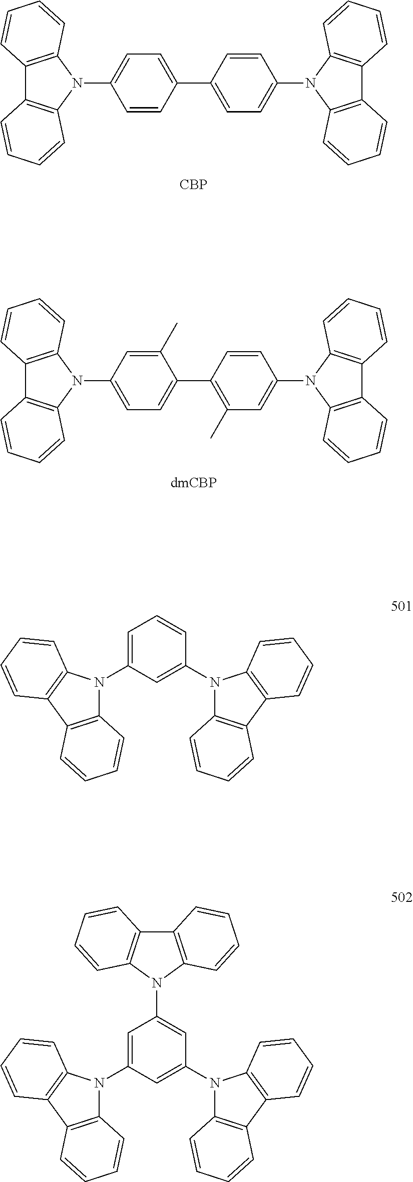 [SMILES: c1ccc2c(c1)c1ccccc1n2-c1ccc(-c2ccc(-n3c4ccccc4c4ccccc43)cc2)cc1 ; "CBP" ; Cc1cc(-n2c3ccccc3c3ccccc32)ccc1-c1ccc(-n2c3ccccc3c3ccccc32)cc1C ; "dmCBP" ; c1cc(-n2c3ccccc3c3ccccc32)cc(-n2c3ccccc3c3ccccc32)c1 ; c1ccc2c(c1)c1ccccc1n2-c1cc(-n2c3ccccc3c3ccccc32)cc(-n2c3ccccc3c3ccccc32)c1]

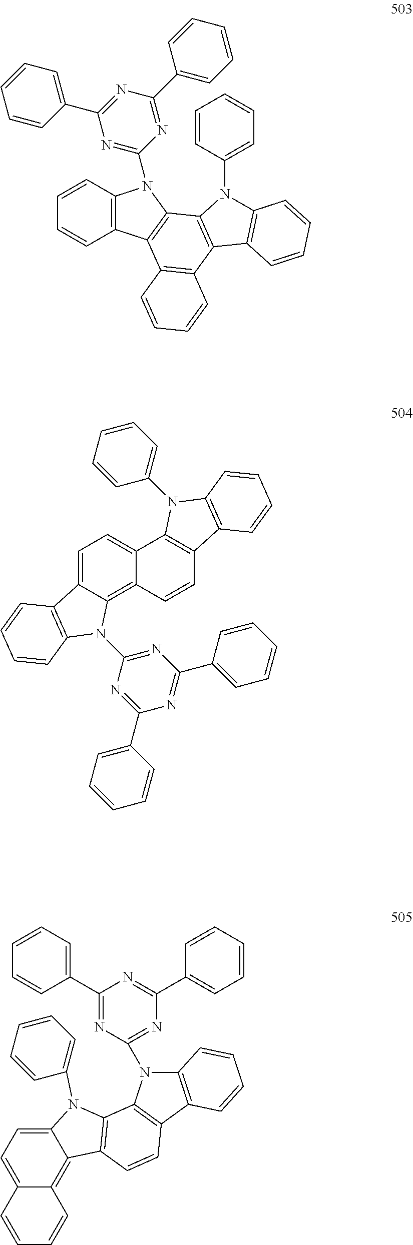 [SMILES: c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-c3ccccc3)nc(-n3c4ccccc4c4ccc5c(ccc6c7ccccc7n(-c7ccccc7)c65)c43)n2)cc1 ; c1ccc(-c2nc(-c3ccccc3)nc(-n3c4ccccc4c4ccc5c6c7ccccc7ccc6n(-c6ccccc6)c5c43)n2)cc1]

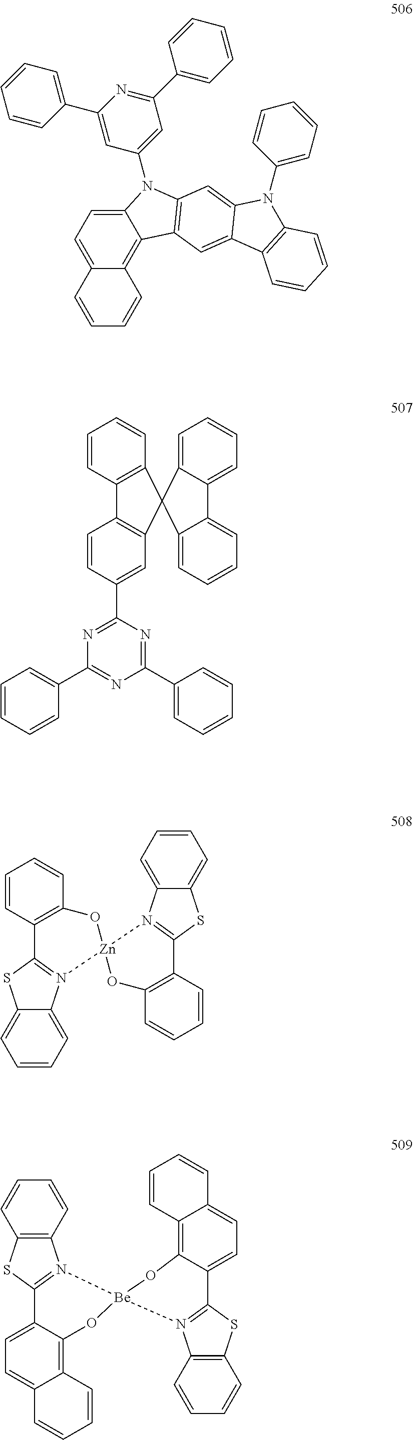

The host may be an anthracene-based compound represented by Formula 400 below:

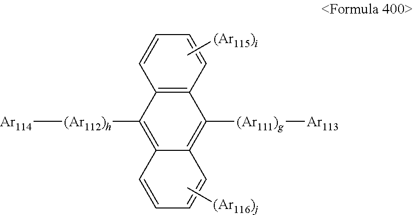

wherein, in Formula 400, Ar₁₁₁ and Ar₁₁₂ may be each independently a substituted or unsubstituted C₅-C₆₀ arylene group; Ar₁₁₃ to Ar₁₁₆ may be each independently a substituted or unsubstituted C₁-C₁₀ alkyl group, or a substituted or unsubstituted C₅-C₆₀ aryl group; and g, h, i, and j are each independently an integer of 0 to 4.

For example, Ar₁₁₁ and Ar₁₁₂ in Formula 400 may each independently be a phenylene group, a naphthylene group, a phenanthrenyl group, or a pyrenylene group; or a phenylene group, a naphthylene group, a phenanthrenyl group, a fluorenyl group, or a pyrenylene group, each substituted with at least one of a phenyl group, a naphthyl group, and an anthryl group.

g, h, i, and j in Formula 400 may be each independently 0, 1, or 2.

Ar₁₁₁ to Ar₁₁₆ in Formula 400 may each independently be a C₁-C₁₀ alkyl group substituted with at least one of a phenyl group, a naphthyl group, and an anthryl group; a phenyl group; a naphthyl group; an anthryl group; a pyrenyl group; a phenanthrenyl group; a fluorenyl group; or a phenyl group, a naphthyl group, an anthryl group, a pyrenyl group, a phenanthrenyl group, and a fluorenyl group, each substituted with at least one of a deuterium, a halogen atom, a hydroxyl group, a cyano group, a nitro group, an amino group, an amidino group, a hydrazine, a hydrazone, a carboxyl group or salt thereof, a sulfonic acid group or salt thereof, a phosphoric acid group or salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthryl group, a pyrenyl group, a phenanthrenyl group, a fluorenyl group, and

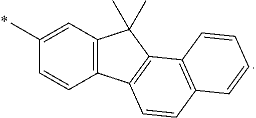 [SMILES: Cc1ccc2c(c1)C(C)(C)c1c-2ccc2ccccc12]

For example, the anthracene-based compound represented by Formula 400 may be one of the following compounds:

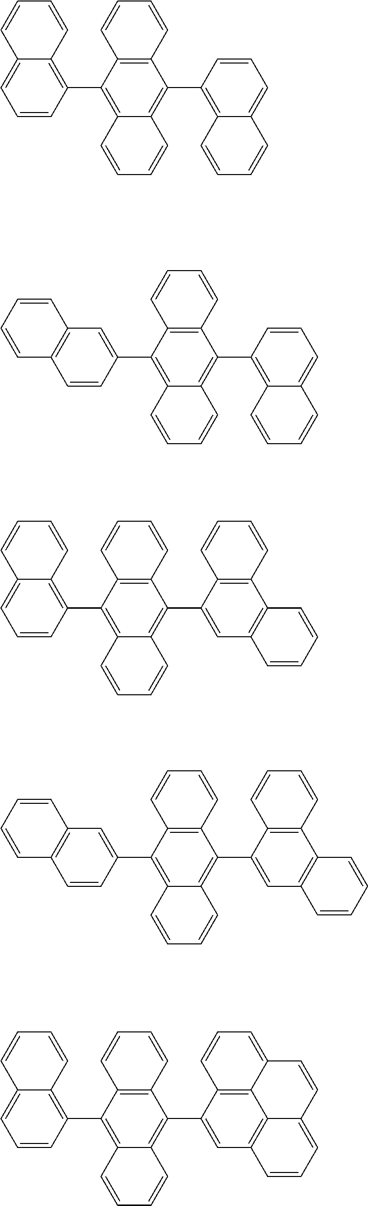

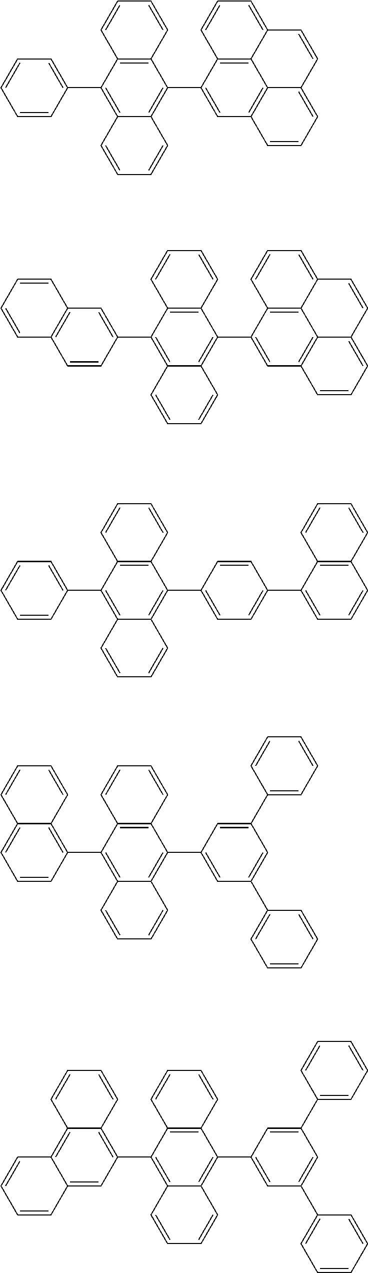

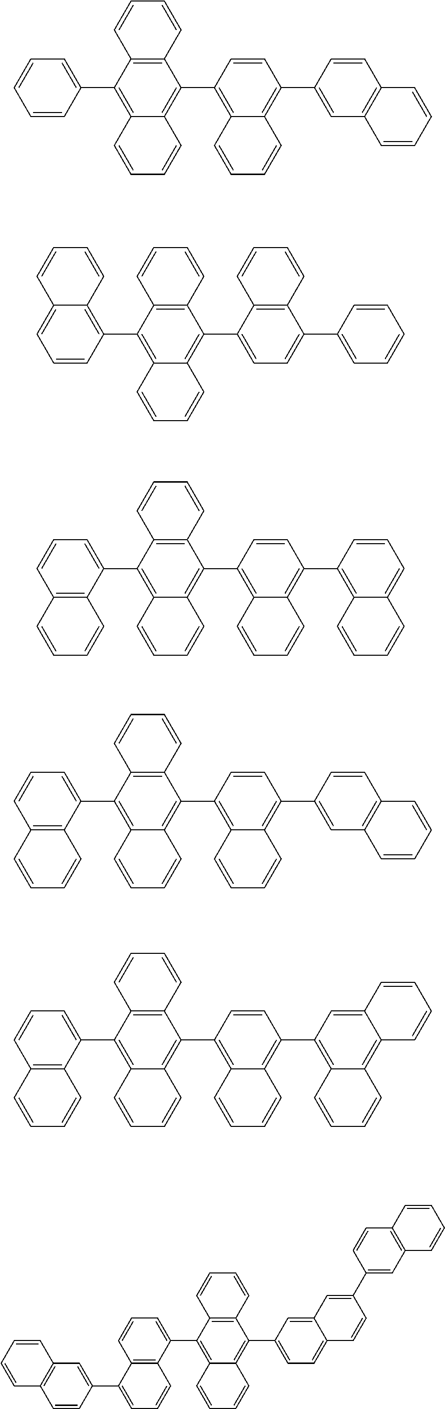

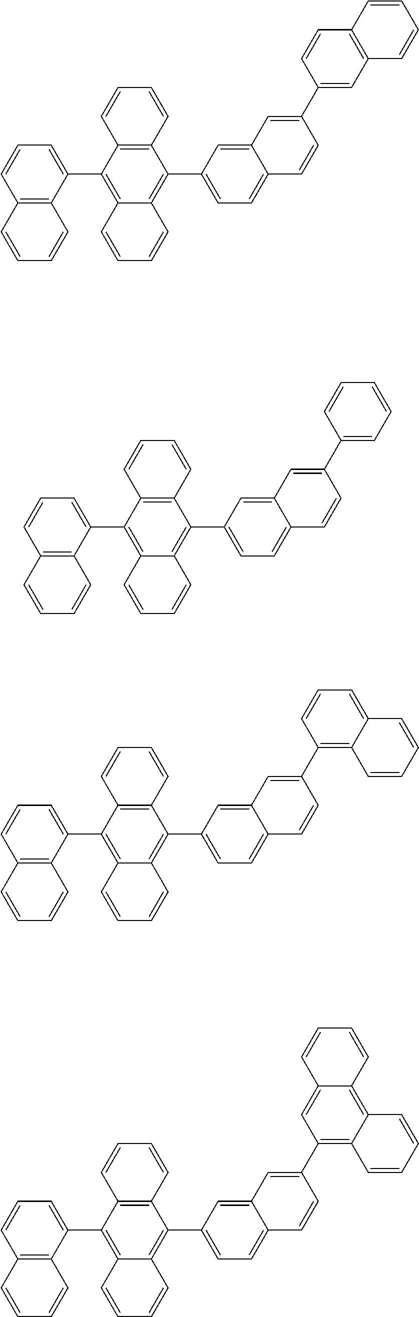

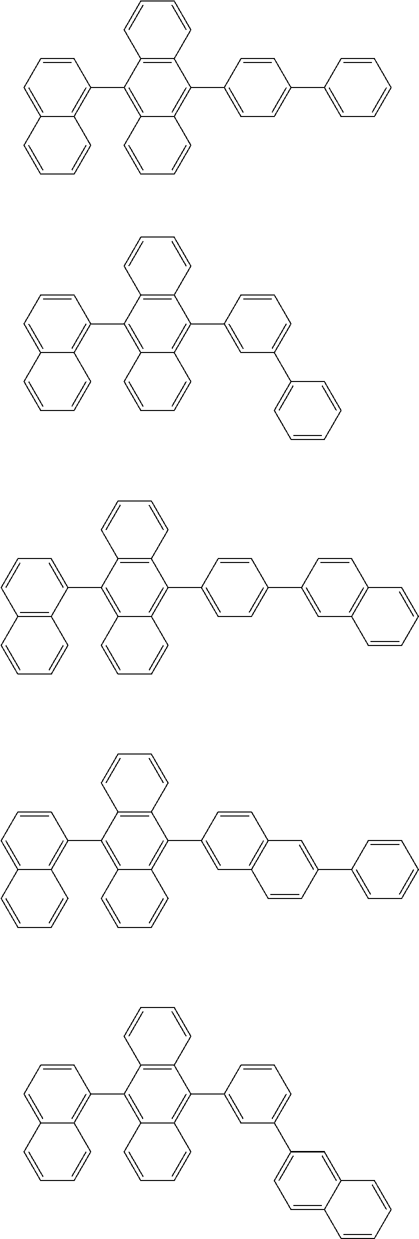

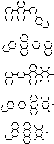

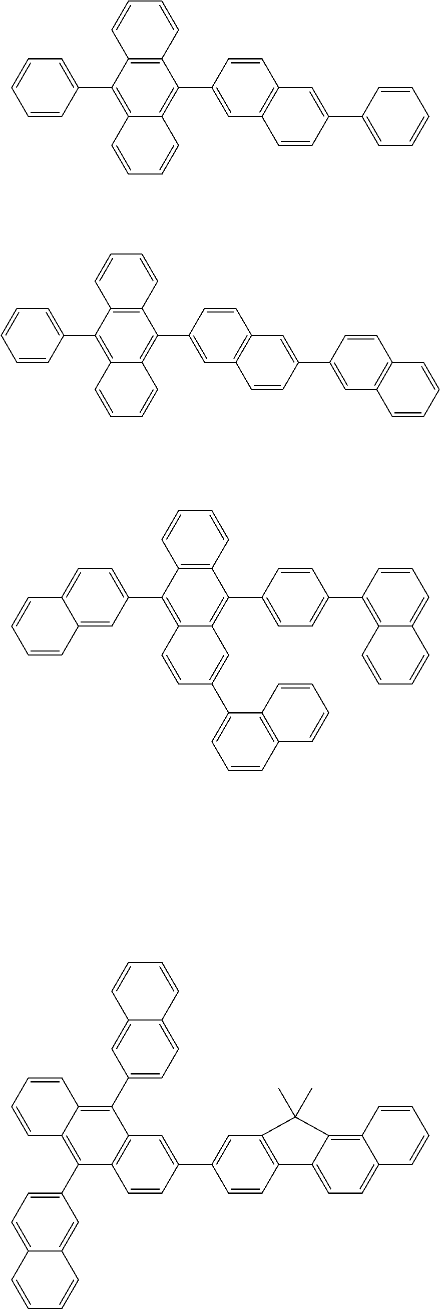

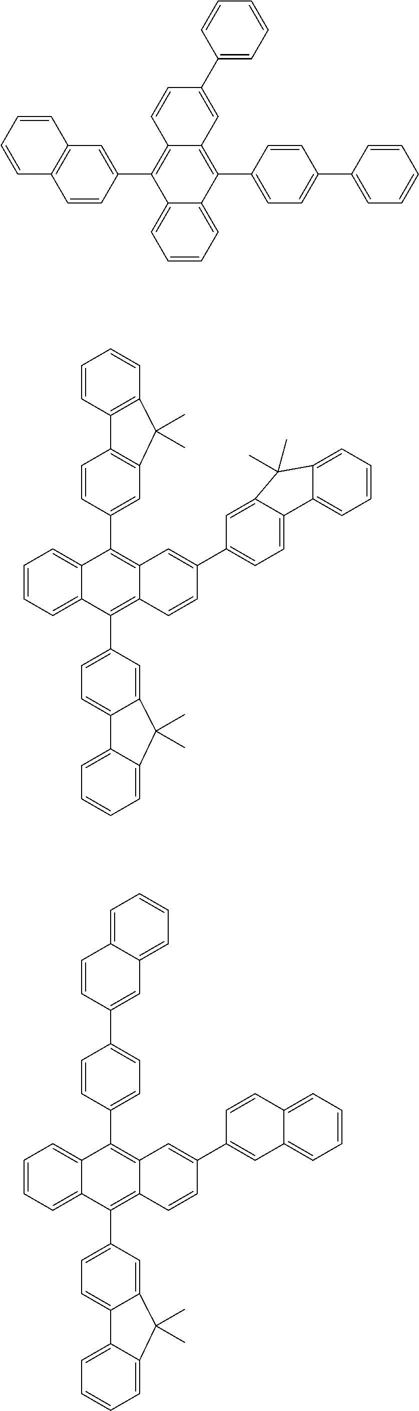

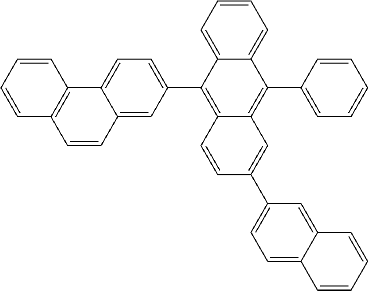 [SMILES: c1ccc(-c2c3ccccc3c(-c3ccc4c(ccc5ccccc54)c3)c3ccc(-c4ccc5ccccc5c4)cc23)cc1]

The host may be an anthracene-based compound represented by Formula 401 below:

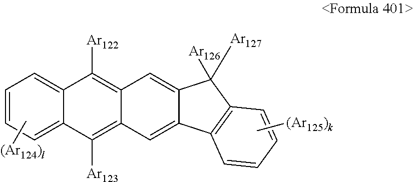

Ar₁₂₂ to Ar₁₂₅ in Formula 401 are the same as described in detail in connection with Ar₁₁₃ in Formula 400.

Ar₁₂₆ and Ar₁₂₇ in Formula 401 may be each independently a C₁-C₁₀ alkyl group (for example, a methyl group, an ethyl group, or a propyl group).

k and 1 in Formula 401 may be each independently an integer of 0 to 4. For example, k and I may be 0, 1, or 2.

For example, the anthracene-based compound represented by Formula 401 may be one of the following compounds:

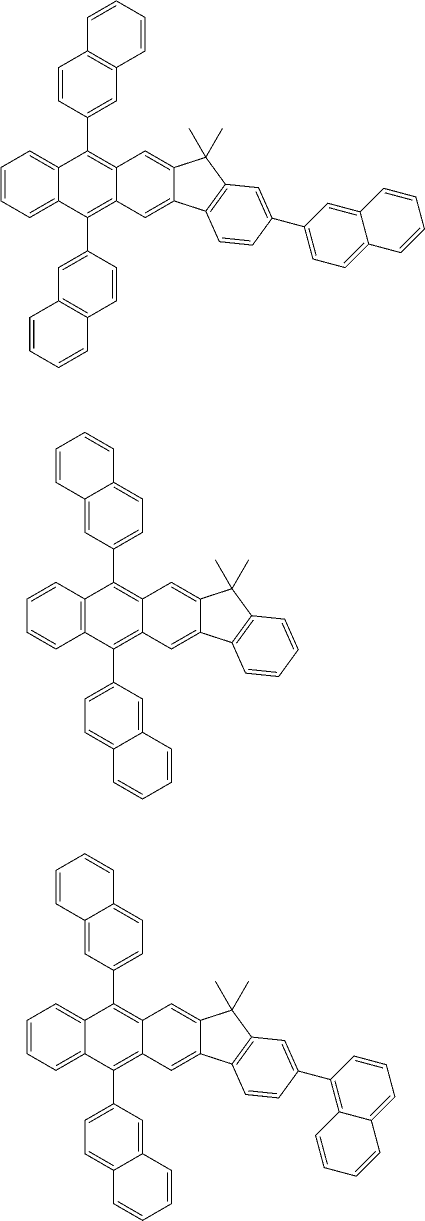

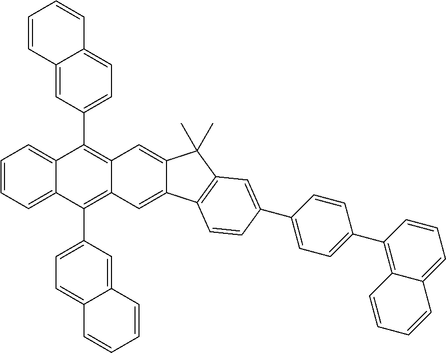 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

When the organic light-emitting device is a full color organic light-emitting device, the emission layer may be patterned into a red emission layer, a green emission layer, and a blue emission layer.

Also, at least one of the red emission layer, the green emission layer, and the blue emission layer may include the following dopants (ppy=phenylpyridine)

For example, compounds illustrated below may be used as a blue dopant.

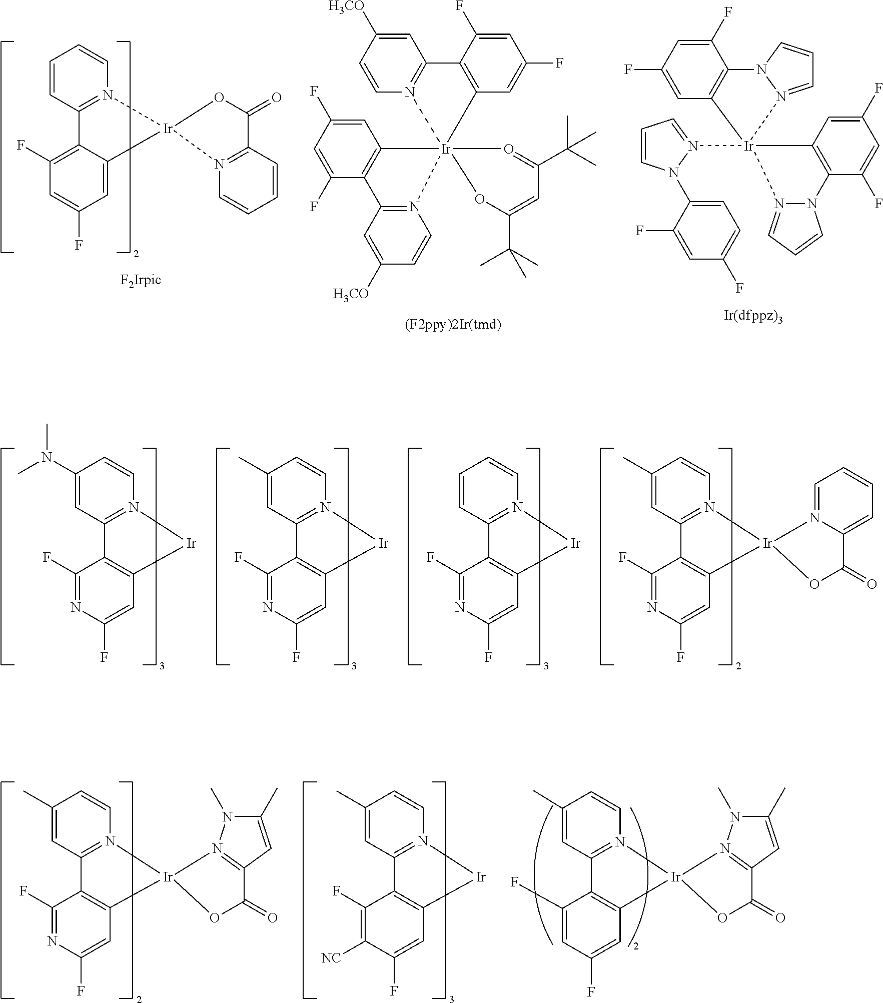

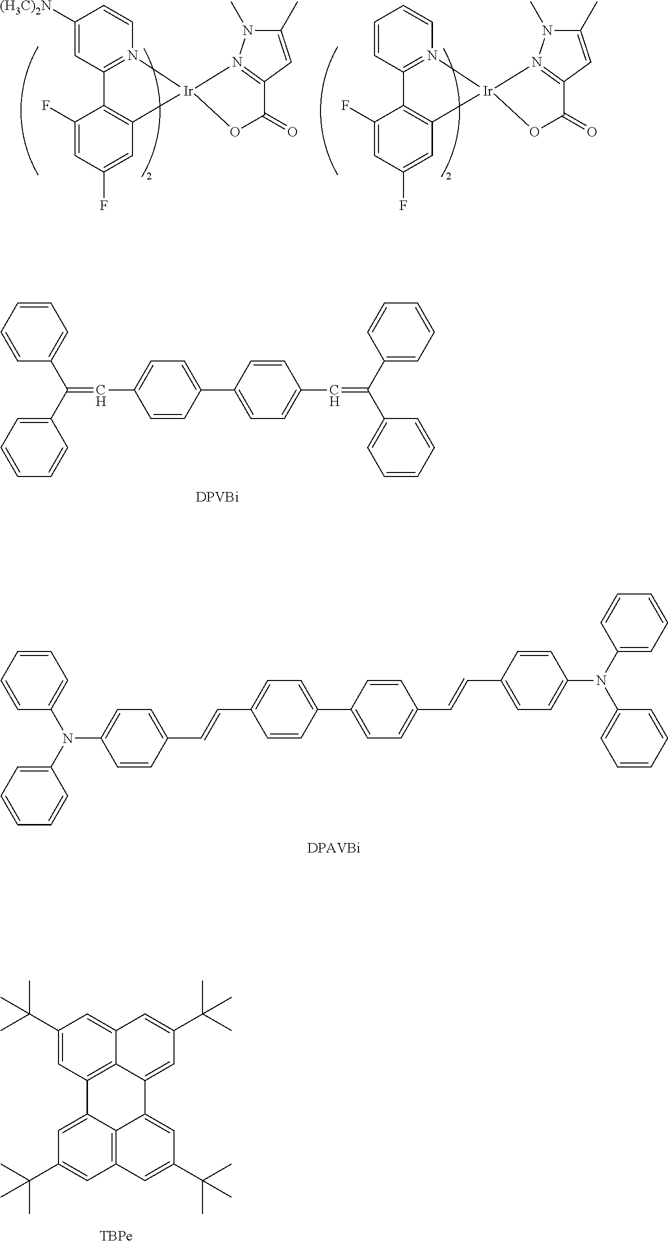

For example, compounds illustrated below may be used as a red dopant.

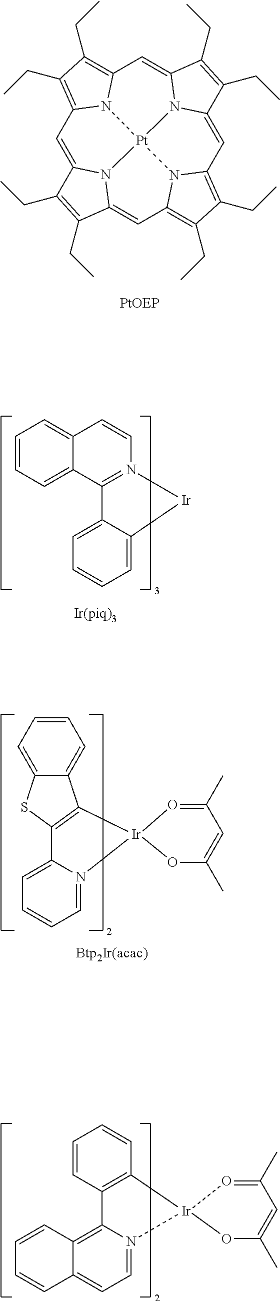

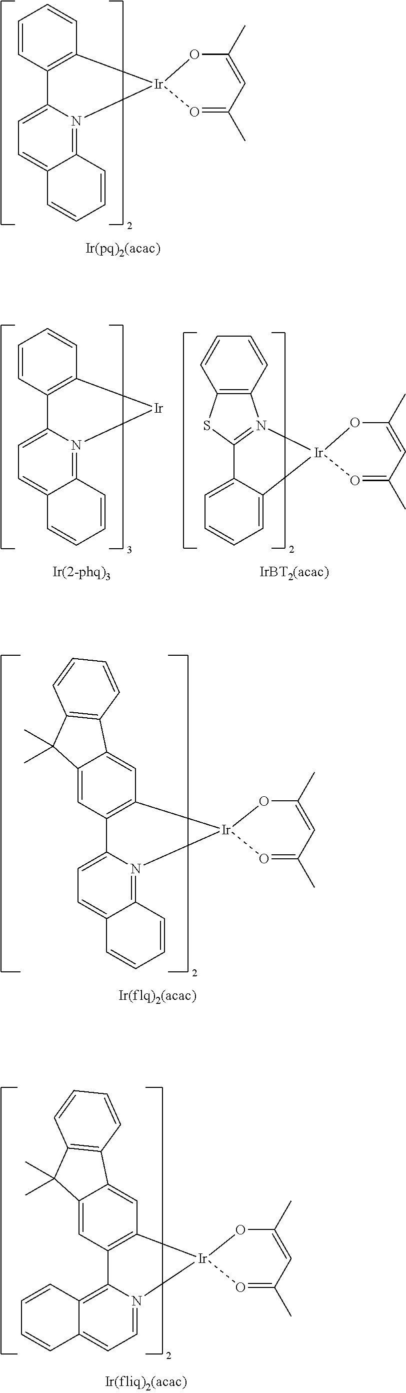

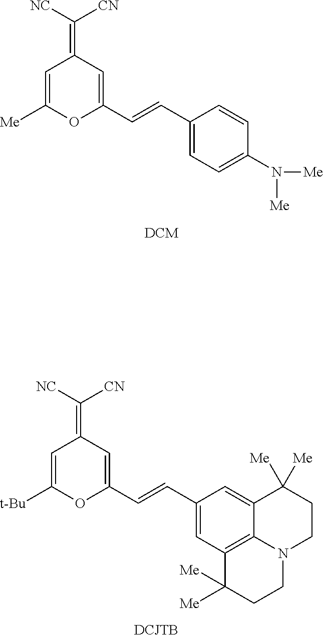 [SMILES: CC1=CC(=C(C#N)C#N)C=C(/C=C/c2ccc(N(C)C)cc2)O1 ; CC(C)(C)C1=CC(=C(C#N)C#N)C=C(/C=C/c2cc3c4c(c2)C(C)(C)CCN4CCC3(C)C)O1]

For example, compounds illustrated below may be used as a green dopant.

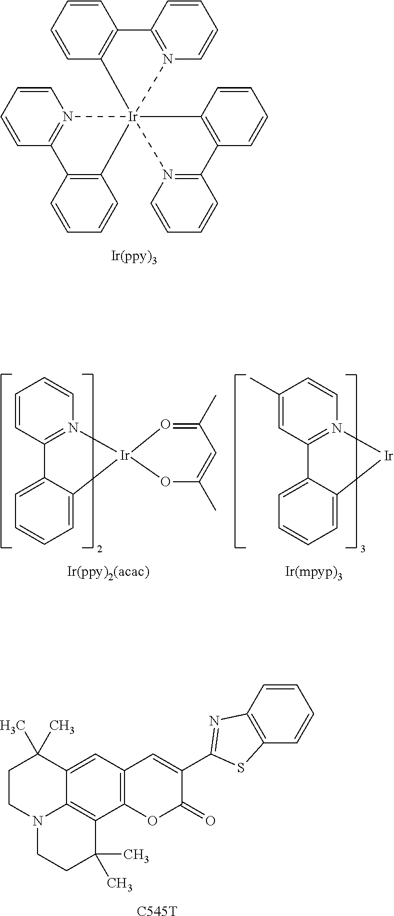

Also, the dopant available for use in the emission layer may be a complex represented by D1-D50 below:

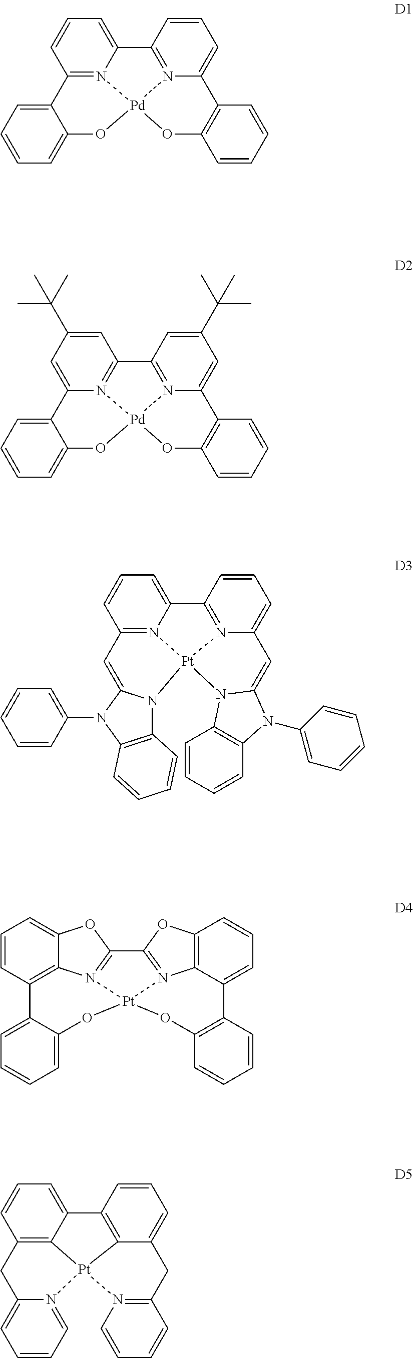

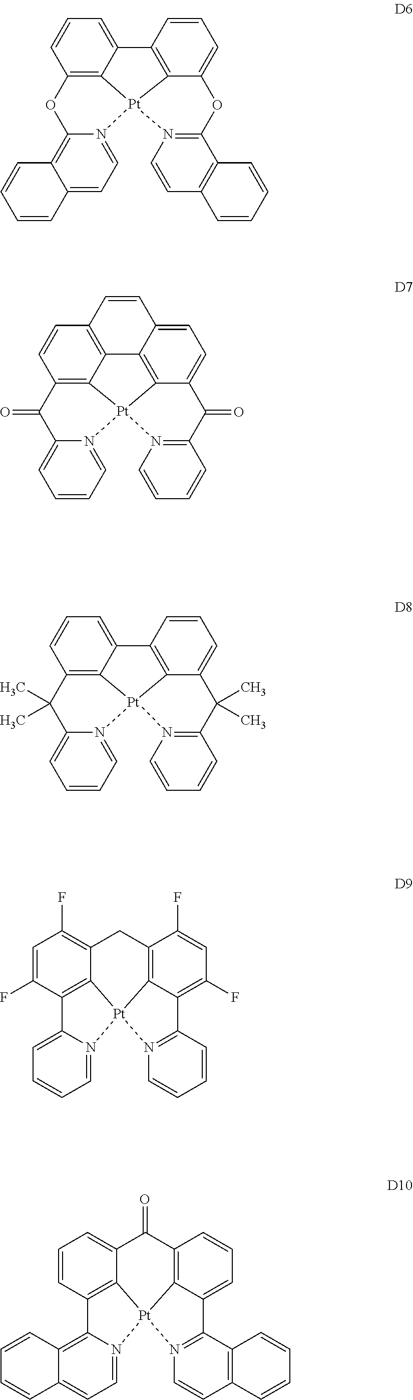

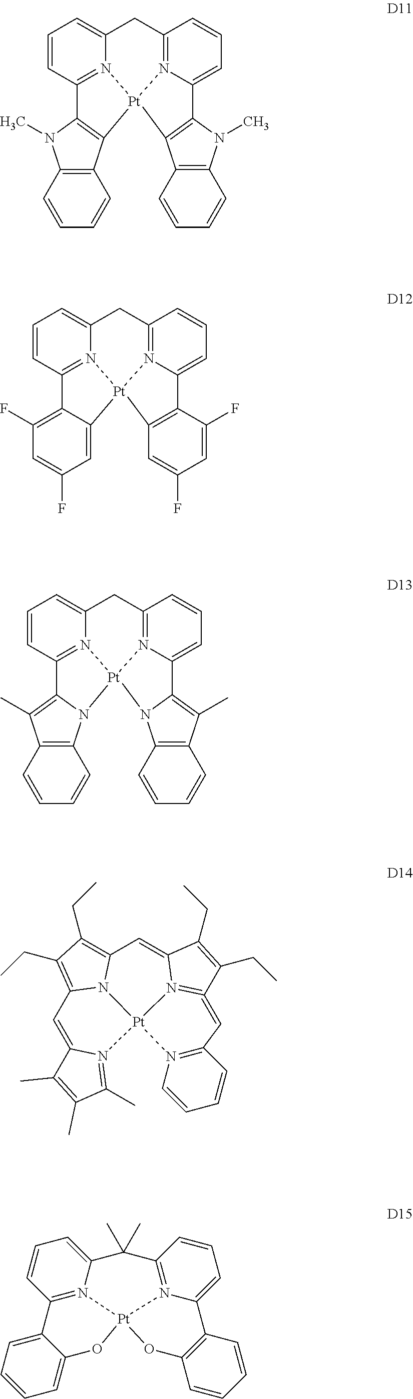

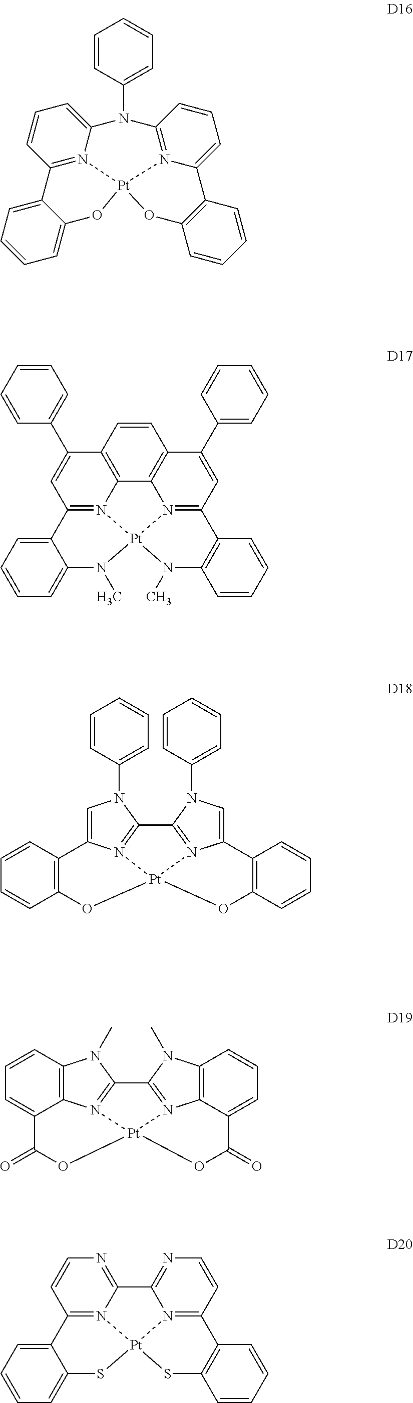

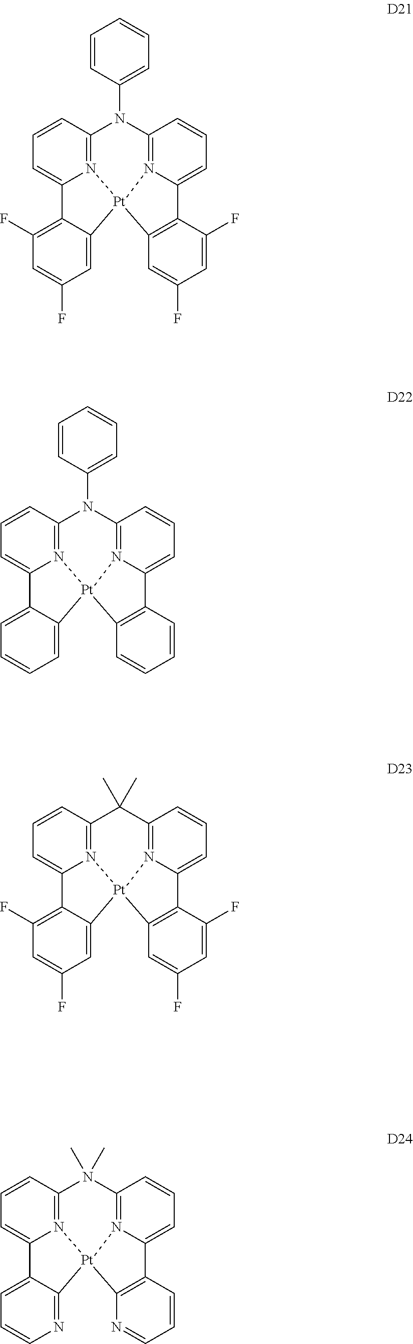

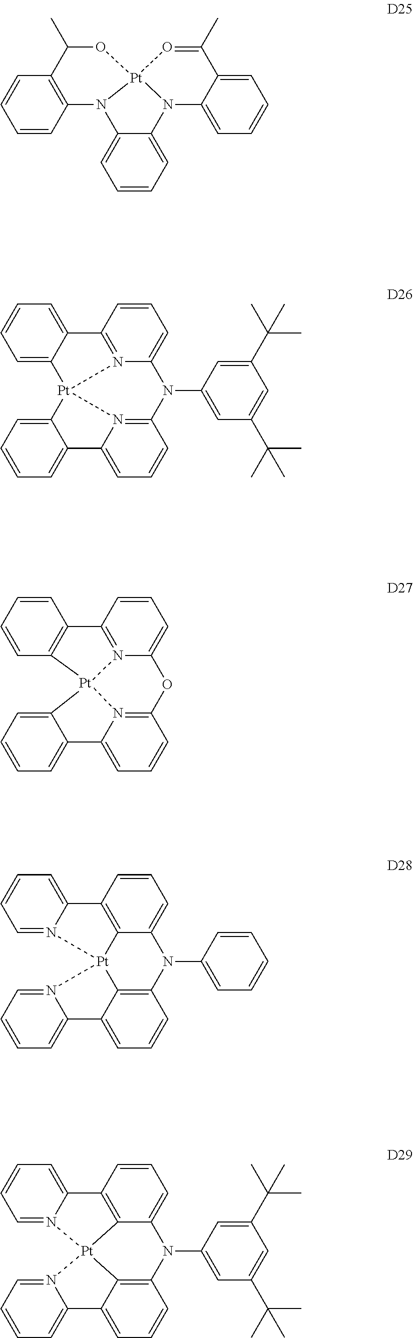

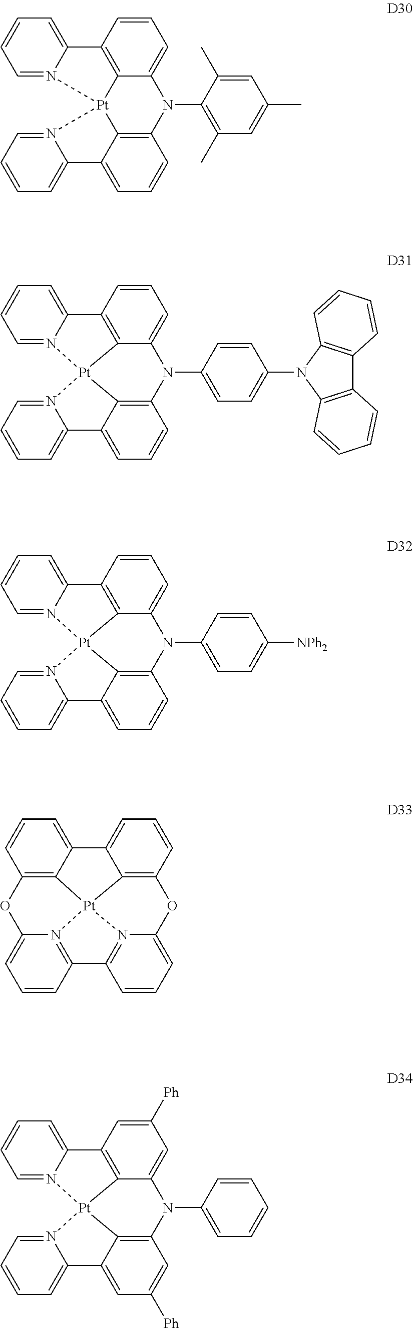

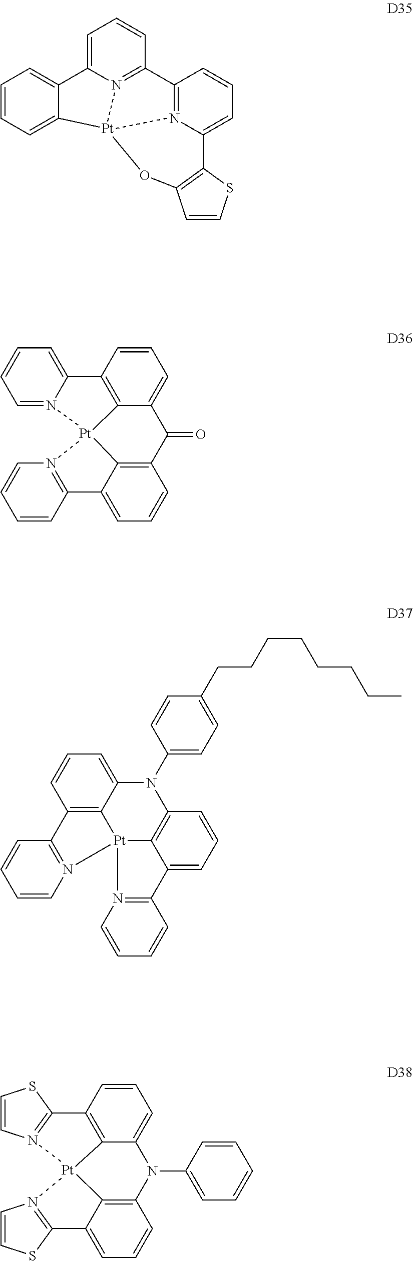

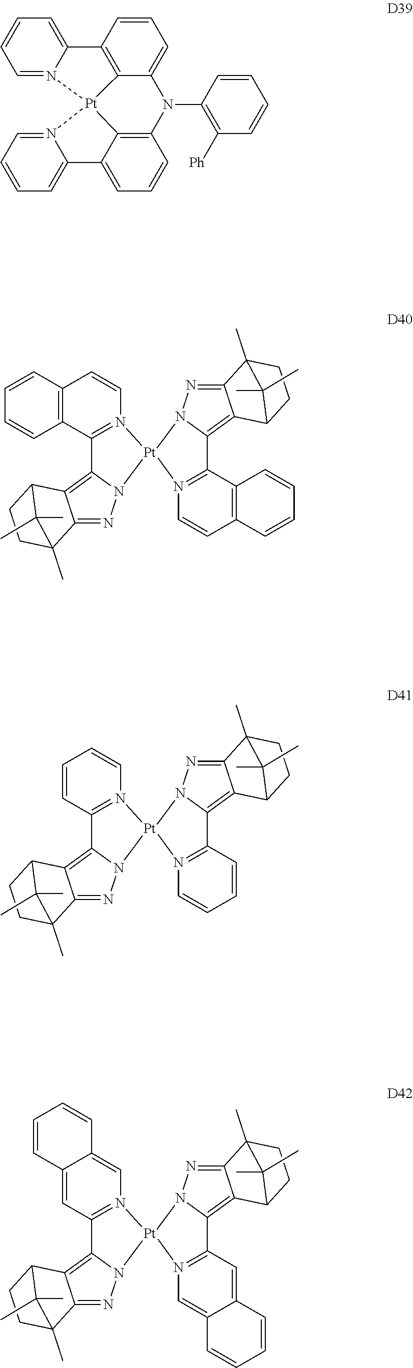

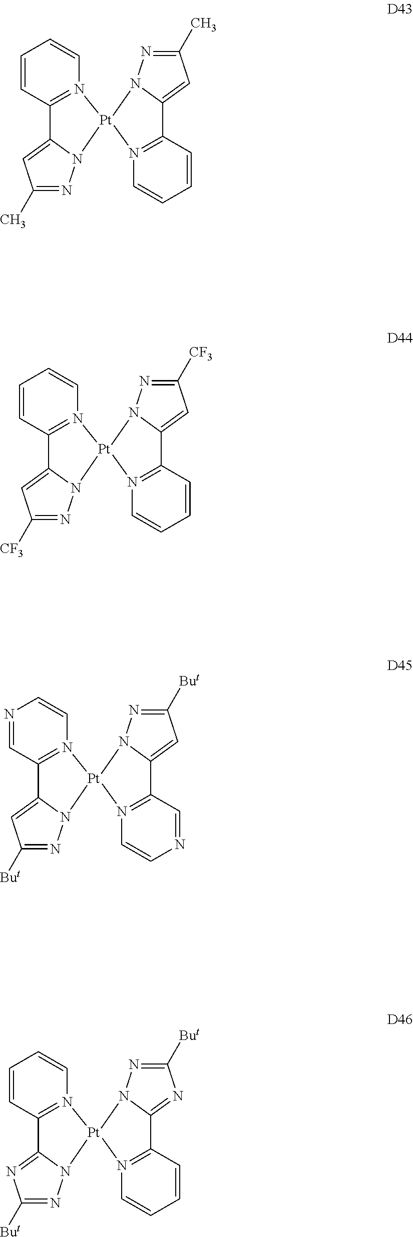

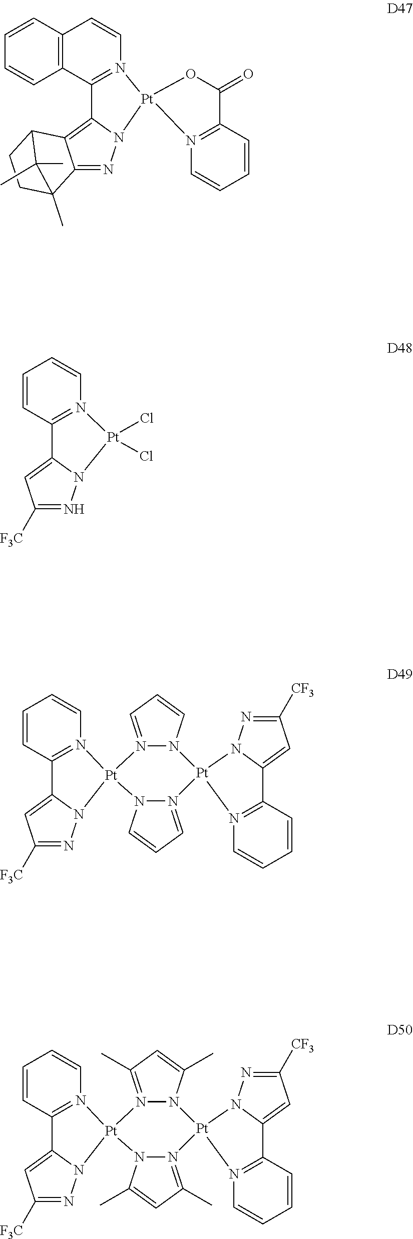

The dopant used in the emission layer may be an Os-complex described below:

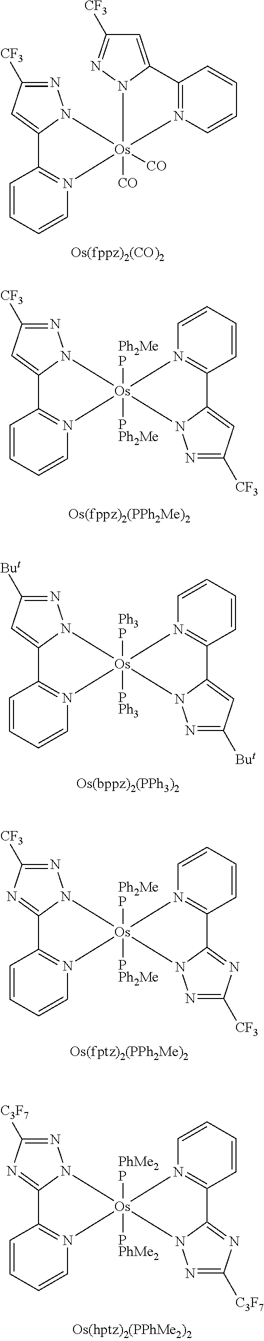

When the emission layer includes a host and a dopant, an amount of the dopant may be in a range of, for example, about 0.01 to about 15 parts by weight based on 100 parts by weight of the host.

A thickness of the emission layer may be in a range of about 100 Å to about 1,000 Å, for example, about 200 Å to about 600 Å. When the thickness of the emission layer is within this range, excellent light-emission characteristics may be obtained without a substantial increase in driving voltage.

Next, an electron transport layer (ETL) may be formed on the emission layer by using a suitable method, for example, vacuum deposition, spin coating, casting, or the like. When the electron transport layer is formed using vacuum deposition or spin coating, the deposition and coating conditions may be similar to those for the formation of the hole injection layer, though the conditions for deposition and coating may vary according to the material that is used to form the electron transport layer.

An electron transport material may be any one of various materials that stably transport electrons provided by an electron injection electrode (cathode). The electron transport material may include the compound represented by Formula 1. Examples of suitable electron transport materials include a quinoline derivative, such as tris(8-quinolinolate)aluminum (Alq3), TAZ, Balq, beryllium bis (benzoquinolin-10-olate) (Bebq₂), ADN, Compound 201, and Compound 202.

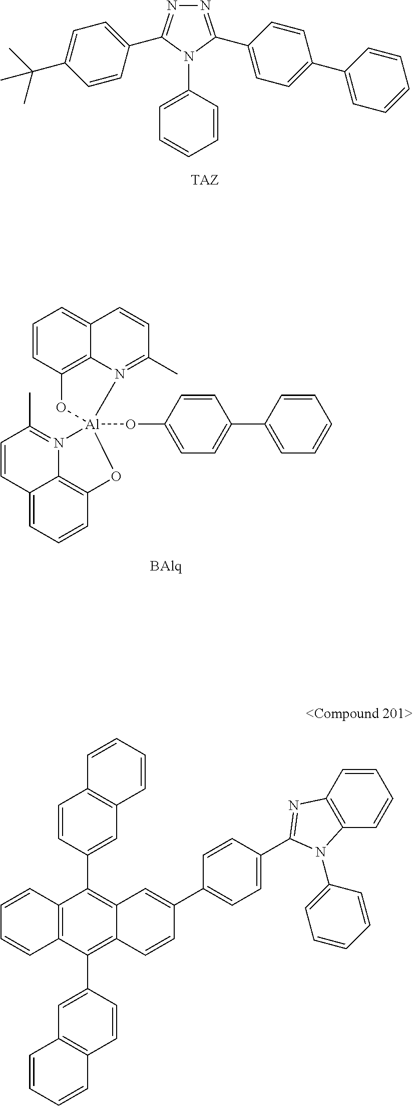

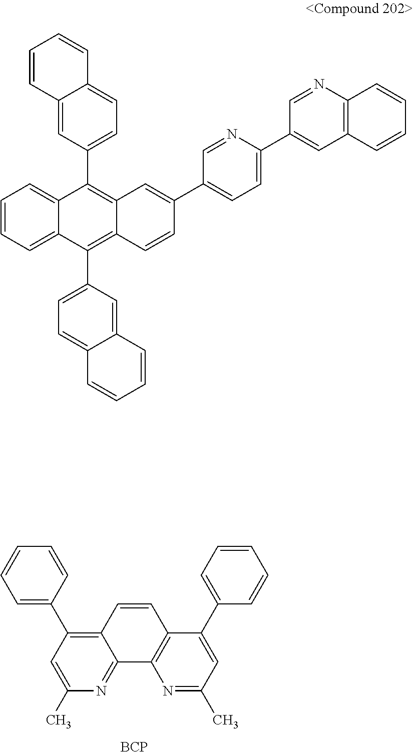 [SMILES: c1ccc2cc(-c3c4ccccc4c(-c4ccc5ccccc5c4)c4cc(-c5ccc(-c6cnc7ccccc7c6)nc5)ccc34)ccc2c1 ; Cc1cc(-c2ccccc2)c2ccc3c(-c4ccccc4)cc(C)nc3c2n1 ; "BCP"]

A thickness of the electron transport layer may be in a range of about 100 Å to about 1,000 Å, for example, about 150 Å to about 500 Å. When the thickness of the electron transport layer is within the range described above, the electron transport layer may have satisfactory electron transport characteristics without a substantial increase in driving voltage.

Also, the electron transport layer may include, in addition to an electron transport organic compound, a metal-containing material.

The metal-containing material may include a Li complex. Examples of the Li complex include lithium quinolate (LiQ) and Compound 203 illustrated below:

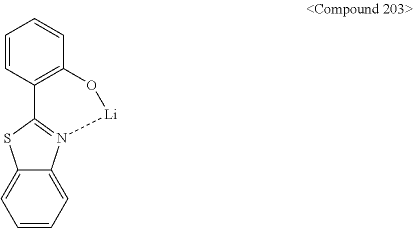

An electron injection layer (EIL), which facilitates injection of electrons from the cathode, may be formed on the electron transport layer. A suitable electron injection material may be used to form the electron injection layer.

Examples of electron injection materials include LiF, NaCl, CsF, Li₂O, and BaO. The deposition conditions of the electron injection layer may be similar to those used to form the hole injection layer, although the deposition conditions may vary according to the material that is used to form the electron injection layer.

A thickness of the electron injection layer may be in a range of about 1 Å to about 100 Å, for example, about 3 Å to about 90 Å. When the thickness of the electron injection layer is within the range described above, the electron injection layer may have satisfactory electron injection characteristics without a substantial increase in driving voltage.

A second electrode may be disposed on the organic layer. The second electrode may be a cathode that is an electron injection electrode. A metal for forming the second electrode may be a material having a low work function. Such a material may be metal, alloy, an electrically conductive compound, or a mixture thereof. For example, lithium (Li), magnesium (Mg), aluminum (Al), aluminum-lithium (Al—Li), calcium (Ca), magnesium-indium (Mg—In), or magnesium-silver (Mg—Ag) may be formed as a thin film to obtain a transmissive electrode. To manufacture a top emission type light-emitting device, a transmissive electrode formed using ITO or IZO may be formed.

Hereinbefore, the organic light-emitting device has been described with reference to FIG. 1. In other implementations, the organic light-emitting device may have other structures.

When a phosphorescent dopant is used in the emission layer, a triplet exciton or a hole may diffuse to the electron transport layer. To prevent the diffusion, a hole blocking layer (HBL) may be formed between the hole transport layer and the emission layer or between the H-functional layer and the emission layer by vacuum deposition, spin coating, casting, LB deposition, or the like. When the hole blocking layer is formed by vacuum deposition or spin coating, the deposition or coating conditions may be similar to those applied to form the hole injection layer, although the deposition or coating conditions may vary according to the material that is used to form the hole blocking layer. A hole blocking material may be a suitable hole blocking material. Examples thereof include an oxadiazole derivative, a triazole derivative, a phenanthroline derivative, and so on. For example, BCP illustrated below may be used as the hole-blocking material.

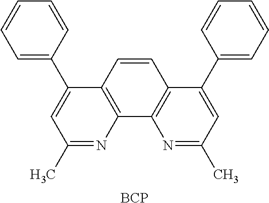

A thickness of the hole blocking layer may be in a range of about 20 Å to about 1,000 Å, for example, about 30 Å to about 300 Å. When the thickness of the hole blocking layer is within these ranges, the hole blocking layer may have excellent hole blocking characteristics without a substantial increase in driving voltage.

An organic light-emitting device according to an embodiment may be used in various flat panel display apparatuses, such as a passive matrix organic light-emitting display apparatus or an active matrix organic light-emitting display apparatus. In particular, when the organic light-emitting device is included in an active matrix organic light-emitting display apparatus, a first electrode disposed on a substrate acts as a pixel and may be electrically connected to a source electrode or a drain electrode of a thin film transistor. In addition, the organic light-emitting device may be included in a flat panel display apparatus that emits light in opposite directions.

An organic layer according to an embodiment may be formed by depositing the compound represented by Formula 1, or may be formed by using a wet method in which the compound represented by Formula 1 is prepared in the form of solution and then the solution of the compound is used for coating.

The following Examples and Comparative Examples are provided in order to highlight characteristics of one or more embodiments, but it is to be understood that the Examples and Comparative Examples are not to be construed as limiting the scope of the embodiments, nor are the Comparative Examples to be construed as being outside the scope of the embodiments. Further, it is to be understood that the embodiments are not limited to the particular details described in the Examples and Comparative Examples.

### EXAMPLE

### Synthesis Example 1

### Synthesis of Compound 2

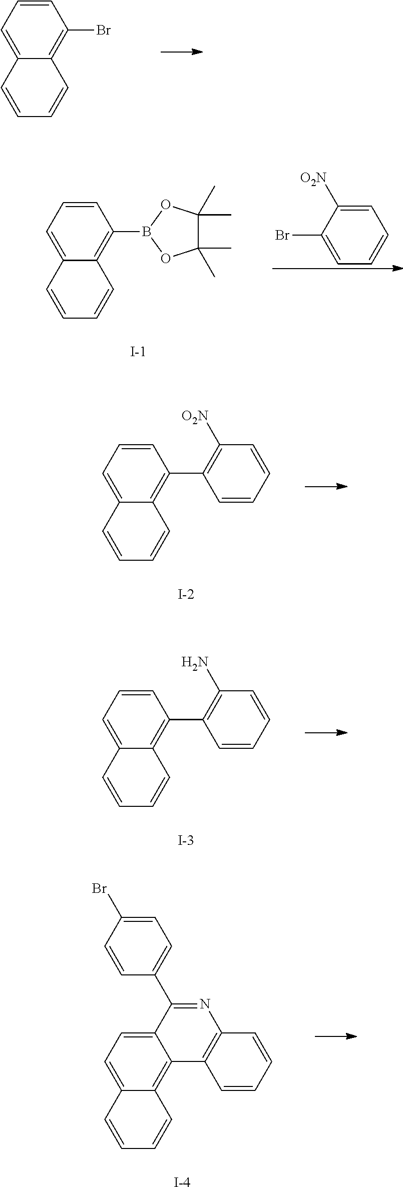

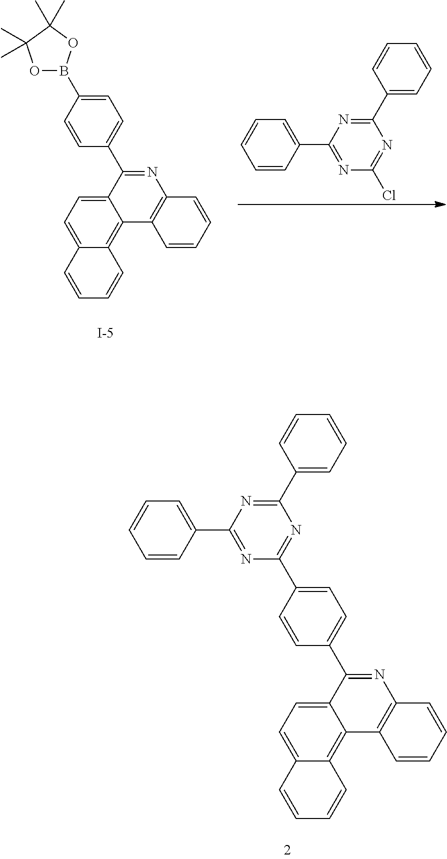

### Synthesis of Intermediate I-1

2.07 g (10 mmol) of 1-bromonaphthalene was dissolved in 30 mL of THF, and then, at a temperature of −78° C., 4 mL of normal butylithium (2.5M in hexane) was added thereto. One hour after, at the same temperature, 2.0 mL (10 mmol) of 2-isopropoxy group-4,4,5,5-tetrametnyl-1,3,2-dioxaborolane was further added thereto. The resultant mixture was stirred at room temperature for 5 hours, and then, water was added thereto, and the result was washed three times with 30 mL of diethylether. The diethylether layer used herein was dried with MgSO₄, and then, the result was under reduced pressure to obtain a product, which was then separation-purified by silica gel column chromatography to obtain 1.96 g (yield of 77%) of Intermediate I-1. The obtained compound was confirmed by LC-MS. C₁₆H₁₉BO₂: M+1 255.2

### Synthesis of Intermediate I-2

2.54 g (10.0 mmol) of Intermediate I-1, 2.02 g (10.0 mmol) of 1-bromo-2-nitrobenzene, 0.58 g (0.50 mmol) of Pd(PPh₃)₄, 0.16 g (0.5 mmol) of tetrabutylammonium bromide (TBAB), and 3.18 g (30.0 mmol) of Na₂CO₃ were dissolved in 60 mL of a toluene/ethanol/H₂O (3/3/1) mixed solution, and then, the resultant mixture was stirred at a temperature of 80° C. for 16 hours. The reaction solution was cooled to room temperature, and the, extracted three times with 60 mL of water and 60 mL of diethylether. An organic layer obtained therefrom was dried using magnesium sulfate and the residual obtained by removing a solvent used therefrom by evaporation was separation-purified by silica gel column chromatography to obtain 2.04 g (yield of 82%) of Intermediate I-2. The obtained compound was identified by LC-MS. C₁₆H₁₁NO₂: M+1 250.1

### Synthesis of Intermediate I-3

2.49 g (10.0 mmol) of Intermediate I-2, 3.56 g (30 mmol) of tin, and 5 mL (50 mmol, conc. 36.5%) of HCl were dissolved in 60 mL of ethanol, and then, the mixture was stirred at a temperature of 100° C. for 8 hours. The reaction solution was cooled to room temperature, and then 3 g of sodium hydroxide dissolved in 10 mL of water was added to a filtrate obtained therefrom by filtering under reduced pressure, and then, the result was extracted three times with 60 mL of water and 60 mL of dichloromethane. An organic layer obtained therefrom was dried using magnesium sulfate and the residual obtained by removing a solvent used therefrom by evaporation was separation-purified by silica gel column chromatography to obtain 1.97 g (yield of 90%) of Intermediate I-3. The obtained compound was identified by LC-MS. C₁₆H₁₃N: M+1 220.1

### Synthesis of Intermediate I-4

2.19 g (10 mmol) of Intermediate I-3 and 3.66 g (20 mmol) of 4-bromobenzaldehyde were dissolved in 10 mL of trifluoroacetic acid, and then, the mixture was stirred in a seal tube at a temperature of 130° C. for 3 days. The reaction solution was cooled to room temperature, and then, quenched using NaHCO₃, and then extracted three time using 60 mL of water and 60 mL of dichloromethane. An organic layer obtained therefrom was dried using magnesium sulfate and the residual obtained by removing a solvent used therefrom by evaporation was separation-purified by silica gel column chromatography to obtain 1.92 g (yield of 50%) of Intermediate I-4. The obtained compound was identified by LC-MS. C₂₃H₁₄BrN: M+1 384.0

### Synthesis of Intermediate I-5

3.15 g (yield of 73%) of Intermediate I-5 was obtained in the same manner as in the synthesis of Intermediate I-1, except that Intermediate I-4 was used instead of 1-bromonaphthalene. The obtained compound was confirmed by LC-MS. C₂₉H₂₆BNO₂: M+1 432.2

### Synthesis of Compound 2

4.31 g (10 mmol) of Intermediate I-5, 2.68 g (10 mmol) of 2-chloro-4,6-diphenyl-1,3,5-triazine, 0.58 g (0.5 mmol) of Pd(PPh₃)₄ (tetrakis(triphenylphosphine)palladium), and 4.14 g (30 mmol) of K₂CO₃ were dissolved in 60 mL of a THF/H₂O (a volumetric ratio of 2/1) mixed solution, and then, the mixture was stirred at a temperature of 80° C. for 16 hours. The reaction solution was cooled to room temperature, and then, 40 mL of water was added thereto, and an extraction process was performed thereon three times with 50 mL of ethylether. A collected organic layer was dried by using magnesium sulfate, and then, the residual obtained by evaporating a solvent therefrom was separation-purified by silica gel column chromatography to obtain 3.38 g (yield of 63%) of Compound 2. The obtained compound was identified by MS/FAB and ¹H NMR. C₃₈H₂₄N₄ cal. 536.20. found 536.19.

### Synthesis Example 2

### Synthesis of Compound 14

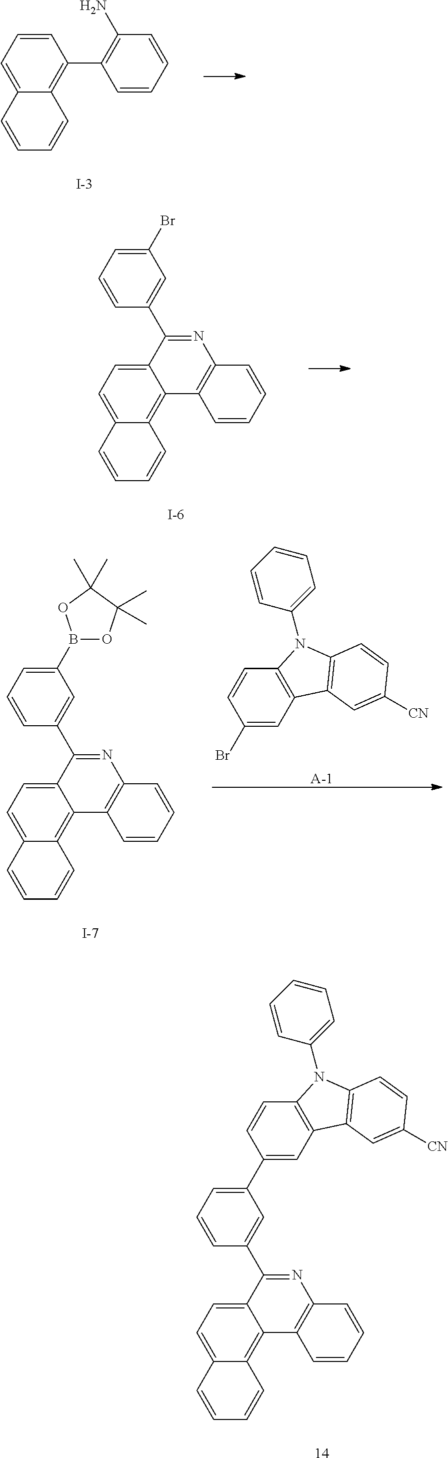

### Synthesis of Intermediate I-6

1.84 g (yield of 48%) of Intermediate I-6 was obtained in the same manner as in the synthesis of Intermediate I-4, except that 3-bromobenzaldehyde was used instead of 4-bromobenzaldehyde. The obtained compound was confirmed by LC-MS. C₂₃H₁₄BrN: M+1 384.0

### Synthesis of Intermediate I-7

3.11 g (yield of 72%) of Intermediate I-7 was obtained in the same manner as in the synthesis of Intermediate I-5, except that Intermediate I-6 was used instead of Intermediate I-4. The obtained compound was confirmed by LC-MS. C₂₉H₂₆BNO₂: M+1 432.2

### Synthesis of Compound 14

3.83 g (yield of 67%) of Compound 14 was obtained in the same manner as used to synthesize Compound 2, except that Intermediate I-7 was used instead of Intermediate I-5 and Intermediate A-1 was used instead of 2-chloro-4,6-diphenyl-1,3,5-triazine. The obtained compound was identified by MS/FAB and ¹H NMR. C₄₂H₂₅N₃ cal. 571.20. found 571.21.

### Synthesis Example 3

### Synthesis of Compound 21

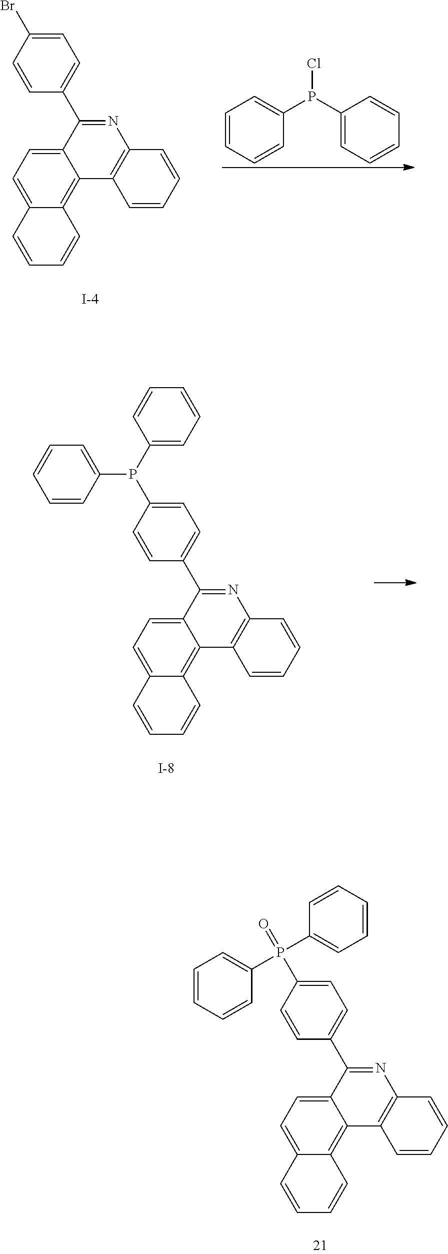

3.84 g (10 mmol) of Intermediate I-4 was dissolved in 30 mL of THF, and then, at a temperature of −78° C., 4 mL of normal butylithium (2.5M in hexane) was added thereto. One hour after, 2.20 g (10 mmol) of chlorodiphenylphosphine was slowly added dropwise thereto, and the resultant mixture was stirred for 3 hours and heated to room temperature, and water was added thereto, and the result was washed three times with 30 mL of ethylacetate. A washed ethylacetate layer was dried by using MgSO₄, and then, dried under reduced pressure to obtain Intermediate I-8. 4.89 g (10 mmol) of Intermediate I-8 was dissolved in 40 mL of dichloromethane, and then 4 mL of hydrogen peroxide was added thereto, and the resultant mixture was stirred at room temperature for 20 hours. 20 mL of water was added thereto and then the result was extracted three times with 20 mL of dichloromethane. A collected organic layer was dried by using magnesium sulfate, and then, the residual obtained by evaporating a solvent therefrom was separation-purified by silica gel column chromatography to obtain 3.74 g (yield of 74%) of Compound 21. The obtained compound was identified by MS/FAB and ¹H NMR. C₃₅H₂₄NOP cal. 505.16. found 505.17.

### Synthesis Example 4

### Synthesis of Compound 42

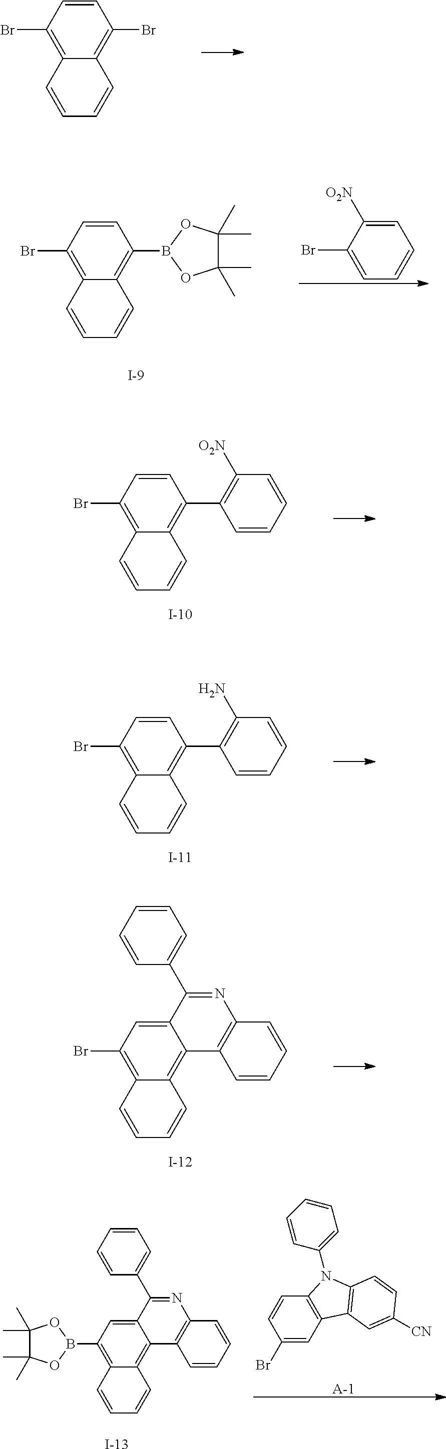

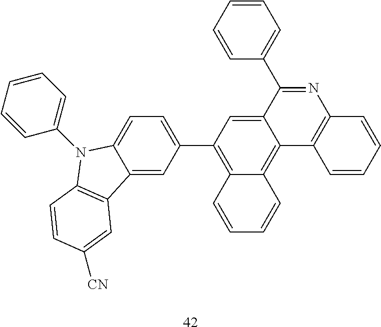 [SMILES: N#Cc1ccc2c(c1)c1cc(-c3cc4c(-c5ccccc5)nc5ccccc5c4c4ccccc34)ccc1n2-c1ccccc1 ; "42"]

### Synthesis of Intermediate I-9

2.46 g (yield of 74%) of Intermediate I-9 was obtained in the same manner as in the synthesis of Intermediate I-1, except that 1,4-dibromonaphthalene was used instead of 1-bromonaphthalene. The obtained compound was confirmed by LC-MS. C₁₆H₁₈BBrO₂: M+1 333.1

### Synthesis of Intermediate I-10

2.63 g (yield of 80%) of Intermediate I-10 was obtained in the same manner as in the synthesis of Intermediate I-2, except that Intermediate I-9 was used instead of Intermediate I-1. The obtained compound was confirmed by LC-MS. C₁₆H₁₀BrNO₂: M+1 328.0

### Synthesis of Intermediate I-11

2.71 g (yield of 91%) of Intermediate I-11 was obtained in the same manner as in the synthesis of Intermediate I-3, except that Intermediate I-10 was used instead of Intermediate I-2. The obtained compound was confirmed by LC-MS. C₁₆H₁₂BrN: M+1 298.0

### Synthesis of Intermediate I-12

2.04 g (yield of 53%) of Intermediate I-12 was obtained in the same manner as in the synthesis of Intermediate I-4, except that benzaldehyde was used instead of 4-bromobenzaldehyde. The obtained compound was confirmed by LC-MS. C₂₃H₁₄BrN: M+1 384.0

### Synthesis of Intermediate I-13

3.23 g (yield of 75%) of Intermediate I-13 was obtained in the same manner as in the synthesis of Intermediate I-5, except that Intermediate I-12 was used instead of Intermediate I-4. The obtained compound was confirmed by LC-MS. C₂₉H₂₆BNO₂: M+1 432.2

### Synthesis of Compound 42

4.17 g (yield of 73%) of Compound 42 was obtained in the same manner as used to synthesize Compound 2, except that Intermediate I-13 was used instead of Intermediate I-5 and Intermediate A-1 was used instead of 2-chloro-4,6-diphenyl-1,3,5-triazine. The obtained compound was identified by MS/FAB and ¹H NMR. C₄₂H₂₅N₃ cal. 571.20. found 571.22.

### Synthesis Example 5

### Synthesis of Compound 94

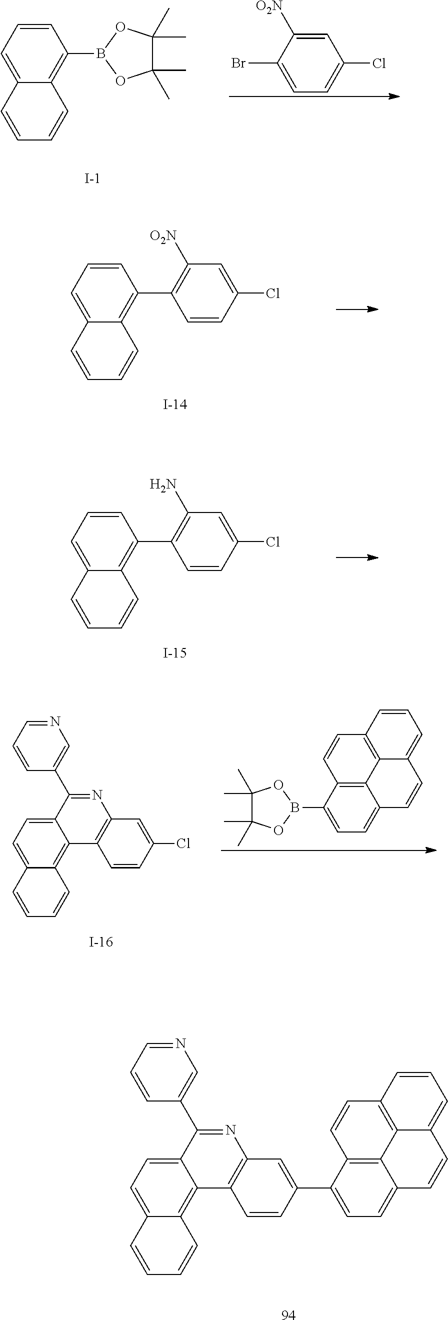

### Synthesis of Intermediate I-14

2.30 g (yield of 81%) of Intermediate I-14 was obtained in the same manner as used to synthesize Intermediate I-2, except that 2-bromo-5-chloronitrobenzene was used instead of 1-bromo-2-nitrobenzene. The obtained compound was confirmed by LC-MS. C₁₆H₁₀ClNO₂: M+1 284.0

### Synthesis of Intermediate I-15

2.28 g (yield of 90%) of Intermediate I-15 was obtained in the same manner as in the synthesis of Intermediate I-3, except that Intermediate I-14 was used instead of Intermediate I-2. The obtained compound was confirmed by LC-MS. C₁₆H₁₂ClN: M+1 254.1

### Synthesis of Intermediate I-16

1.60 g (yield of 47%) of Intermediate I-16 was obtained in the same manner as in the synthesis of Intermediate I-4, except that 3-pyridinecarboaldehyde was used instead of 4-bromobenzaldehyde. The obtained compound was confirmed by LC-MS. C₂₂H₁₃ClN₂: M+1 341.1

### Synthesis of Compound 94

3.60 g (yield of 71%) of Compound 94 was obtained in the same manner as used to synthesize Compound 2, except that Intermediate I-16 was used instead of Intermediate I-5 and 1-pyreneboronic acid was used instead of 2-chloro-4,6-diphenyl-1,3,5-triazine. The obtained compound was identified by MS/FAB and ¹H NMR. C₃₈H₂₂N₂ cal. 506.18. found 506.19.

Other compounds were synthesized by using the same synthesis method as described above and appropriate intermediate materials. ¹H NMR and MS/FAB results of the obtained compounds are shown in Table 1 below.

Methods of synthesizing compounds other than the compound shown in Table 1 may be understood by one of ordinary skill in the art by referring to the synthesis path and source materials described above.

TABLE 1

| | | MS/FAB | |
|---|---|---|---|
| Compound | ¹H NMR (CDCl₃, 400 MHz) | found | calc. |
| 2 | δ = 8.74-8.72 (m, 1H), 8.71-8.70 (m, 2H), 8.69-8.67 (m, 2H), 8.56-8.55 | 536.19 | 536.20 |
| | (m, 1H), 8.54-8.53 (m, 1H), 8.48-8.46 (m, 1H), 8.42-8.41 (m, 1H), | | |
| | 8.40-8.36 (m, 2H), 8.28-8.26 (m, 1H), 7.95-7.91 (m, 1H), 7.86-7.82 | | |
| | (m, 1H), 7.72-7.68 (m, 1H), 7.55-7.54 (m, 1H), 7.53-7.52 (m, 2H), 7.51-7.50 | | |
| | (m, 1H), 7.47-7.41 (m, 5H) | | |
| 4 | δ = 8.81-8.80 (m, 2H), 8.72-8.69 (m, 1H), 8.58-8.56 (m, 2H), 8.54-8.52 | 535.21 | 535.20 |
| | (m, 1H), 8.48-8.45 (m, 1H), 8.28-8.21 (m, 3H), 8.01 (t, 1H), 7.99 (t, 1H), | | |
| | 7.94-7.91 (m, 1H), 7.87-7.81 (m, 6H), 7.72-7.68 (m, 1H), 7.48-7.42 | | |
| | (m, 5H) | | |
| 10 | δ = 8.69-8.67 (m, 1H), 8.47-8.45 (m, 1H), 8.41-8.38 (m, 1H), 8.26-8.22 | 330.13 | 330.12 |
| | (m, 3H), 8.01-8.00 (m, 2H), 7.95-7.91 (m, 1H), 7.86-7.82 (m, 1H), | | |
| | 7.72-7.68 (m, 1H), 7.49-7.44 (m, 3H) | | |
| 14 | δ = 8.71-8.69 (m, 1H), 8.48-8.46 (m, 2H), 8.40-8.36 (m, 2H), 8.25-8.22 | 571.21 | 571.20 |
| | (m, 2H), 7.95-7.91 (m, 2H), 7.88-7.80 (m, 3H), 7.72-7.68 (m, 3H), | | |
| | 7.52-7.41 (m, 8H), 7.32-7.24 (m, 2H) | | |
| 21 | δ = 8.72-8.70 (m, 1H), 8.49-8.47 (m, 1H), 8.42-8.38 (m, 1H), 8.27-8.25 | 505.17 | 505.16 |
| | (m, 1H), 8.03-8.00 (m, 2H), 7.95-7.92 (m, 1H), 7.86-7.82 (m, 1H), | | |
| | 7.79-7.74 (m, 2H), 7.72-7.65 (m, 5H), 7.52-7.47 (m, 2H), 7.45-7.39 | | |
| | (m, 7H) | | |
| 26 | δ = 9.10-9.07 (m, 1H), 8.86-8.84 (m, 1H), 8.78-8.75 (m, 1H), 8.72-8.70 | 506.14 | 506.15 |
| | (m, 1H), 8.49-8.45 (m, 1H), 8.33-8.31 (m, 1H), 7.95-7.91 (m, 2H), | | |
| | 7.85-7.78 (m, 5H), 7.72-7.68 (m, 1H), 7.63-7.60 (m, 1H), 7.53-7.38 | | |
| | (m, 8H) | | |
| 30 | δ = 9.03-9.01 (m, 1H), 8.65-8.63 (m, 1H), 8.55-8.53 (m, 1H), 8.51-8.49 | 648.25 | 648.23 |
| | (m, 1H), 8.41-8.40 (m, 1H), 8.34-8.33 (m, 1H), 8.25-8.21 (m, 3H), | | |
| | 8.18-8.17 (m, 1H), 8.14-8.12 (m, 1H), 8.00-7.94 (m, 3H), 7.86-7.82 | | |
| | (m, 2H), 7.75-7.67 (m, 3H), 7.64-7.61 (m, 1H), 7.52-7.44 (m, 6H), 7.35-7.26 | | |
| | (m, 2H) | | |
| 35 | δ = 8.68-8.66 (m, 1H), 8.41-8.40 (m, 1H), 8.30-8.25 (m, 5H), 8.20-8.11 | 581.20 | 581.21 |
| | (m, 7H), 8.09-8.05 (m, 1H), 7.88-7.81 (m, 5H), 7.75-7.67 (m, 3H), | | |
| | 7.48-7.44 (m, 2H), 7.40-7.36 (m, 2H) | | |
| 40 | δ = 8.87-8.86 (m, 1H), 8.70-8.63 (m, 6H), 8.59-8.56 (m, 3H), 8.45-8.42 | 663.25 | 663.24 |
| | (m, 2H), 8.35-8.31 (m, 2H), 8.26-8.22 (m, 2H), 7.86-7.82 (m, 1H), | | |
| | 7.77-7.70 (m, 3H), 7.63-7.59 (m, 1H), 7.54-7.51 (m, 4H), 7.49-7.41 | | |
| | (m, 4H) | | |
| 42 | δ = 8.70-8.68 (m, 1H), 8.51-8.50 (m, 1H), 8.42-8.41 (m, 1H), 8.38-8.37 | 571.22 | 571.20 |
| | (m, 1H), 8.26-8.23 (m, 2H), 8.09-8.06 (m, 1H), 7.95-7.92 (m, 2H), | | |
| | 7.87-7.82 (m, 2H), 7.75-7.58 (m, 7H), 7.53-7.46 (m, 4H), 7.43-7.39 | | |
| | (m, 1H), 7.34-7.24 (m, 2H) | | |
| 45 | δ = 8.67-8.65 (m, 1H), 8.49-8.48 (m, 1H), 8.44-8.43 (m, 1H), 8.39-8.38 | 747.28 | 747.27 |
| | (m, 1H), 8.30-8.26 (m, 2H), 7.94-7.92 (m, 2H), 7.88-7.79 (m, 7H), | | |
| | 7.75-7.59 (m, 7H), 7.53-7.47 (m, 4H), 7.42-7.24 (m, 7H) | | |
| 50 | δ = 9.09-9.08 (m, 1H), 8.94-8.92 (m, 1H), 8.69-8.65 (m, 1H), 8.53-8.51 | 535.21 | 535.20 |
| | (m, 1H), 8.31-8.29 (m, 4H), 8.27-8.26 (m, 1H), 8.00 (s, 1H), 7.96-7.93 | | |
| | (m, 2H), 7.88-7.82 (m, 2H), 7.75-7.71 (m, 1H), 7.68-7.59 (m, 4H), | | |
| | 7.53-7.48 (m, 4H), 7.31-7.27 (m, 2H) | | |
| 54 | δ = 9.01-9.00 (m, 1H), 8.71-8.69 (m, 1H), 8.68-8.66 (m, 1H), 8.63-8.62 | 608.24 | 608.23 |
| | (m, 1H), 8.42-8.40 (m, 1H), 8.28-8.25 (m, 2H), 7.87-7.81 (m, 6H), | | |
| | 7.80-7.70 (m, 5H), 7.66-7.64 (m, 1H), 7.42-7.30 (m, 8H), 7.08-7.04 | | |
| | (m, 1H) | | |
| 59 | δ = 8.78-8.77 (m, 1H), 8.69-8.67 (m, 1H), 8.53-8.51 (m, 1H), 8.46-8.45 | 483.16 | 483.17 |
| | (m, 1H), 8.34-8.31 (m, 2H), 8.26-8.24 (m, 1H), 8.14-8.12 (m, 1H), | | |
| | 8.04-8.01 (m, 2H), 7.93-7.90 (m, 2H), 7.86-7.81 (m, 3H), 7.79-7.77 | | |
| | (m, 1H), 7.75-7.68 (m, 3H), 7.47-7.38 (m, 2H) | | |
| 63 | δ = 8.68-8.65 (m, 1H), 8.45-8.44 (m, 1H), 8.27-8.24 (m, 2H), 8.18-8.14 | 581.20 | 581.19 |
| | (m, 1H), 7.95-7.92 (m, 2H), 7.86-7.82 (m, 1H), 7.75-7.47 (m, 15H), | | |
| | 7.44-7.39 (m, 5H) | | |
| 68 | δ = 8.66-8.64 (m, 1H), 8.51-8.50 (m, 1H), 8.27-8.25 (m, 1H), 8.14-8.12 | 521.13 | 521.14 |
| | (m, 1H), 7.97-7.91 (m, 5H), 7.86-7.82 (m, 3H), 7.79-7.75 (m, 2H), | | |
| | 7.73-7.70 (m, 1H), 7.68-7.55 (m, 5H), 7.52-7.48 (m, 2H), 7.40-7.36 | | |
| | (m, 1H) | | |
| 79 | δ = 8.81-8.79 (m, 2H), 8.51-8.47 (m, 4H), 8.44-8.42 (m, 1H), 8.40-8.37 | 611.25 | 611.24 |
| | (m, 1H), 8.34-8.33 (m, 1H), 8.08-8.06 (m, 1H), 8.01 (t, 1H), 7.99 | | |
| | (t, 1H), 7.96-7.92 (m, 2H), 7.83-7.76 (m, 6H), 7.54-7.43 (m, 8H), 7.38-7.34 | | |
| | (m, 1H) | | |
| 88 | δ = 9.01-9.00 (m, 1H), 8.73-8.71 (m, 1H), 8.54-8.52 (m, 2H), 8.49-8.46 | 558.22 | 558.21 |
| | (m, 1H), 8.42-8.38 (m, 1H), 8.30-8.28 (m, 1H), 8.23-8.21 (dd, 2H), | | |
| | 8.07-8.05 (m, 1H), 8.00-7.97 (dd, 2H), 7.95-7.87 (m, 3H), 7.66-7.58 | | |
| | (m, 3H), 7.52-7.48 (m, 1H), 7.45-7.41 (m, 3H), 7.39-7.30 (m, 4H) | | |
| 89 | δ = 8.82-8.80 (m, 1H), 8.53-8.49 (m, 2H), 8.47-8.44 (m, 1H), 8.11-8.09 | 582.20 | 582.19 |
| | (m, 1H), 7.95-7.85 (m, 6H), 7.78-7.72 (m, 4H), 7.65-7.60 (m, 3H), | | |
| | 7.56-7.51 (m, 2H), 7.45-7.40 (m, 7H) | | |
| 94 | δ = 8.92-8.91 (m, 1H), 8.75-8.73 (m, 1H), 8.66-8.64 (m, 1H), 8.61-8.59 | 506.19 | 506.18 |
| | (m, 1H), 8.57-8.56 (m, 1H), 8.47-8.43 (m, 2H), 8.40-8.35 (m, 2H), | | |
| | 8.27-8.25 (m, 1H), 8.20-8.18 (m, 3H), 8.09-8.05 (m, 1H), 7.95-7.91 | | |
| | (m, 1H), 7.88-7.86 (m, 1H), 7.81-7.79 (m, 1H), 7.69-7.67 (m, 1H), 7.56-7.54 | | |
| | (m, 1H), 7.45-7.42 (m, 2H), 7.39-7.36 (m, 1H) | | |
| 99 | δ = 8.69-8.67 (m, 2H), 8.57-8.55 (m, 1H), 8.48-8.47 (m, 1H), 8.45-8.42 | 522.15 | 522.14 |
| | (m, 1H), 8.39-8.37 (m, 1H), 8.29 (t, 1H), 8.24-8.19 (m, 3H), 7.95-7.92 | | |
| | (m, 3H), 7.88-7.87 (m, 1H), 7.85 (d, 1H), 7.62-7.58 (m, 2H), 7.54-7.50 | | |
| | (m, 2H), 7.46-7.42 (m, 3H) | | |
| 101 | δ = 9.02-9.01 (m, 1H), 8.92-8.90 (m, 1H), 8.81-8.79 (m, 1H), 8.70-8.68 | 637.24 | 637.23 |
| | (m, 4H), 8.53-8.52 (m, 1H), 8.27-8.24 (m, 3H), 8.17-8.15 (m, 2H), | | |
| | 8.04-8.01 (m, 2H), 7.83-7.80 (dd, 1H), 7.72-7.68 (m, 1H), 7.54-7.51 | | |
| | (m, 4H), 7.48-7.36 (m, 6H) | | |

### Example 1

An anode was prepared by cutting a Corning 15 Ω² cm² (1,200 Å) ITO glass substrate to a size of 50 mm×50 mm×0.7 mm, ultrasonically cleaning the glass substrate by using isopropyl alcohol and pure water for 5 minutes each, and then irradiating UV light for 30 minutes thereto and exposing to ozone to clean. Then, the anode was loaded into a vacuum deposition apparatus.

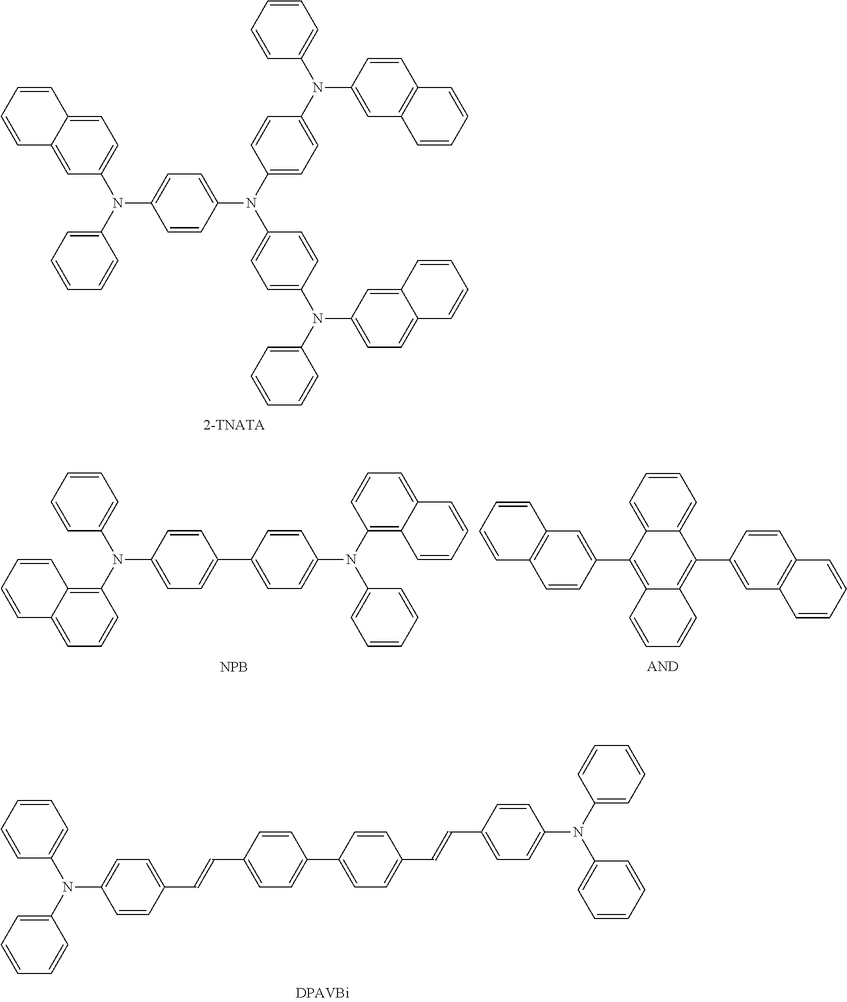

2-TNATA was vacuum deposited on the resultant substrate to form a hole injection layer having a thickness of 600 Å, and then, 4,4t-bis[N-(1-naphthyl)-N-phenylamino]biphenyl (NPB), as a hole transport compound, was deposited thereon to form a hole transport layer having a thickness of 300 Å. 9,10-di-naphthalene-2-yl-anthracene (ADN), as a blue fluorescent host, and 4,4′-bis[2-(4-(N,N-diphenylamino)phenyl)vinyl]biphenyl (DPAVBi), as a fluorescent dopant, were co-deposited at a weight ratio of 98:2 on the hole transport layer to form an emission layer having a thickness of 300 Å.

Then, Compound 2 was deposited on the emission layer to form an electron transport layer having a thickness of 300 Å. LiF, which is a halogenated alkalimetal, was deposited on the electron transport layer to form an electron injection layer having a thickness of 10 Å, and Al was vacuum deposited thereon to a thickness of 3,000 Å (cathode), thereby forming an LiF/Al electrode, thereby completing the manufacturing of an organic light-emitting device.

The device had, at a current density of 50 mA/cm², a driving voltage of 5.43V, a luminescence brightness of 3,185 cd/m², a luminescence efficiency of 6.37 cd/A, and a half-lifespan (hr @100 mA/cm²) of 278 hours.

### Example 2

An organic light-emitting device was manufactured in the same manner as in Example 1, except that in forming the electron transport layer, Compound 14 was used instead of Compound 2.

The device had, at a current density of 50 mA/cm², a driving voltage of 5.95V, a luminescence brightness of 3,010 cd/m², a luminescence efficiency of 6.02 cd/A, and a half-lifespan (hr @100 mA/cm²) of 322 hours.

### Example 3

An organic light-emitting device was manufactured in the same manner as in Example 1, except that in forming the electron transport layer, Compound 21 was used instead of Compound 2.

The device had, at a current density of 50 mA/cm², a driving voltage of 6.04V, a luminescence brightness of 3,075 cd/m², a luminescence efficiency of 6.15 cd/A, and a half-lifespan (hr @100 mA/cm²) of 362 hours.

### Example 4

An organic light-emitting device was manufactured in the same manner as in Example 1, except that in forming the electron transport layer, Compound 35 was used instead of Compound 2.

The device had, at a current density of 50 mA/cm², a driving voltage of 6.01V, a luminescence brightness of 3,160 cd/m², a luminescence efficiency of 6.32 cd/A, and a half-lifespan (hr @100 mA/cm²) of 297 hours.

### Example 5

An organic light-emitting device was manufactured in the same manner as in Example 1, except that in forming the electron transport layer, Compound 42 was used instead of Compound 2.

The device had, at a current density of 50 mA/cm², a driving voltage of 5.84V, a luminescence brightness of 3,280 cd/m², a luminescence efficiency of 6.56 cd/A, and a half-lifespan (hr @100 mA/cm²) of 310 hours.

### Example 6

An organic light-emitting device was manufactured in the same manner as in Example 1, except that in forming the electron transport layer, Compound 54 was used instead of Compound 2.

The device had, at a current density of 50 mA/cm², a driving voltage of 6.08V, a luminescence brightness of 3,055 cd/m², a luminescence efficiency of 6.11 cd/A, and a half-lifespan (hr @100 mA/cm²) of 298 hours.

### Example 7

An organic light-emitting device was manufactured in the same manner as in Example 1, except that in forming the electron transport layer, Compound 63 was used instead of Compound 2.

The device had, at a current density of 50 mA/cm², a driving voltage of 6.15V, a luminescence brightness of 3,140 cd/m², a luminescence efficiency of 6.28 cd/A, and a half-lifespan (hr @100 mA/cm²) of 349 hours.

### Example 8

An organic light-emitting device was manufactured in the same manner as in Example 1, except that in forming the electron transport layer, Compound 94 was used instead of Compound 2.

The device had, at a current density of 50 mA/cm², a driving voltage of 5.81 V, a luminescence brightness of 3,155 cd/m², a luminescence efficiency of 6.31 cd/A, and a half-lifespan (hr @100 mA/cm²) of 300 hours.

### Example 9

An organic light-emitting device was manufactured in the same manner as in Example 1, except that in forming the electron transport layer, Compound 101 was used instead of Compound 2.

The device had, at a current density of 50 mA/cm², a driving voltage of 5.76V, a luminescence brightness of 3,110 cd/m², a luminescence efficiency of 6.22 cd/A, and a half-lifespan (hr @100 mA/cm²) of 313 hours.

### Comparative Example 1

An organic light-emitting device was manufactured in the same manner as in Example 1, except that in forming the electron transport layer, Algₐ, which is a known material, was used instead of Compound 2.

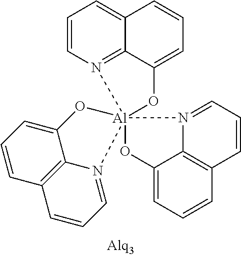

The device had, at a current density of 50 mA/cm², a driving voltage of 7.35V, a luminescence brightness of 2,065 cd/m², a luminescence efficiency of 4.13 cd/A, and a half-lifespan (hr @100 mA/cm²) of 145 hours.

When the compounds having the structure represented by Formula 1 according to embodiments were used as an electron transport material, they all had a driving voltage that was 1 V or lower than that of Algₐ, which is a known material, and also showed high efficiency and excellent I-V-L characteristics, and in particular, excellent lifespan improvement effects. Such results show that compounds including a novel condensed ring, in particular a compound represented by Formula 1 according to embodiments, have high effects as an electron transport material. Measurements and lifespans of the organic light-emitting devices manufactured according to Examples explained above are shown in Table 2 below.

TABLE 2

| | | Driving | Current | | | | Half lifespan |
|---|---|---|---|---|---|---|---|
| | Electron | voltage | density | Brightness | Efficiency | Emission | (hours @ |
| | transport layer | (V) | (mA/cm²) | [cd/m²] | (cd/A) | color | 100 mA/cm²) |
| Example 1 | Compound 2 | 5.43 | 50 | 3,185 | 6.37 | Blue | 278 hours |
| Example 2 | Compound 14 | 5.95 | 50 | 3,010 | 6.02 | Blue | 322 hours |
| Example 3 | Compound 21 | 6.04 | 50 | 3,075 | 6.15 | Blue | 362 hours |
| Example 4 | Compound 35 | 6.01 | 50 | 3,160 | 6.32 | Blue | 297 hours |
| Example 5 | Compound 42 | 5.84 | 50 | 3,280 | 6.56 | Blue | 310 hours |
| Example 6 | Compound 54 | 6.08 | 50 | 3,055 | 6.11 | Blue | 298 hours |
| Example 7 | Compound 63 | 6.15 | 50 | 3,140 | 6.28 | Blue | 349 hours |
| Example 8 | Compound 94 | 5.81 | 50 | 3,155 | 6.31 | Blue | 300 hours |
| Example 9 | Compound 101 | 5.76 | 50 | 3,110 | 6.22 | Blue | 313 hours |
| Comparative | Alq3 | 7.35 | 50 | 2,065 | 4.13 | Blue | 145 hours |
| Example 1 | | | | | | | |

Compounds represented by Formula 1 have excellent material stabilities and are suitable for use as an electron transport material. An organic light-emitting device manufactured using a compound represented by Formula 1 may have high efficiency, low voltage, high brightness, and a long lifespan.

By way of summation and review, a general organic light-emitting device has a structure including a substrate, and an anode, a hole transport layer, an emission layer, an electron transport layer, and a cathode which are sequentially stacked on the substrate. The hole transport layer, the emission layer, and the electron transport layer are organic thin films formed of organic compounds.

The driving principle of an organic light-emitting device having such a structure is as follows:

When a voltage is applied between the anode and the cathode, holes injected from the anode pass the hole transport layer and migrate toward the emission layer, and electrons injected from the cathode pass the electron transport layer and migrate toward the emission layer. Carriers, such as holes and electrons, are recombined in the emission layer to produce excitons. These excitons change from an excited state to a ground state, thereby generating light.

It is desirable to provide a material that has excellent electric stability, high charge transport capability or luminescent capability, high glass transition temperature, and high crystallization prevention capability, compared to an organic monomolecular material.

Embodiments provide a compound that has excellent electric characteristics, a high charge transporting capability, a high light-emitting capability, a high glass transition temperature, and a crystallization-preventing capability, and that is suitable for use as an electron transport material. Embodiments further provide an organic light-emitting device that has high efficiency, low voltage, high brightness, long lifespan due to the inclusion of the compound.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope as set forth in the following claims.

What is claimed is:

1. A compound represented by Formula 1 below: 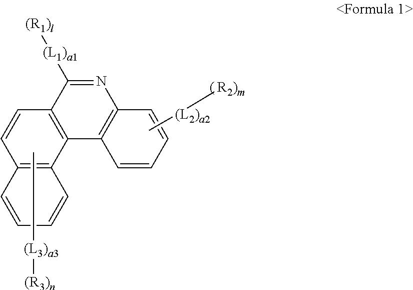
wherein in Formula 1,
R₁ to R₃ are each independently a hydrogen; a deuterium; a halogen; a cyano group; a hydroxyl group; a nitro group; an amino group; an amidino group; a hydrazine group; a hydrazone group; carboxylic acid or a salt thereof; a sulfonic acid or a salt thereof; a phosphoric acid or a salt thereof; a substituted or unsubstituted C₁ to C₆₀ alkyl group; a substituted or unsubstituted C₂ to C₆₀ alkenyl group; a substituted or unsubstituted C₂ to C₆₀ alkynyl group; a substituted or unsubstituted C₃ to C₆₀ cycloalkyl group; a substituted or unsubstituted C₃ to C₆₀ cycloalkenyl group; a substituted or unsubstituted C₆ to C₆₀ aryl group; a substituted or unsubstituted C₁ to C₆₀ heteroaryl group; or a C₆ to C₆₀ substituted or unsubstituted condensed polycyclic group; —P(═O)R₄R₅; —P(═S)R₆R₇; —S(═O)R₈; or —S(═O)₂R₉,
L₁ to L₃ are each independently a C₃ to C₁₀ substituted or unsubstituted cycloalkylene group; a C₃ to C₁₀ substituted or unsubstituted heterocycloalkylene group; a C₃ to C₁₀ substituted or unsubstituted cycloalkenylene group; a C₃ to C₁₀ substituted or unsubstituted heterocycloalkenylene group; a C₆ to C₆₀ substituted or unsubstituted arylene group; a C₁ to C₆₀ substituted or unsubstituted heteroarylene group; a C₆ to C₆₀ substituted or unsubstituted condensed polycyclic group; —P(═O)R₄—; —P(═S)R₅—; —S(═O)—; or —S(═O)₂—;
R₄ to R₉ are each independently a hydrogen; a deuterium; a substituted or unsubstituted C₆ to C₆₀ aryl group; a substituted or unsubstituted C₁ to C₆₀ heteroaryl group; or a C₆ to C₆₀ substituted or unsubstituted condensed polycyclic group,
a1 to a3 are each independently an integer of 0 to 3; and
l, m, and n are each independently 1 or 2.

2. The compound as claimed in claim 1, wherein:
L₁ to L₃ are each independently a C₆ to C₃₀ substituted or unsubstituted arylene group; a C₁ to C₃₀ substituted or unsubstituted heteroarylene group; a C₆ to C₃₀ substituted or unsubstituted condensed polycyclic group; —P(═O)R₄—; —P(═S)R₅—; —S(═O)—; or —S(═O)₂—, and
R₄ and R₅ are as defined in claim 1.

3. The compound as claimed in claim 1, wherein:
R₁ to R₃ in Formula 1 are each independently a hydrogen; a deuterium; a cyano group; a substituted or unsubstituted C₆ to C₃₀ aryl group; a substituted or unsubstituted C₁ to C₃₀ heteroaryl group; a C₆ to C₃₀ substituted or unsubstituted condensed polycyclic group; —P(═O)R₄R₅; —P(═S)R₆R₇; —S(═O)R₈; or —S(═O)₂R₉, and
R₄ to R₉ are as defined in claim 1.

4. The compound as claimed in claim 1, wherein:
R₁ in Formula 1 is a cyano group; a substituted or unsubstituted C₆ to C₃₀ aryl group; a substituted or unsubstituted C₁ to C₃₀ heteroaryl group; a C₃ to C₆₀ substituted or unsubstituted condensed polycyclic group; —P(═O)R₄R₅; —P(═S)R₆R₇; —S(═O)R₈; or —S(═O)₂R₉, and
R₄ to R₉ are as defined in claim 1.

5. The compound as claimed in claim 1, wherein:
R₂ in Formula 1 is a cyano group; a substituted or unsubstituted C₆ to C₃₀ aryl group; a substituted or unsubstituted C₁ to C₃₀ heteroaryl group; a C₃ to C₆₀ substituted or unsubstituted condensed polycyclic group; —P(═O)R₄R₅; —P(═S)R₆R₇; —S(═O)R₈; or —S(═O)₂R₉, and
R₄ to R₉ are as defined in claim 1.

6. The compound as claimed in claim 1, wherein:
R₃ in Formula 1 is a cyano group; a substituted or unsubstituted C₆ to C₃₀ aryl group; a substituted or unsubstituted C₁ to C₃₀ heteroaryl group; a C₃ to C₆₀ substituted or unsubstituted condensed polycyclic group; —P(═O)R₄R₅; —P(═S)R₆R₇; —S(═O)R₈; or —S(═O)₂R₉, and
R₄ to R₉ are as defined in claim 1.

7. The compound as claimed in claim 1, wherein R₂ and R₃ in Formula 1 are each a hydrogen or a deuterium, and a2 and a3 are each 0.

8. The compound as claimed in claim 1, wherein, in Formula 1, R₂ is a hydrogen or a deuterium, and a2 is 0.

9. The compound as claimed in claim 1, wherein, in Formula 1, R₃ is a hydrogen or a deuterium, and a3 is 0.

10. The compound as claimed in claim 1, wherein:
L₁ to L₃ in Formula 1 are each independently —P(═O)R₄—; —P(═S)R₅—; —S(═O)—; —S(═O)₂—; or one of Formulae 2a to 2h illustrated below: 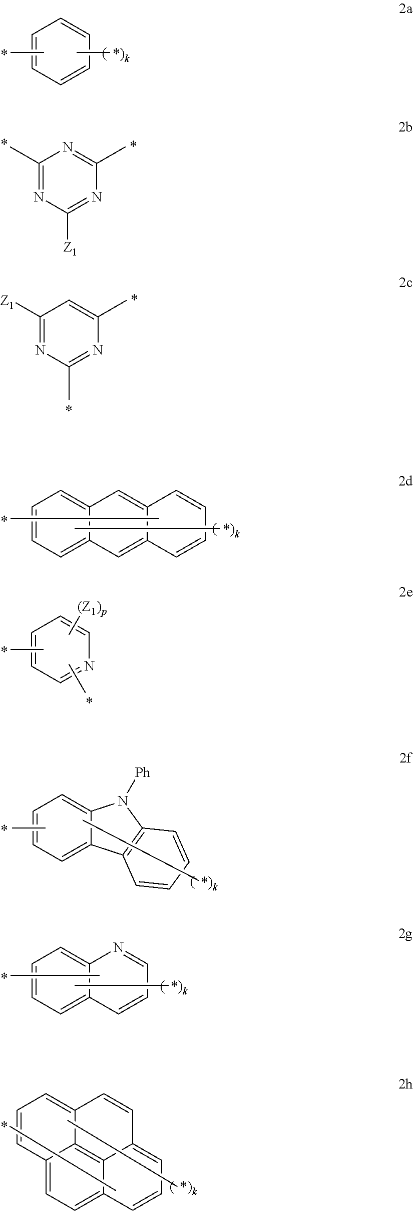
wherein in Formulae 2a to 2h above, Z₁ is a hydrogen; a deuterium; a substituted or unsubstituted C₁ to C₂₀ alkyl group; a substituted or unsubstituted C₆ to C₂₀ aryl group; a substituted or unsubstituted C₁ to C₂₀ heteroaryl group; a substituted or unsubstituted C₆ to C₂₀ condensed polycyclic group; a halogen group; a cyano group; a nitro group; a hydroxyl group; or a carboxy group;
p and k are each independently an integer of 1 to 3;
* indicates a binding site; and
R₄ and R₅ are as defined in claim 1.

11. The compound as claimed in claim 1, wherein
R₁ to R₃ in Formula 1 are each independently a hydrogen; a deuterium; a cyano group; —P(═O)R₄R₅; —P(═S)R₆R₇; —S(═O)R₈; —S(═O)₂R₉; or any one of Formulae 3a to 3h illustrated below: 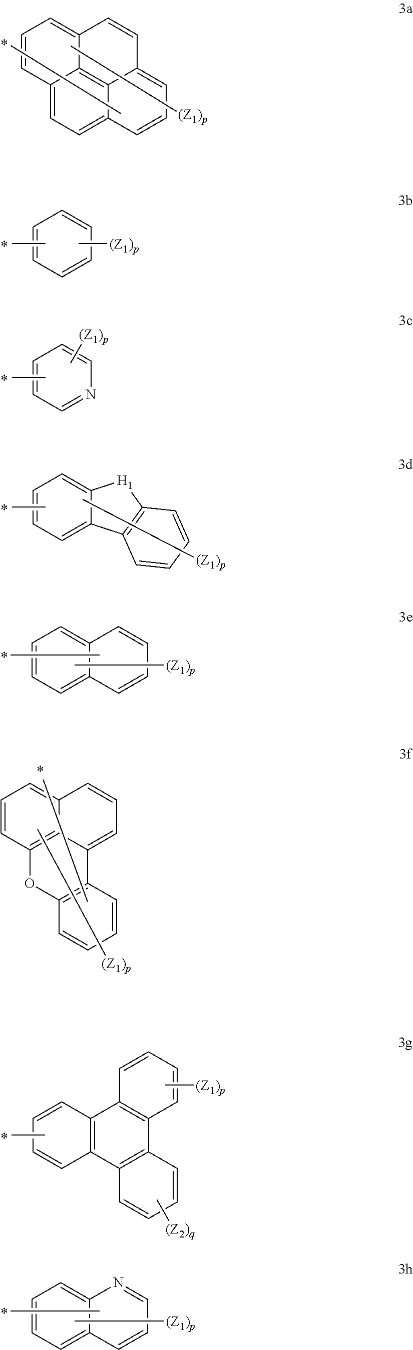
wherein in Formulae 3a to 3h above, Z₁ and Z₂ are each independently a hydrogen, a deuterium, a substituted or unsubstituted C₁ to C₂₀ alkyl group, a substituted or unsubstituted C₆ to C₂₀ aryl group, a substituted or unsubstituted C₁ to C₂₀ heteroaryl group, a substituted or unsubstituted C₆ to C₂₀ condensed polycyclic group, a halogen group, a cyano group, a nitro group, a hydroxyl group, or a carboxy group;
p and q are each independently an integer of 1 to 9;
* indicates a binding site; and
R₄ to R₉ are as defined in claim 1.

12. The compound as claimed in claim 1, wherein the compound of Formula 1 is any one of compounds 1 through 102 below:

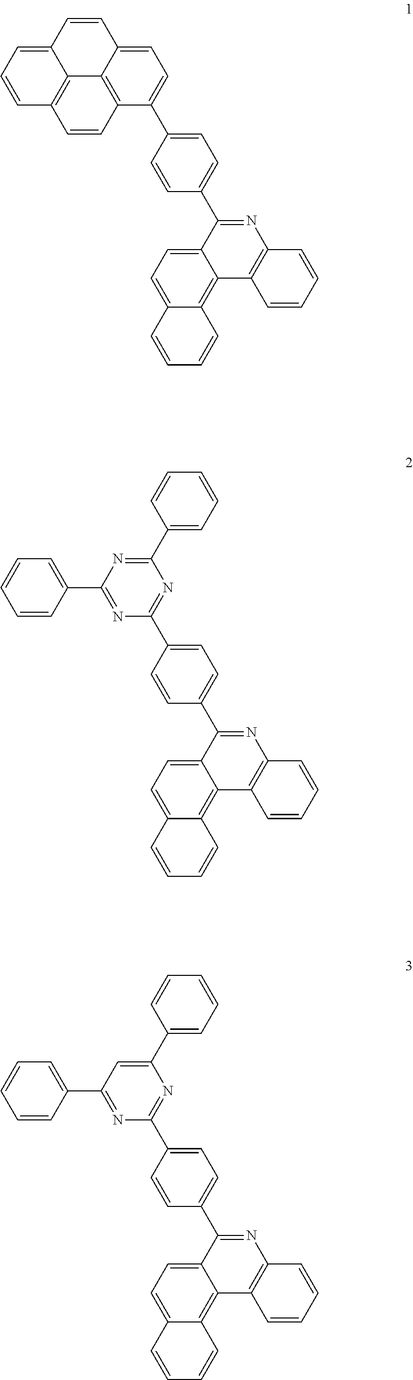 [SMILES: c1ccc2c(c1)ccc1c(-c3ccc(-c4ccc5ccc6cccc7ccc4c5c67)cc3)nc3ccccc3c12 ; c1ccc(-c2nc(-c3ccccc3)nc(-c3ccc(-c4nc5ccccc5c5c4ccc4ccccc45)cc3)n2)cc1 ; c1ccc(-c2cc(-c3ccccc3)nc(-c3ccc(-c4nc5ccccc5c5c4ccc4ccccc45)cc3)n2)cc1]

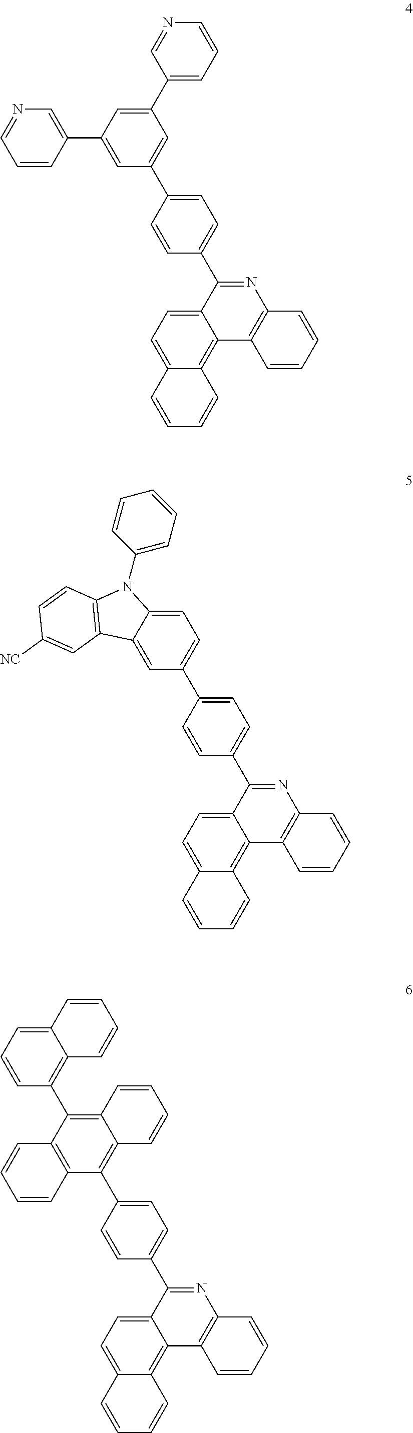 [SMILES: c1cncc(-c2cc(-c3ccc(-c4nc5ccccc5c5c4ccc4ccccc45)cc3)cc(-c3cccnc3)c2)c1 ; N#Cc1ccc2c(c1)c1cc(-c3ccc(-c4nc5ccccc5c5c4ccc4ccccc45)cc3)ccc1n2-c1ccccc1 ; c1ccc2c(-c3c4ccccc4c(-c4ccc(-c5nc6ccccc6c6c5ccc5ccccc56)cc4)c4ccccc34)cccc2c1]

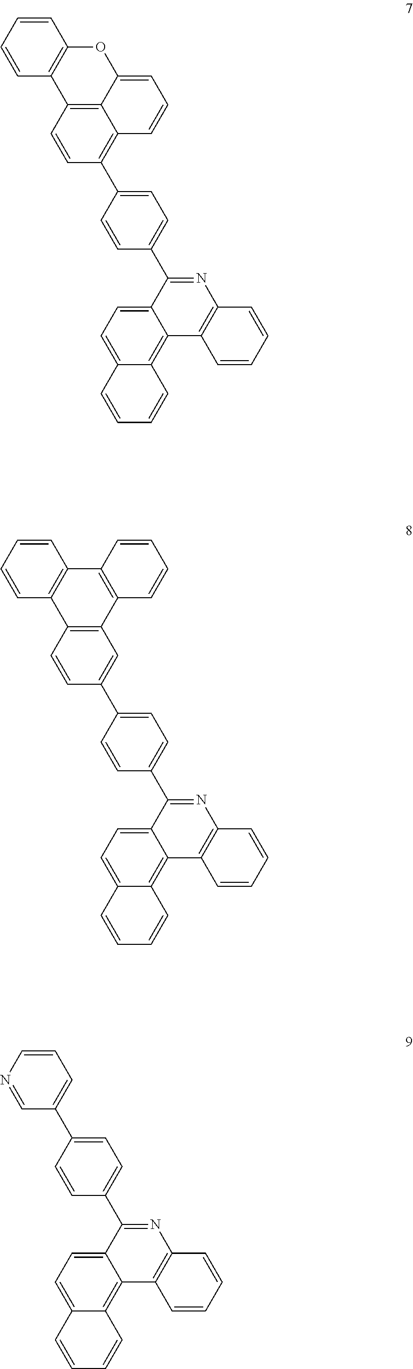 [SMILES: c1ccc2c(c1)Oc1cccc3c(-c4ccc(-c5nc6ccccc6c6c5ccc5ccccc56)cc4)ccc-2c13 ; c1ccc2c(c1)ccc1c(-c3ccc(-c4ccc5c6ccccc6c6ccccc6c5c4)cc3)nc3ccccc3c12 ; c1cncc(-c2ccc(-c3nc4ccccc4c4c3ccc3ccccc34)cc2)c1]

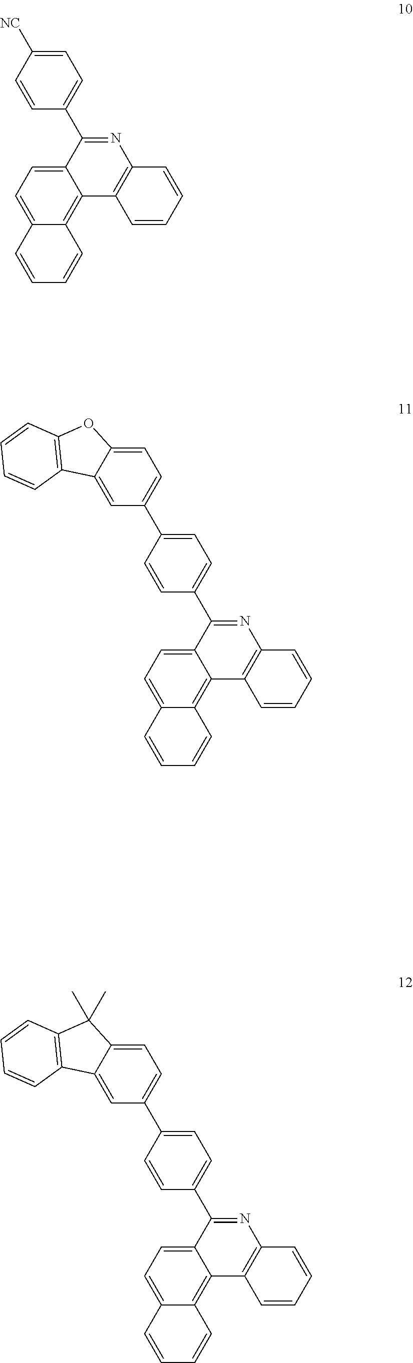 [SMILES: N#Cc1ccc(-c2nc3ccccc3c3c2ccc2ccccc23)cc1 ; c1ccc2c(c1)ccc1c(-c3ccc(-c4ccc5oc6ccccc6c5c4)cc3)nc3ccccc3c12 ; CC1(C)c2ccccc2-c2cc(-c3ccc(-c4nc5ccccc5c5c4ccc4ccccc45)cc3)ccc21]

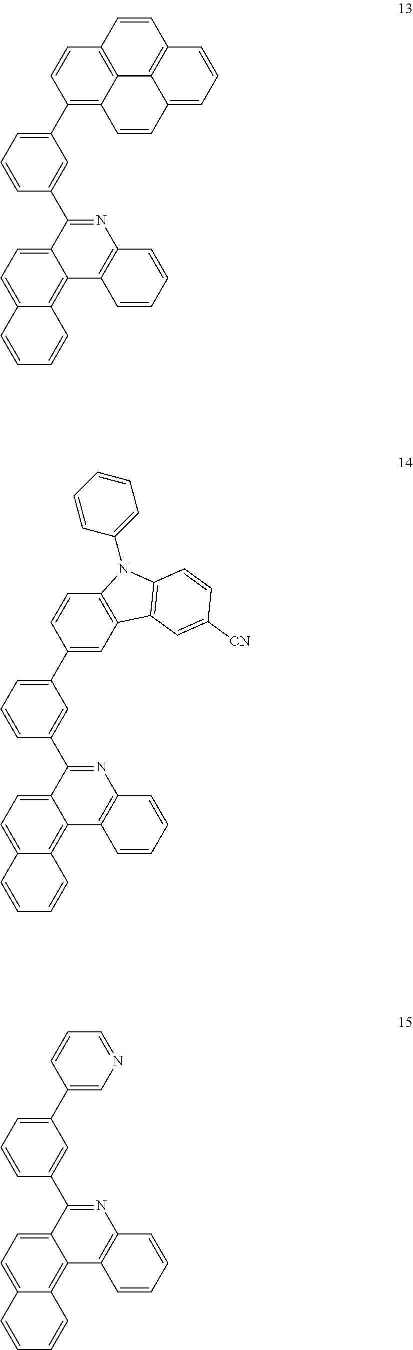 [SMILES: c1cc(-c2nc3ccccc3c3c2ccc2ccccc23)cc(-c2ccc3ccc4cccc5ccc2c3c45)c1 ; N#Cc1ccc2c(c1)c1cc(-c3cccc(-c4nc5ccccc5c5c4ccc4ccccc45)c3)ccc1n2-c1ccccc1 ; c1cncc(-c2cccc(-c3nc4ccccc4c4c3ccc3ccccc34)c2)c1]

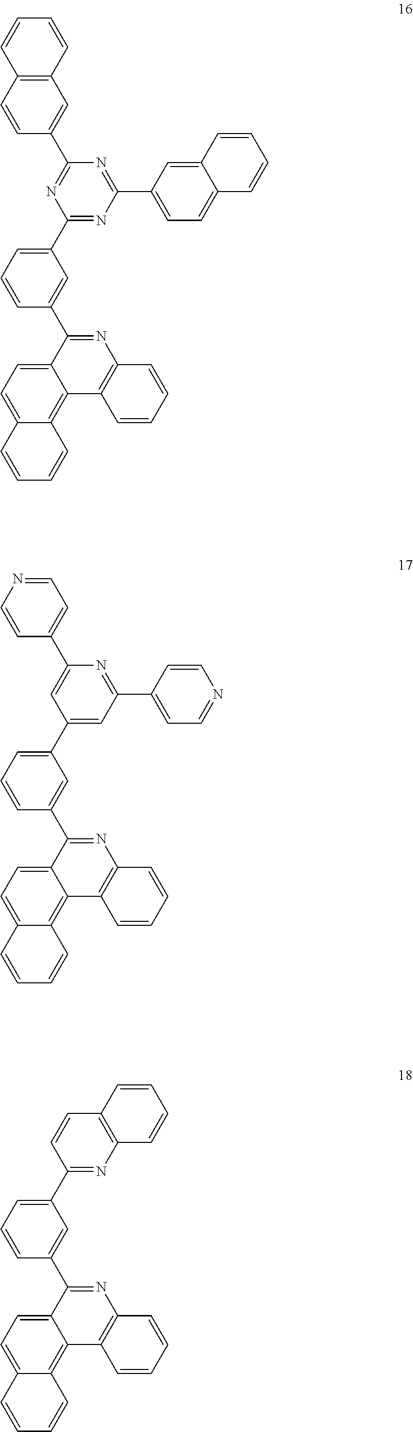 [SMILES: c1cc(-c2nc(-c3ccc4ccccc4c3)nc(-c3ccc4ccccc4c3)n2)cc(-c2nc3ccccc3c3c2ccc2ccccc23)c1 ; c1cc(-c2cc(-c3ccncc3)nc(-c3ccncc3)c2)cc(-c2nc3ccccc3c3c2ccc2ccccc23)c1 ; c1cc(-c2ccc3ccccc3n2)cc(-c2nc3ccccc3c3c2ccc2ccccc23)c1]

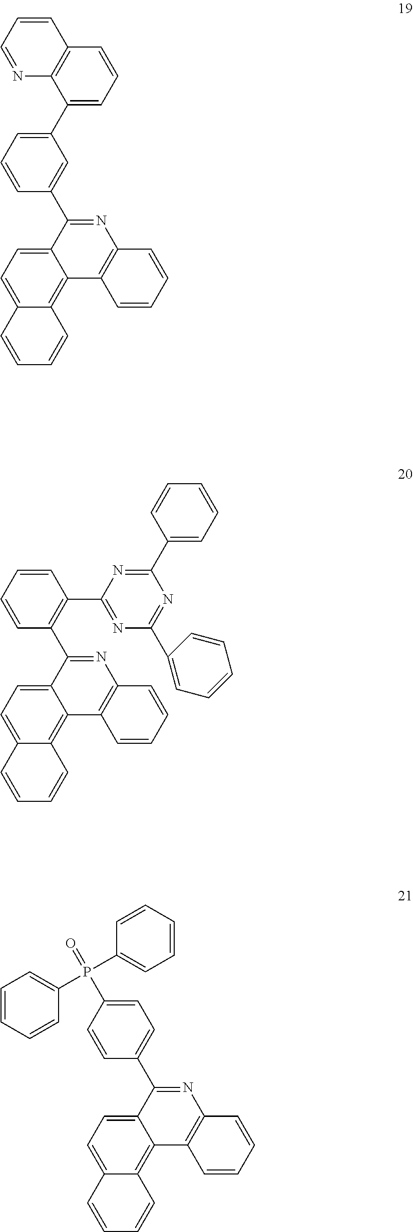 [SMILES: c1cc(-c2nc3ccccc3c3c2ccc2ccccc23)cc(-c2cccc3cccnc23)c1 ; c1ccc(-c2nc(-c3ccccc3)nc(-c3ccccc3-c3nc4ccccc4c4c3ccc3ccccc34)n2)cc1 ; O=P(c1ccccc1)(c1ccccc1)c1ccc(-c2nc3ccccc3c3c2ccc2ccccc23)cc1]

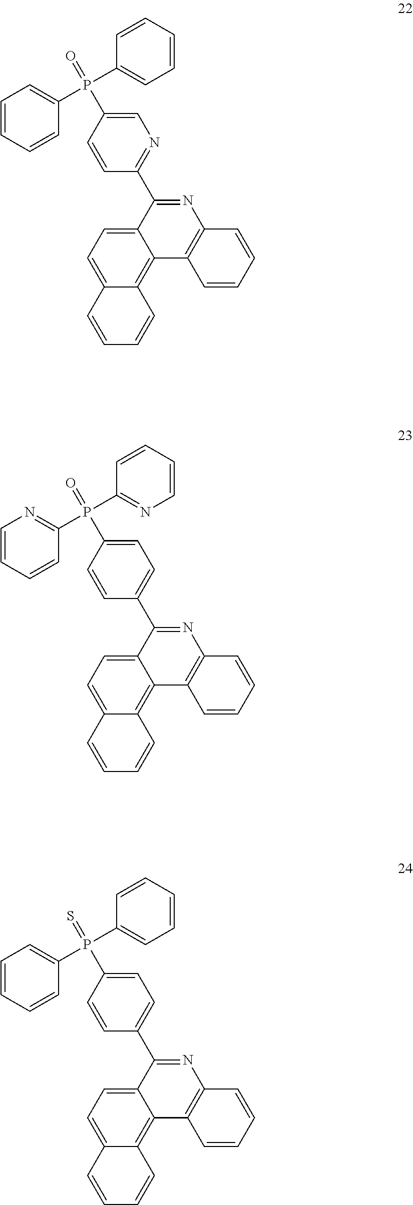 [SMILES: O=P(c1ccccc1)(c1ccccc1)c1ccc(-c2nc3ccccc3c3c2ccc2ccccc23)nc1 ; O=P(c1ccc(-c2nc3ccccc3c3c2ccc2ccccc23)cc1)(c1ccccn1)c1ccccn1 ; S=P(c1ccccc1)(c1ccccc1)c1ccc(-c2nc3ccccc3c3c2ccc2ccccc23)cc1]

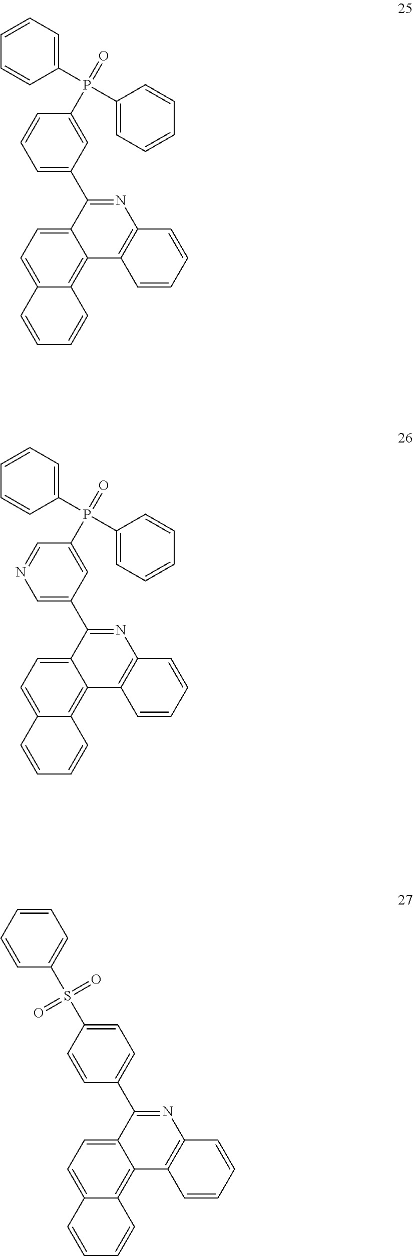 [SMILES: O=P(c1ccccc1)(c1ccccc1)c1cccc(-c2nc3ccccc3c3c2ccc2ccccc23)c1 ; O=P(c1ccccc1)(c1ccccc1)c1cncc(-c2nc3ccccc3c3c2ccc2ccccc23)c1 ; O=S(=O)(c1ccccc1)c1ccc(-c2nc3ccccc3c3c2ccc2ccccc23)cc1]

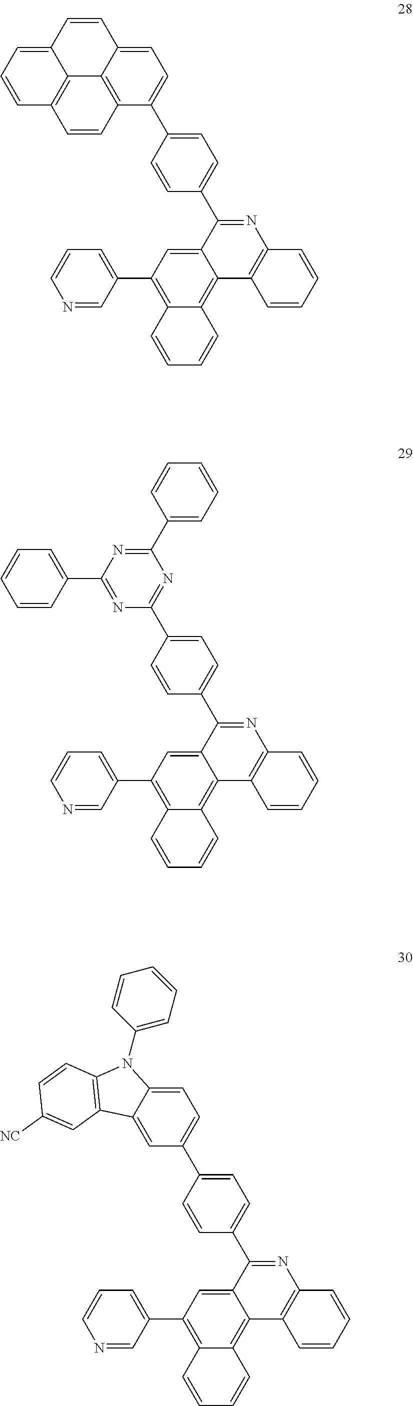 [SMILES: c1cncc(-c2cc3c(-c4ccc(-c5ccc6ccc7cccc8ccc5c6c78)cc4)nc4ccccc4c3c3ccccc23)c1 ; c1ccc(-c2nc(-c3ccccc3)nc(-c3ccc(-c4nc5ccccc5c5c4cc(-c4cccnc4)c4ccccc45)cc3)n2)cc1 ; N#Cc1ccc2c(c1)c1cc(-c3ccc(-c4nc5ccccc5c5c4cc(-c4cccnc4)c4ccccc45)cc3)ccc1n2-c1ccccc1]

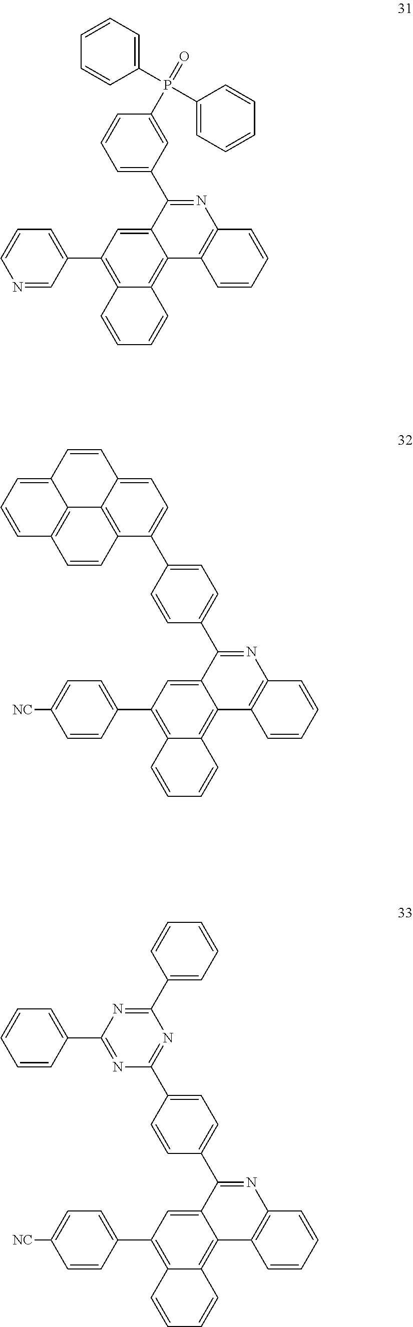

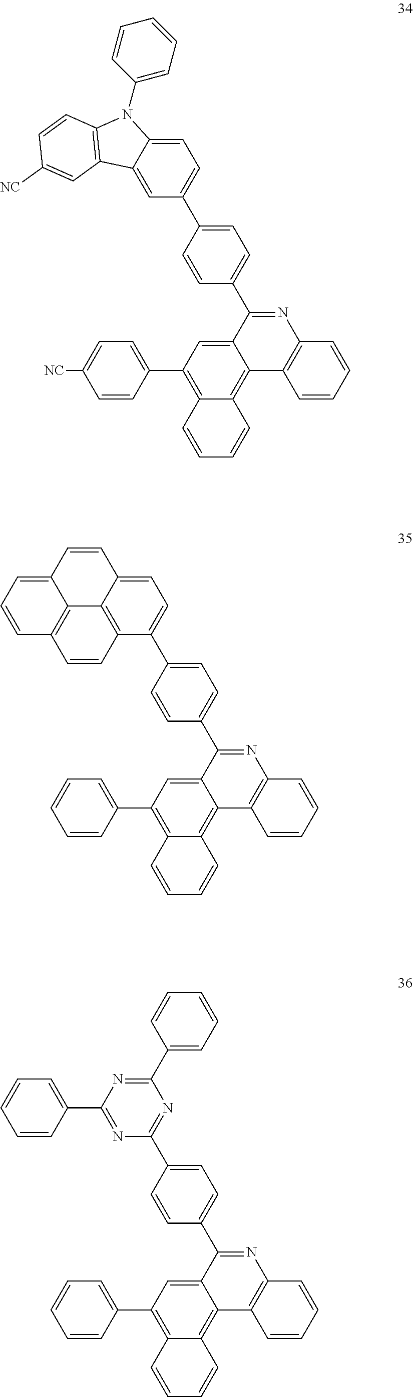

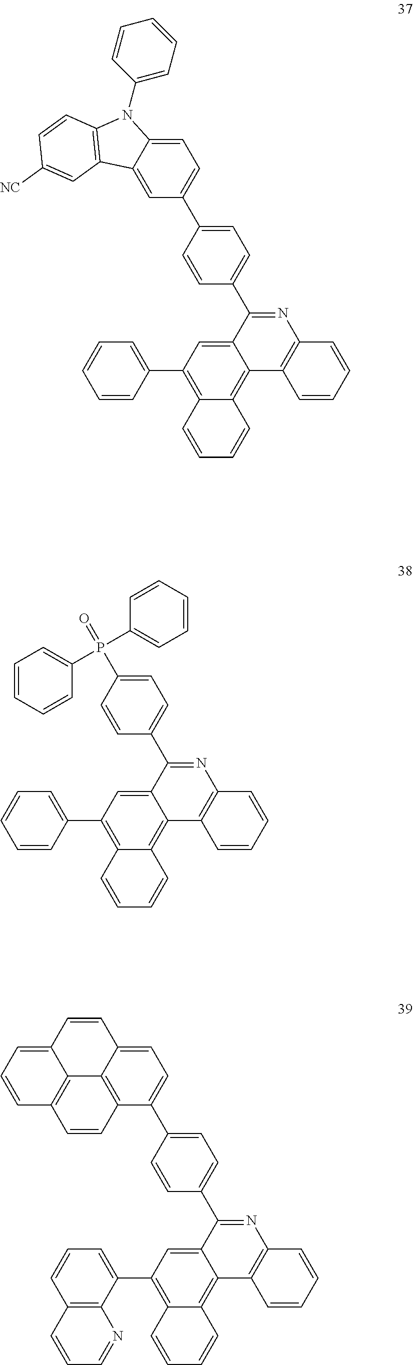 [SMILES: N#Cc1ccc2c(c1)c1cc(-c3ccc(-c4nc5ccccc5c5c4cc(-c4ccccc4)c4ccccc45)cc3)ccc1n2-c1ccccc1 ; O=P(c1ccccc1)(c1ccccc1)c1ccc(-c2nc3ccccc3c3c2cc(-c2ccccc2)c2ccccc23)cc1 ; c1cnc2c(-c3cc4c(-c5ccc(-c6ccc7ccc8cccc9ccc6c7c89)cc5)nc5ccccc5c4c4ccccc34)cccc2c1]

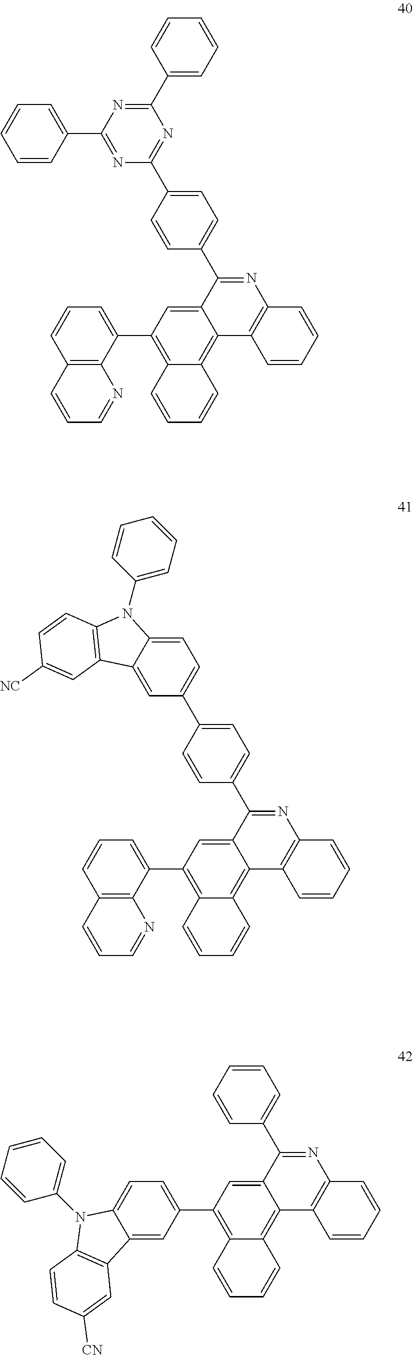 [SMILES: c1ccc(-c2nc(-c3ccccc3)nc(-c3ccc(-c4nc5ccccc5c5c4cc(-c4cccc6cccnc46)c4ccccc45)cc3)n2)cc1 ; N#Cc1ccc2c(c1)c1cc(-c3ccc(-c4nc5ccccc5c5c4cc(-c4cccc6cccnc46)c4ccccc45)cc3)ccc1n2-c1ccccc1 ; N#Cc1ccc2c(c1)c1cc(-c3cc4c(-c5ccccc5)nc5ccccc5c4c4ccccc34)ccc1n2-c1ccccc1]

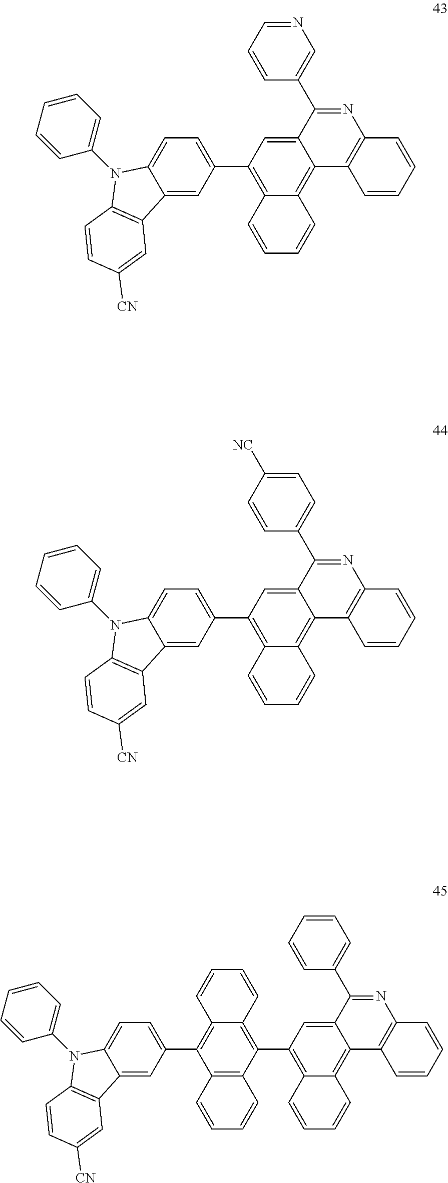 [SMILES: N#Cc1ccc2c(c1)c1cc(-c3cc4c(-c5cccnc5)nc5ccccc5c4c4ccccc34)ccc1n2-c1ccccc1 ; N#Cc1ccc(-c2nc3ccccc3c3c2cc(-c2ccc4c(c2)c2cc(C#N)ccc2n4-c2ccccc2)c2ccccc23)cc1 ; N#Cc1ccc2c(c1)c1cc(-c3c4ccccc4c(-c4cc5c(-c6ccccc6)nc6ccccc6c5c5ccccc45)c4ccccc34)ccc1n2-c1ccccc1]

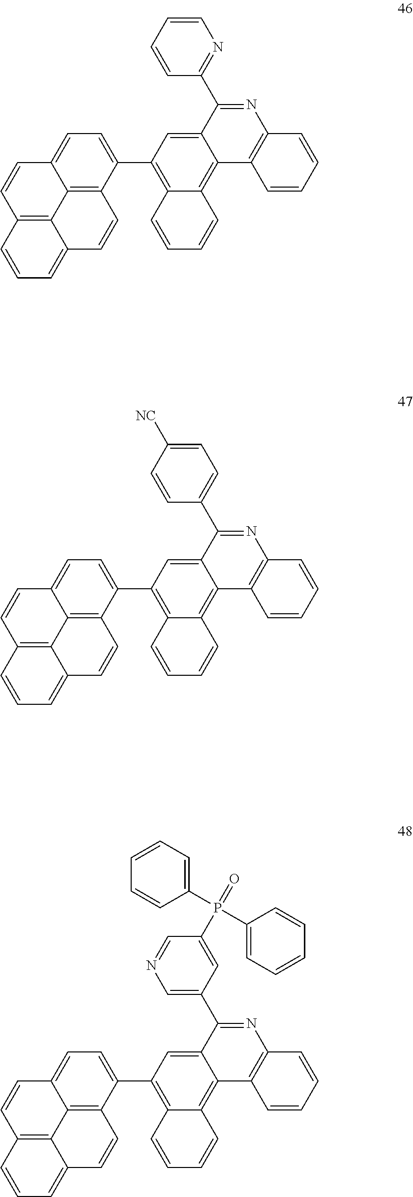 [SMILES: c1ccc(-c2nc3ccccc3c3c2cc(-c2ccc4ccc5cccc6ccc2c4c56)c2ccccc23)nc1 ; N#Cc1ccc(-c2nc3ccccc3c3c2cc(-c2ccc4ccc5cccc6ccc2c4c56)c2ccccc23)cc1 ; O=P(c1ccccc1)(c1ccccc1)c1cncc(-c2nc3ccccc3c3c2cc(-c2ccc4ccc5cccc6ccc2c4c56)c2ccccc23)c1]

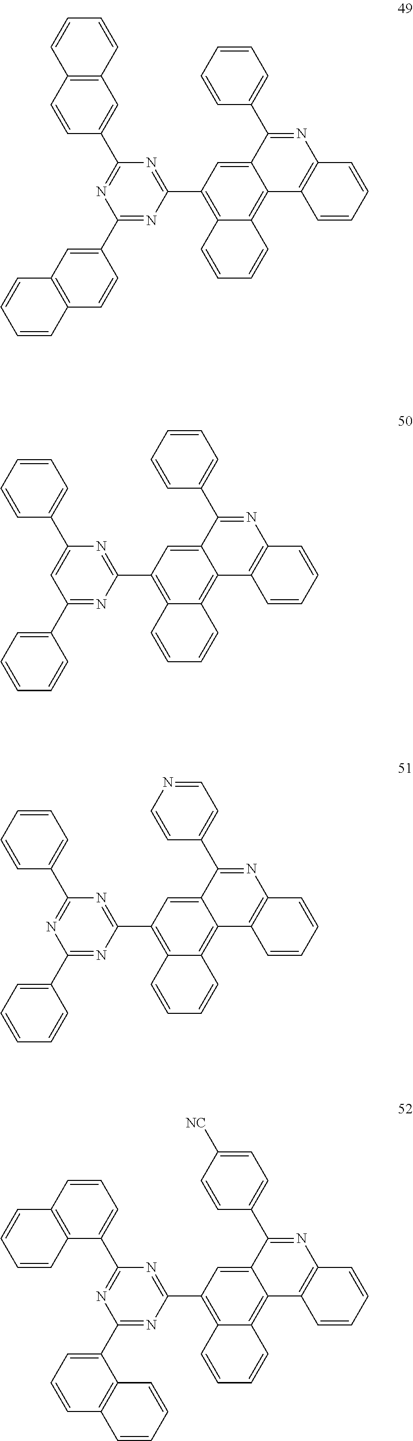 [SMILES: c1ccc(-c2nc3ccccc3c3c2cc(-c2nc(-c4ccc5ccccc5c4)nc(-c4ccc5ccccc5c4)n2)c2ccccc23)cc1 ; c1ccc(-c2cc(-c3ccccc3)nc(-c3cc4c(-c5ccccc5)nc5ccccc5c4c4ccccc34)n2)cc1 ; c1ccc(-c2nc(-c3ccccc3)nc(-c3cc4c(-c5ccncc5)nc5ccccc5c4c4ccccc34)n2)cc1 ; N#Cc1ccc(-c2nc3ccccc3c3c2cc(-c2nc(-c4cccc5ccccc45)nc(-c4cccc5ccccc45)n2)c2ccccc23)cc1]

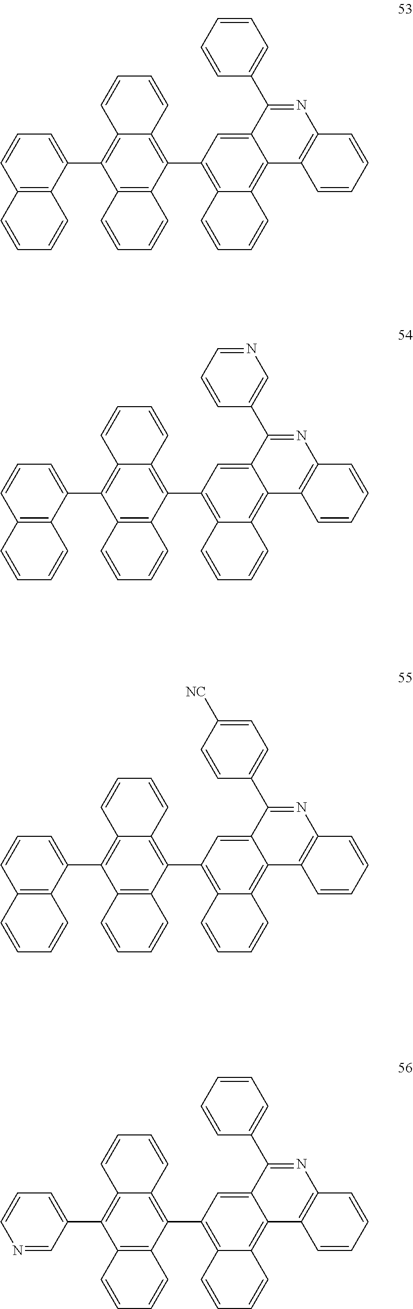 [SMILES: c1ccc(-c2nc3ccccc3c3c2cc(-c2c4ccccc4c(-c4cccc5ccccc45)c4ccccc24)c2ccccc23)cc1 ; c1cncc(-c2nc3ccccc3c3c2cc(-c2c4ccccc4c(-c4cccc5ccccc45)c4ccccc24)c2ccccc23)c1 ; N#Cc1ccc(-c2nc3ccccc3c3c2cc(-c2c4ccccc4c(-c4cccc5ccccc45)c4ccccc24)c2ccccc23)cc1 ; c1ccc(-c2nc3ccccc3c3c2cc(-c2c4ccccc4c(-c4cccnc4)c4ccccc24)c2ccccc23)cc1]

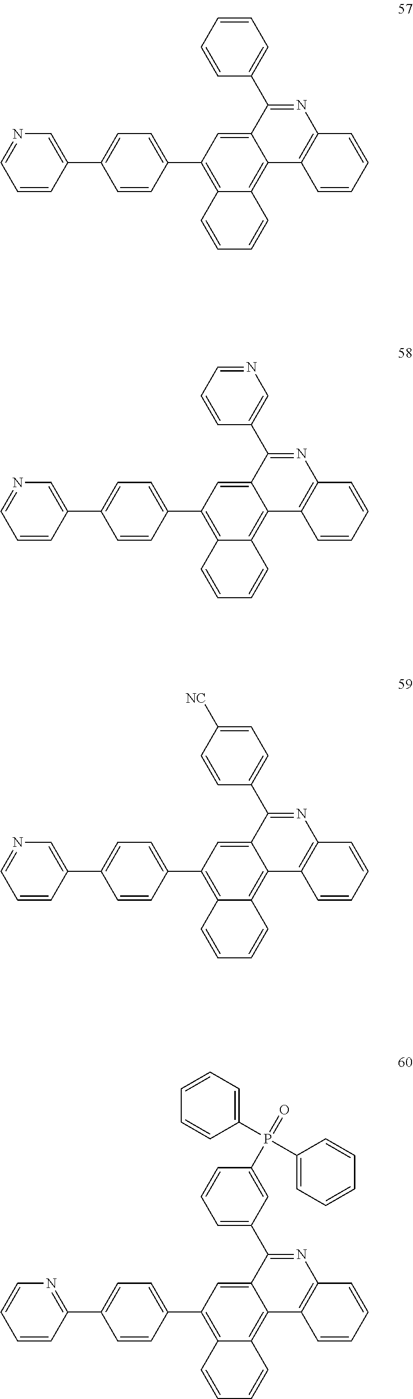 [SMILES: c1ccc(-c2nc3ccccc3c3c2cc(-c2ccc(-c4cccnc4)cc2)c2ccccc23)cc1 ; c1cncc(-c2ccc(-c3cc4c(-c5cccnc5)nc5ccccc5c4c4ccccc34)cc2)c1 ; N#Cc1ccc(-c2nc3ccccc3c3c2cc(-c2ccc(-c4cccnc4)cc2)c2ccccc23)cc1 ; O=P(c1ccccc1)(c1ccccc1)c1cccc(-c2nc3ccccc3c3c2cc(-c2ccc(-c4ccccn4)cc2)c2ccccc23)c1]

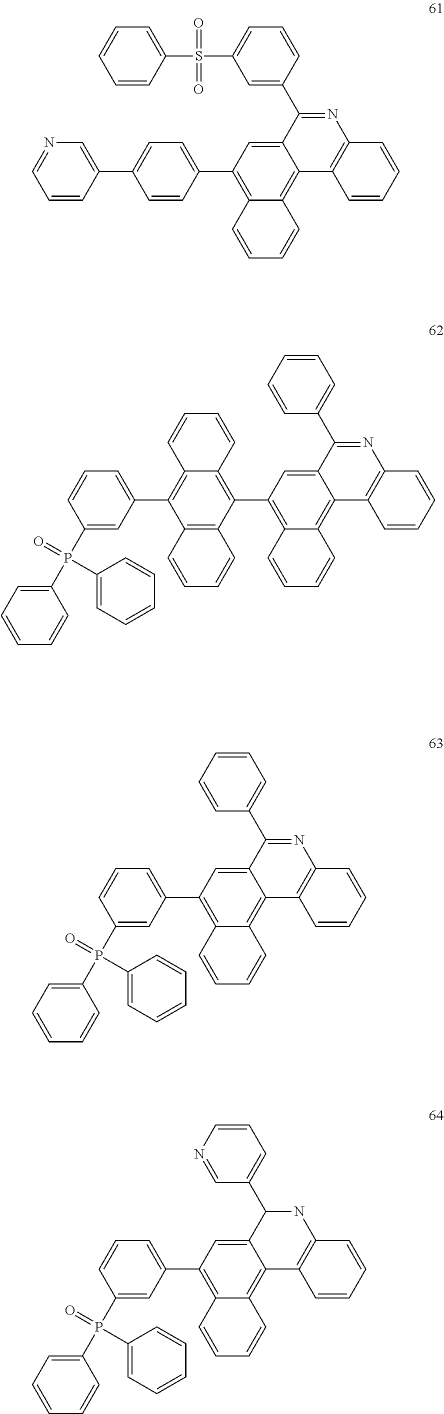 [SMILES: O=S(=O)(c1ccccc1)c1cccc(-c2nc3ccccc3c3c2cc(-c2ccc(-c4cccnc4)cc2)c2ccccc23)c1 ; O=P(c1ccccc1)(c1ccccc1)c1cccc(-c2c3ccccc3c(-c3cc4c(-c5ccccc5)nc5ccccc5c4c4ccccc34)c3ccccc23)c1 ; O=P(c1ccccc1)(c1ccccc1)c1cccc(-c2cc3c(-c4ccccc4)nc4ccccc4c3c3ccccc23)c1 ; O=P(c1ccccc1)(c1ccccc1)c1cccc(-c2cc3c(c4ccccc24)-c2ccccc2NC3c2cccnc2)c1]

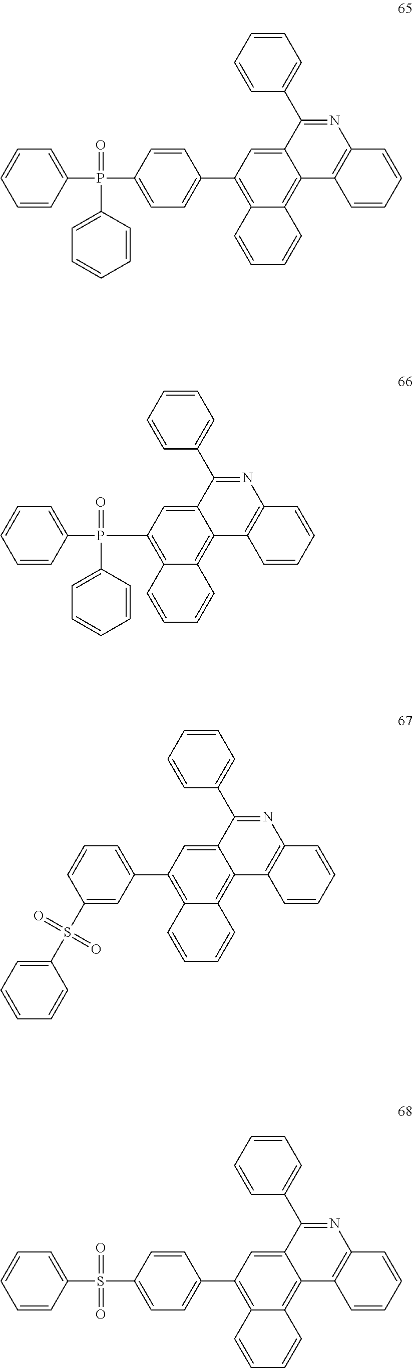 [SMILES: O=P(c1ccccc1)(c1ccccc1)c1ccc(-c2cc3c(-c4ccccc4)nc4ccccc4c3c3ccccc23)cc1 ; O=P(c1ccccc1)(c1ccccc1)c1cc2c(-c3ccccc3)nc3ccccc3c2c2ccccc12 ; O=S(=O)(c1ccccc1)c1cccc(-c2cc3c(-c4ccccc4)nc4ccccc4c3c3ccccc23)c1 ; O=S(=O)(c1ccccc1)c1ccc(-c2cc3c(-c4ccccc4)nc4ccccc4c3c3ccccc23)cc1]

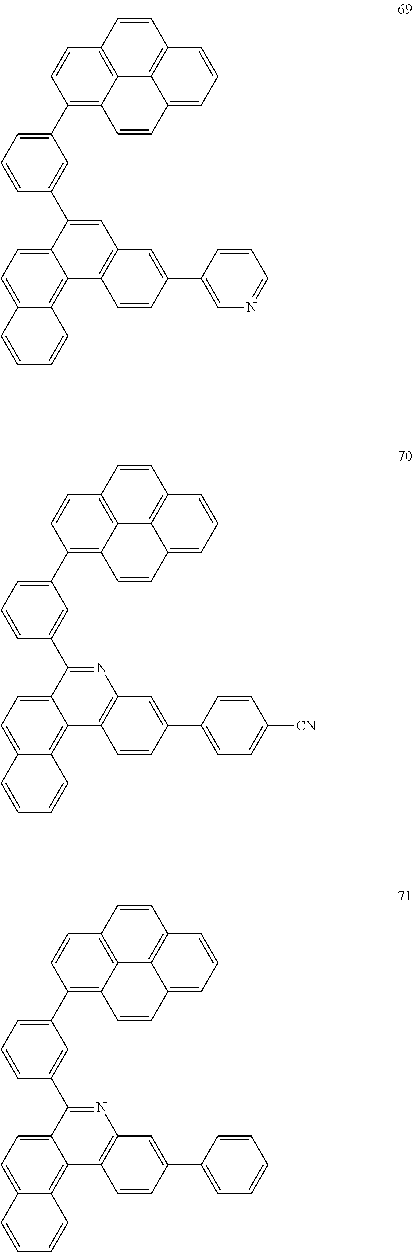 [SMILES: c1cncc(-c2ccc3c(c2)cc(-c2cccc(-c4ccc5ccc6cccc7ccc4c5c67)c2)c2ccc4ccccc4c23)c1 ; N#Cc1ccc(-c2ccc3c(c2)nc(-c2cccc(-c4ccc5ccc6cccc7ccc4c5c67)c2)c2ccc4ccccc4c23)cc1 ; c1ccc(-c2ccc3c(c2)nc(-c2cccc(-c4ccc5ccc6cccc7ccc4c5c67)c2)c2ccc4ccccc4c23)cc1]

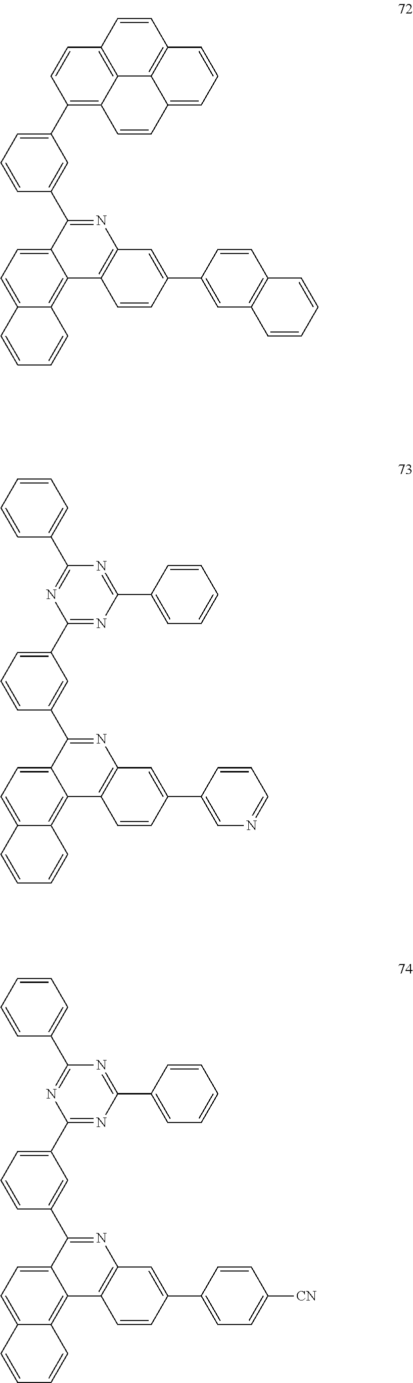 [SMILES: c1cc(-c2nc3cc(-c4ccc5ccccc5c4)ccc3c3c2ccc2ccccc23)cc(-c2ccc3ccc4cccc5ccc2c3c45)c1 ; c1ccc(-c2nc(-c3ccccc3)nc(-c3cccc(-c4nc5cc(-c6cccnc6)ccc5c5c4ccc4ccccc45)c3)n2)cc1 ; N#Cc1ccc(-c2ccc3c(c2)nc(-c2cccc(-c4nc(-c5ccccc5)nc(-c5ccccc5)n4)c2)c2ccc4ccccc4c23)cc1]

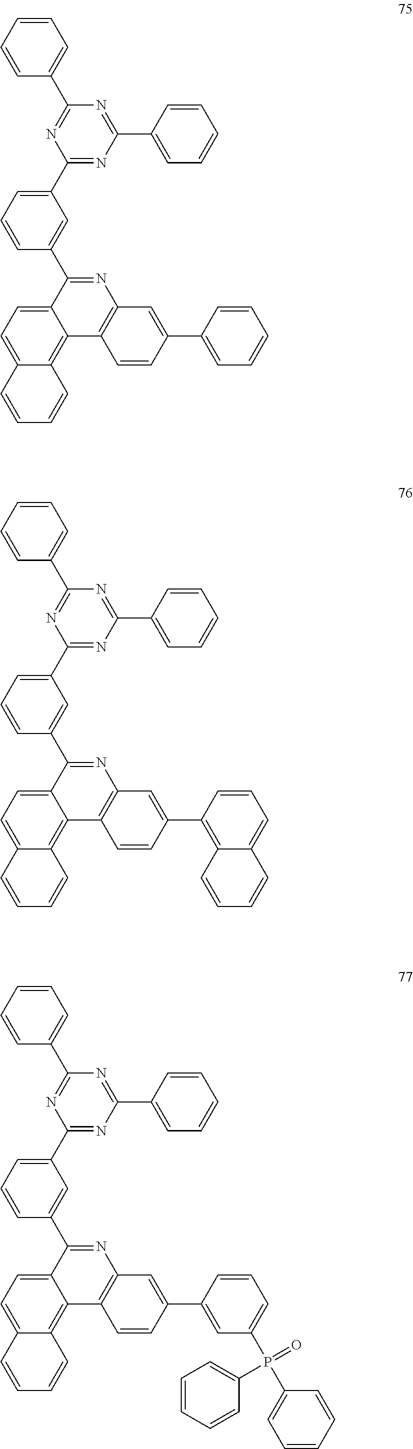 [SMILES: c1ccc(-c2ccc3c(c2)nc(-c2cccc(-c4nc(-c5ccccc5)nc(-c5ccccc5)n4)c2)c2ccc4ccccc4c23)cc1 ; c1ccc(-c2nc(-c3ccccc3)nc(-c3cccc(-c4nc5cc(-c6cccc7ccccc67)ccc5c5c4ccc4ccccc45)c3)n2)cc1 ; O=P(c1ccccc1)(c1ccccc1)c1cccc(-c2ccc3c(c2)nc(-c2cccc(-c4nc(-c5ccccc5)nc(-c5ccccc5)n4)c2)c2ccc4ccccc4c23)c1]

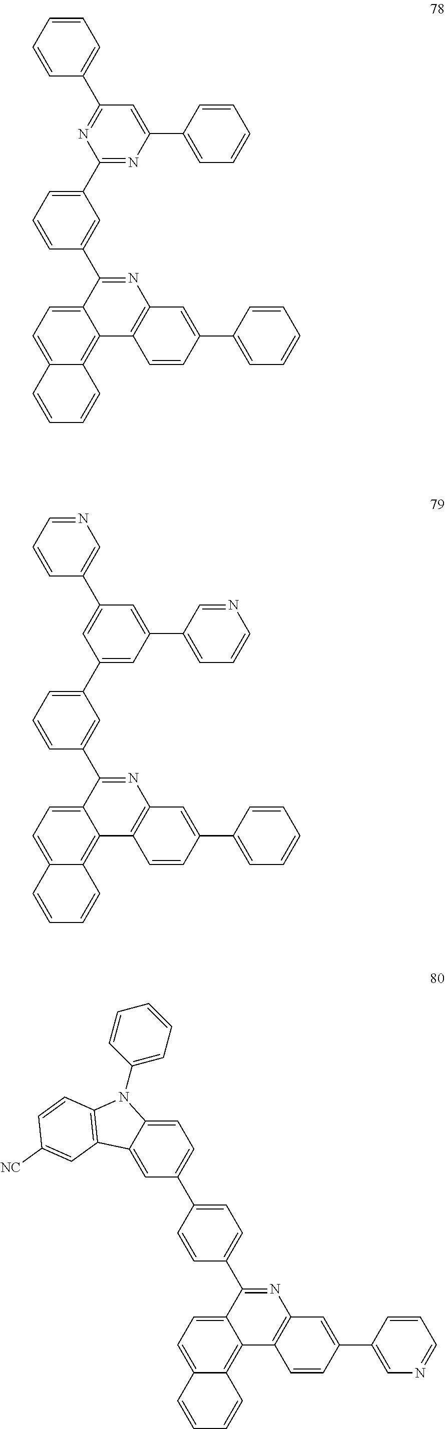 [SMILES: c1ccc(-c2ccc3c(c2)nc(-c2cccc(-c4nc(-c5ccccc5)cc(-c5ccccc5)n4)c2)c2ccc4ccccc4c23)cc1 ; c1ccc(-c2ccc3c(c2)nc(-c2cccc(-c4cc(-c5cccnc5)cc(-c5cccnc5)c4)c2)c2ccc4ccccc4c23)cc1 ; N#Cc1ccc2c(c1)c1cc(-c3ccc(-c4nc5cc(-c6cccnc6)ccc5c5c4ccc4ccccc45)cc3)ccc1n2-c1ccccc1]

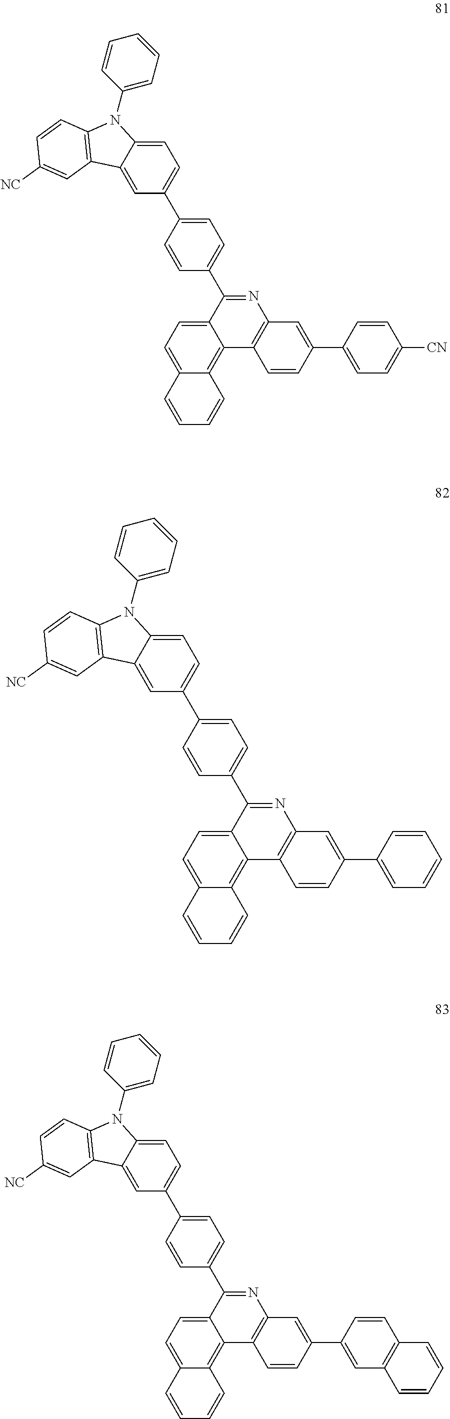 [SMILES: N#Cc1ccc(-c2ccc3c(c2)nc(-c2ccc(-c4ccc5c(c4)c4cc(C#N)ccc4n5-c4ccccc4)cc2)c2ccc4ccccc4c23)cc1 ; N#Cc1ccc2c(c1)c1cc(-c3ccc(-c4nc5cc(-c6ccccc6)ccc5c5c4ccc4ccccc45)cc3)ccc1n2-c1ccccc1 ; N#Cc1ccc2c(c1)c1cc(-c3ccc(-c4nc5cc(-c6ccc7ccccc7c6)ccc5c5c4ccc4ccccc45)cc3)ccc1n2-c1ccccc1]

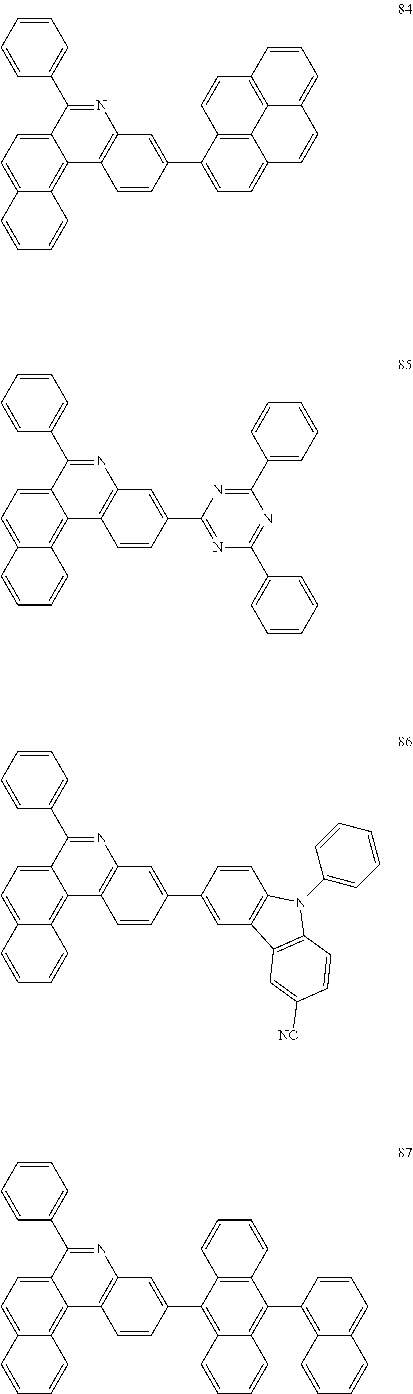 [SMILES: c1ccc(-c2nc3cc(-c4ccc5ccc6cccc7ccc4c5c67)ccc3c3c2ccc2ccccc23)cc1 ; c1ccc(-c2nc(-c3ccccc3)nc(-c3ccc4c(c3)nc(-c3ccccc3)c3ccc5ccccc5c34)n2)cc1 ; N#Cc1ccc2c(c1)c1cc(-c3ccc4c(c3)nc(-c3ccccc3)c3ccc5ccccc5c34)ccc1n2-c1ccccc1 ; c1ccc(-c2nc3cc(-c4c5ccccc5c(-c5cccc6ccccc56)c5ccccc45)ccc3c3c2ccc2ccccc23)cc1]

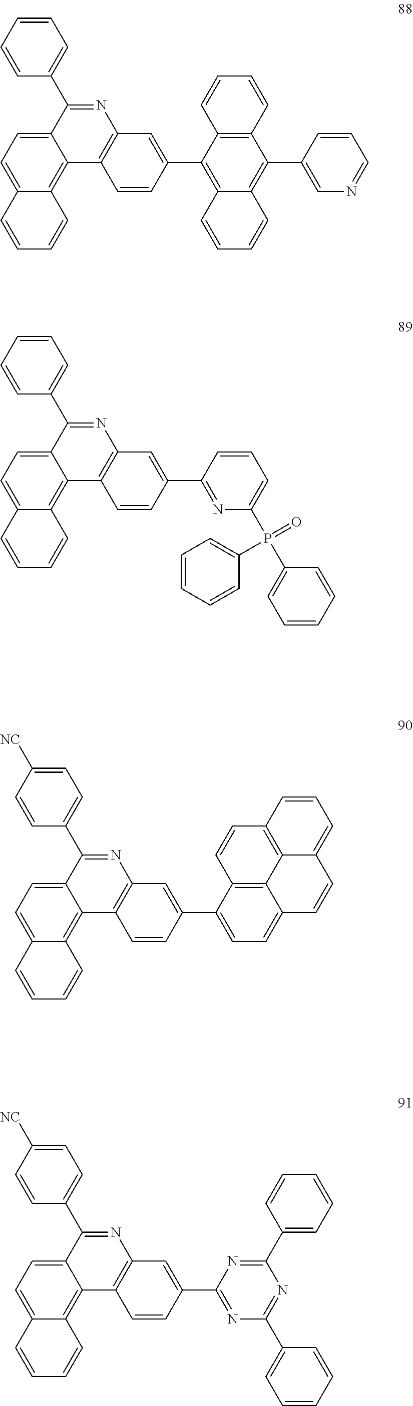 [SMILES: c1ccc(-c2nc3cc(-c4c5ccccc5c(-c5cccnc5)c5ccccc45)ccc3c3c2ccc2ccccc23)cc1 ; O=P(c1ccccc1)(c1ccccc1)c1cccc(-c2ccc3c(c2)nc(-c2ccccc2)c2ccc4ccccc4c23)n1 ; N#Cc1ccc(-c2nc3cc(-c4ccc5ccc6cccc7ccc4c5c67)ccc3c3c2ccc2ccccc23)cc1 ; N#Cc1ccc(-c2nc3cc(-c4nc(-c5ccccc5)nc(-c5ccccc5)n4)ccc3c3c2ccc2ccccc23)cc1]

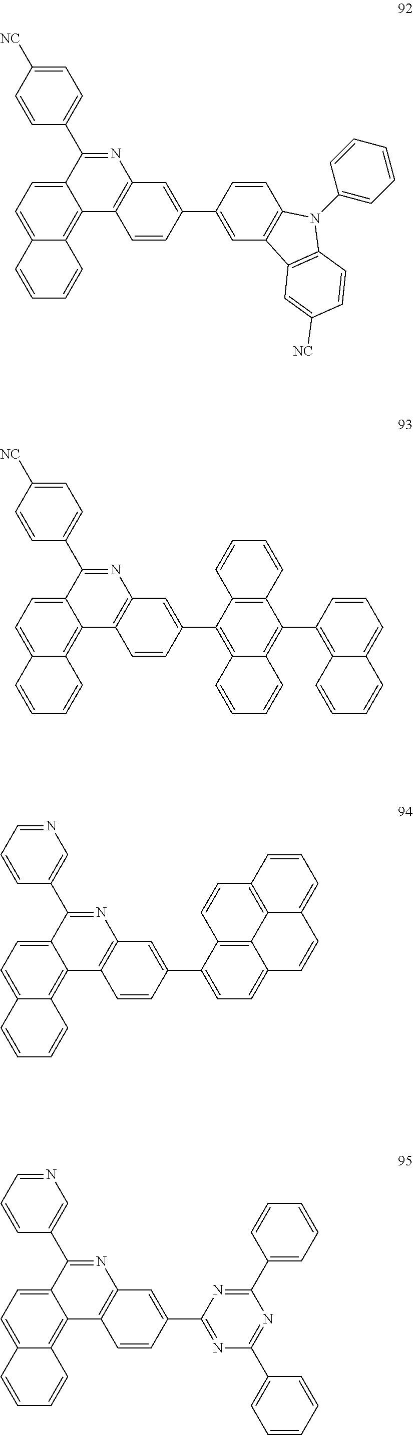 [SMILES: N#Cc1ccc(-c2nc3cc(-c4ccc5c(c4)c4cc(C#N)ccc4n5-c4ccccc4)ccc3c3c2ccc2ccccc23)cc1 ; N#Cc1ccc(-c2nc3cc(-c4c5ccccc5c(-c5cccc6ccccc56)c5ccccc45)ccc3c3c2ccc2ccccc23)cc1 ; c1cncc(-c2nc3cc(-c4ccc5ccc6cccc7ccc4c5c67)ccc3c3c2ccc2ccccc23)c1 ; c1ccc(-c2nc(-c3ccccc3)nc(-c3ccc4c(c3)nc(-c3cccnc3)c3ccc5ccccc5c34)n2)cc1]

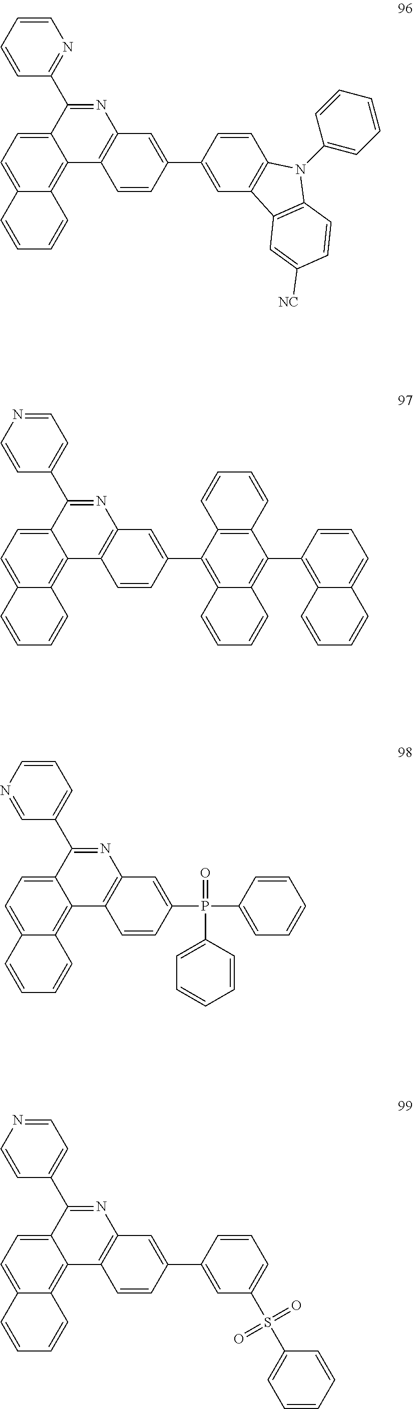 [SMILES: N#Cc1ccc2c(c1)c1cc(-c3ccc4c(c3)nc(-c3ccccn3)c3ccc5ccccc5c34)ccc1n2-c1ccccc1 ; c1ccc2c(-c3c4ccccc4c(-c4ccc5c(c4)nc(-c4ccncc4)c4ccc6ccccc6c45)c4ccccc34)cccc2c1 ; O=P(c1ccccc1)(c1ccccc1)c1ccc2c(c1)nc(-c1cccnc1)c1ccc3ccccc3c12 ; O=S(=O)(c1ccccc1)c1cccc(-c2ccc3c(c2)nc(-c2ccncc2)c2ccc4ccccc4c23)c1]

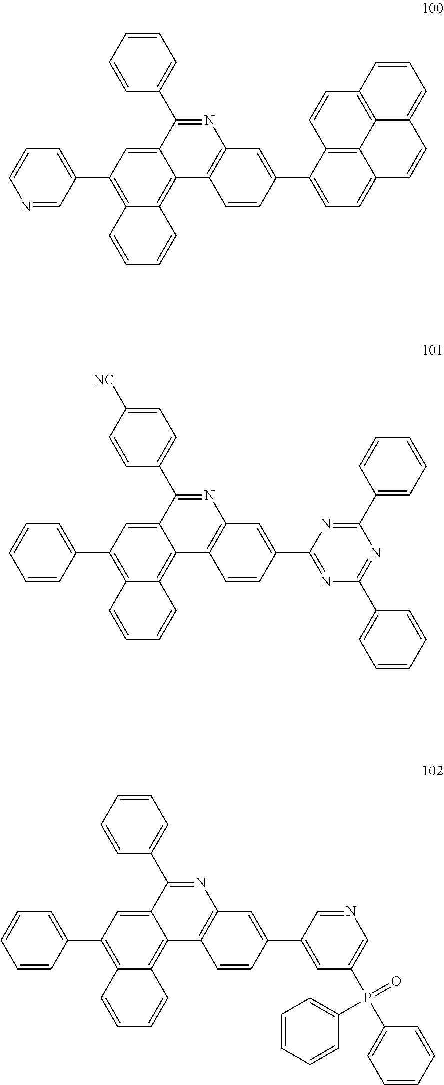 [SMILES: c1ccc(-c2nc3cc(-c4ccc5ccc6cccc7ccc4c5c67)ccc3c3c2cc(-c2cccnc2)c2ccccc23)cc1 ; N#Cc1ccc(-c2nc3cc(-c4nc(-c5ccccc5)nc(-c5ccccc5)n4)ccc3c3c2cc(-c2ccccc2)c2ccccc23)cc1 ; O=P(c1ccccc1)(c1ccccc1)c1cncc(-c2ccc3c(c2)nc(-c2ccccc2)c2cc(-c4ccccc4)c4ccccc4c23)c1]

13. An organic light-emitting device, comprising
a first electrode;
a second electrode; and
an organic layer between the first electrode and the second electrode,
wherein the organic layer includes the compound represented by Formula 1 as claimed in claim 1.

14. The organic light-emitting device as claimed in claim 13, wherein
the organic layer is an electron transport layer

15. The organic light-emitting device as claimed in claim 13, wherein:
the organic layer includes an emission layer, and an electron injection layer, an electron transport layer, a functional layer having an electron injection capability and an electron transportation capability, a hole injection layer, a hole transport layer, or a functional layer having a hole injection capability and a hole transportation capability, and
the emission layer includes an anthracene-based compound, an arylamine-based compound, or a styryl-based compound.

16. The organic light-emitting device as claimed in claim 13, wherein:
the organic light-emitting device includes an emission layer, and an electron injection layer, an electron transport layer, a functional layer having an electron injection capability and an electron transportation capability, a hole injection layer, a hole transport layer, or a functional layer having a hole injection capability and a hole transportation capability,
the emission layer includes a red layer, a green layer, a blue layer, and a white layer, and
any one of the red, green, and blue layers includes a phosphorescent compound.

17. The organic light-emitting device as claimed in claim 16, wherein
the hole injection layer, the hole transport layer, or the functional layer having a hole injection capability and a hole transportation capability includes an electron-generating material.

18. The organic light-emitting device as claimed in claim 13, wherein
the organic layer includes an electron transport layer that includes a metal complex.

19. The organic light-emitting device as claimed in claim 13, wherein
the organic layer is formed by a wet process.

20. A flat display apparatus comprising the organic light-emitting device of claim 13, wherein the first electrode of the organic light-emitting device is electrically connected to a source electrode or a drain electrode of a thin film transistor.
